(19) United States
(12) Patent Application Publication
(10) Pub. No.: US 2016/0104734 A1
(43) Pub. Date: Apr. 14, 2016

(54) IMAGING DEVICE

(71) Applicant: Semiconductor Energy Laboratory Co., Ltd., Atsugi-shi (JP)

(72) Inventors: Atsushi HIROSE, Isehara (JP); Yoshiyuki KUROKAWA, Sagamihara (JP); Takayuki IKEDA, Atsugi (JP)

(21) Appl. No.: 14/874,664

(22) Filed: Oct. 5, 2015

(30) Foreign Application Priority Data
Oct. 10, 2014 (JP) 2014-209236
Nov. 10, 2014 (JP) 2014-227919
Jan. 26, 2015 (JP) 2015-012296
May 15, 2015 (JP) 2015-099700

(51) Int. Cl. H01L 27/146; H01L 27/12

(52) U.S. Cl. CPC H01L 27/14616; H01L 27/1225; H01L 27/14643

(57) ABSTRACT

To provide an imaging device in which incident light can be converted into an appropriate electric signal. The imaging device includes a photoelectric conversion element, a first transistor, a second transistor, a third transistor, and a fourth transistor. One of a source electrode and a drain electrode of the first transistor and one electrode of the photoelectric conversion element have an electrical connection portion in a first opening provided in an insulating layer positioned between the one of the source electrode and the drain electrode of the first transistor and the one electrode of the photoelectric conversion element. The number of the first opening is one in a region where the one of the source electrode and the drain electrode of the first transistor overlaps with the one electrode of the photoelectric conversion element.

### TECHNICAL FIELD

One embodiment of the present invention relates to an imaging device including an oxide semiconductor.

Note that one embodiment of the present invention is not limited to the above technical field. The technical field of one embodiment of the invention disclosed in this specification and the like relates to an object, a method, or a manufacturing method. In addition, one embodiment of the present invention relates to a process, a machine, manufacture, or a composition of matter. Specifically, examples of the technical field of one embodiment of the present invention disclosed in this specification include a semiconductor device, a display device, a liquid crystal display device, a light-emitting device, a lighting device, a power storage device, a memory device, an imaging device, a method for driving any of them, and a method for manufacturing any of them.

Note that in this specification and the like, a semiconductor device generally means a device that can function by utilizing semiconductor characteristics. A transistor or a semiconductor circuit is one embodiment of the semiconductor device. A memory device, a display device, an imaging device, or an electronic device includes a semiconductor device in some cases.

### BACKGROUND ART

A technique for forming a transistor by using a semiconductor thin film over a substrate having an insulating surface has attracted attention. The transistor is used in a wide range of electronic devices such as an integrated circuit (IC) and a display device. Silicon-based semiconductors are widely known as a semiconductor material applicable to a transistor; as another material, an oxide semiconductor has been attracting attention.

For example, a technique for forming a transistor using zinc oxide or an In—Ga—Zn-based oxide semiconductor as an oxide semiconductor is disclosed (see Patent Documents 1 and 2).

Patent Document 3 discloses an imaging device in which a transistor including an oxide semiconductor and having an extremely low off-state current is used in part of a pixel circuit and a transistor including silicon with which a complementary metal oxide semiconductor (CMOS) circuit can be formed is used in a peripheral circuit.

Patent Document 4 discloses an imaging device in which a transistor including silicon, a transistor including an oxide semiconductor, and a photodiode including a crystalline silicon layer are stacked.

### REFERENCES

### Patent Documents

[Patent Document 1] Japanese Published Patent Application No. 2007-123861
[Patent Document 2] Japanese Published Patent Application No. 2007-096055
[Patent Document 3] Japanese Published Patent Application No. 2011-119711
[Patent Document 4] Japanese Published Patent Application No. 2013-243355

### DISCLOSURE OF INVENTION

A pixel circuit has a function of converting incident light into an electric signal. To convert incident light into an appropriate electric signal, transistor noise needs to be reduced to a predetermined value or less. That is, the transistor noise is preferably as low as possible.

In view of the above, an object of one embodiment of the present invention is to provide an imaging device in which incident light can be converted into an appropriate electric signal. Another object of one embodiment of the present invention is to provide an imaging device including a low noise transistor. Another object of one embodiment of the present invention is to provide an imaging device that is suitable for high-speed operation. Another object of one embodiment of the present invention is to provide an imaging device with high resolution. Another object of one embodiment of the present invention is to provide a highly integrated imaging device. Another object of one embodiment of the present invention is to provide an imaging device with low power consumption. Another object of one embodiment of the present invention is to provide an imaging device capable of capturing an image under a low illuminance condition. Another object of one embodiment of the present invention is to provide an imaging device with a wide dynamic range. Another object of one embodiment of the present invention is to provide an imaging device that can be used in a wide temperature range. Another object of one embodiment of the present invention is to provide an imaging device with a high aperture ratio. Another object of one embodiment of the present invention is to provide an imaging device with high reliability. Another object of one embodiment of the present invention is to provide a novel imaging device or the like. Another object of one embodiment of the present invention is to provide a novel semiconductor device or the like.

Note that the description of these objects does not disturb the existence of other objects. In one embodiment of the present invention, there is no need to achieve all the objects. Other objects will be apparent from and can be derived from the description of the specification, the drawings, the claims, and the like.

One embodiment of the present invention relates to an imaging device including a transistor that is formed using an oxide semiconductor.

One embodiment of the present invention is an imaging device including a photoelectric conversion element, a first transistor, a second transistor, a third transistor, and a fourth transistor. The first to fourth transistors each include an oxide semiconductor in an active layer. One of a source electrode and a drain electrode of the first transistor is electrically connected to one electrode of the photoelectric conversion element. The other of the source electrode and the drain electrode of the first transistor is electrically connected to a gate electrode of the second transistor. The other of the source electrode and the drain electrode of the first transistor is electrically connected to one of a source electrode and a drain electrode of the third transistor. One of a source electrode and a drain electrode of the second transistor is electrically connected to one of a source electrode and a drain electrode of the fourth transistor. The one of the source electrode and the drain electrode of the first transistor and the one electrode of the photoelectric conversion element have an electrical connection portion in a first opening provided in an insulating layer positioned between the one of the source electrode and the drain electrode of the first transistor and the one electrode of the photoelectric conversion element. The number of the first opening is one in a region where the one of the source electrode and the drain electrode of the first transistor overlaps with the one electrode of the photoelectric conversion element.

The other of the source electrode and the drain electrode of the first transistor and the gate electrode of the second transistor may have an electrical connection portion in a second opening provided in an insulating layer positioned between the other of the source electrode and the drain electrode of the first transistor and the gate electrode of the second transistor, and the number of the second opening may be one in a region where the other of the source electrode and the drain electrode of the first transistor overlaps with the gate electrode of the second transistor.

The other of the source electrode and the drain electrode of the first transistor may be electrically connected to one electrode of a capacitor.

The oxide semiconductor preferably contains In, Zn, and M (M is Al, Ti, Ga, Sn, Y, Zr, La, Ce, Nd, or Hf).

In the photoelectric conversion element, selenium may be used for a photoelectric conversion layer.

According to one embodiment of the present invention, an imaging device in which incident light can be converted into an appropriate electric signal can be provided. An imaging device including a low noise transistor can be provided. An imaging device that is suitable for high-speed operation can be provided. An imaging device with high resolution can be provided. A highly integrated imaging device can be provided. An imaging device with low power consumption can be provided. An imaging device capable of capturing an image under a low illuminance condition can be provided. An imaging device with a wide dynamic range can be provided. An imaging device that can be used in a wide temperature range can be provided. An imaging device with a high aperture ratio can be provided. An imaging device with high reliability can be provided. A novel imaging device or the like can be provided. A novel semiconductor device or the like can be provided.

Note that one embodiment of the present invention is not limited to these effects. For example, depending on circumstances or conditions, one embodiment of the present invention might produce another effect. Furthermore, depending on circumstances or conditions, one embodiment of the present invention might not produce any of the above effects.

### BRIEF DESCRIPTION OF DRAWINGS

FIGS. 1A and 1B are a top view and a cross-sectional view illustrating an imaging device;

FIGS. 2A and 2B illustrate circuits included in an imaging device;

FIGS. 3A to 3D are cross-sectional views illustrating connection configurations of a photoelectric conversion element;

FIGS. 4A and 4B are cross-sectional views illustrating imaging devices;

FIGS. 5A to 5F are cross-sectional views illustrating connection configurations of a photoelectric conversion element;

FIG. 6 is a cross-sectional view illustrating an imaging device;

FIGS. 7A and 7B are cross-sectional views illustrating an imaging device;

FIGS. 8A to 8D are cross-sectional views illustrating structures of an imaging device;

FIGS. 9A1 to 9A3 and 9B1 to 9B3 illustrate bent imaging devices;

FIGS. 10A and 10B each illustrate a configuration of a pixel circuit;

FIGS. 11A to 11C are timing charts showing operations of a pixel circuit;

FIGS. 12A and 12B each illustrate a configuration of a pixel circuit;

FIGS. 13A and 13B each illustrate a configuration of a pixel circuit;

FIGS. 14A and 14B each illustrate a configuration of a pixel circuit;

FIG. 15 illustrates a configuration of a pixel circuit;

FIG. 16 illustrates a configuration of a pixel circuit;

FIG. 17 illustrates a configuration of a pixel circuit;

FIG. 18 illustrates a configuration of a pixel circuit;

FIGS. 19A and 19B are timing charts showing operation in a global shutter system and a rolling shutter system, respectively;

FIGS. 20A and 20B are a top view and a cross-sectional view of a transistor;

FIGS. 21A and 21B are a top view and a cross-sectional view of a transistor;

FIGS. 22A and 22B are a top view and a cross-sectional view of a transistor;

FIGS. 23A and 23B are a top view and a cross-sectional view of a transistor;

FIGS. 24A and 24B are a top view and a cross-sectional view of a transistor;

FIGS. 25A and 25B are a top view and a cross-sectional view of a transistor;

FIGS. 26A to 26D illustrate cross sections of a transistor in the channel width direction;

FIGS. 27A to 27F illustrate cross sections of a transistor in the channel length direction;

FIGS. 28A to 28E are a top view and cross-sectional views illustrating a semiconductor layer;

FIGS. 29A and 29B are a top view and a cross-sectional view of a transistor;

FIGS. 30A and 30B are a top view and a cross-sectional view of a transistor;

FIGS. 31A and 31B are a top view and a cross-sectional view of a transistor;

FIGS. 32A and 32B are a top view and a cross-sectional view of a transistor;

FIGS. 33A and 33B are a top view and a cross-sectional view of a transistor;

FIGS. 34A and 34B are a top view and a cross-sectional view of a transistor;

FIGS. 35A to 35D illustrate cross sections of a transistor in the channel width direction;

FIGS. 36A to 36F illustrate cross sections of a transistor in the channel length direction;

FIGS. 37A and 37B are top views each illustrating a transistor;

FIGS. 38A to 38F illustrate electronic devices;

FIGS. 39A and 39B show the Id−Vg characteristics and drain breakdown voltage of transistors;

FIGS. 40A and 40B show the Id−Vg characteristics and drain breakdown voltage of transistors;

FIGS. 41A to 41C show the gate breakdown voltage of transistors;

FIGS. 42A to 42C show the drain breakdown voltage and gate breakdown voltage of transistors;

FIG. 43 shows the amount of change in drain current with time due to noise;

FIG. 44 shows the 1/f noise characteristics of transistors;

FIG. 45 shows the 1/f noise characteristics of transistors;

FIG. 46 shows the 1/f noise characteristics of transistors;

FIG. 47 shows the 1/f noise characteristics of transistors;

FIGS. 48A and 48B are photographs showing a top surface of an imaging device;

FIGS. 49A and 49B are photographs showing a top surface and a cross section of an imaging device;

FIGS. 50A and 50B are cross-sectional views illustrating connection configurations of a photoelectric conversion element;

FIG. 51 shows surface roughness of electrodes;

FIGS. 52A and 52B show cross-sectional STEM images of OS FETs in the channel length direction;

FIG. 53 shows the Id−Vg characteristics of OS FETs;

FIGS. 54A and 54B show drain current spectral density (S_{Id})as a function of frequency;

FIG. 55 shows drain current spectral density (S_{Id})as a function of frequency;

FIGS. 56A and 56B show drain current spectral density (S_{Id})as a function of frequency;

FIGS. 57A and 57B show drain current spectral density (S_{Id})as a function of frequency;

FIGS. 58A and 58B show the relationship between (S_{Id}/Id²) and (Vgs−Vth) of each transistor;

FIG. 59 shows the relationship between (S_{Id}/Id²) and (Vgs−Vth) of each transistor;

FIG. 60 shows the relationship between Hooge's parameter (α_{H}) and Id;

FIGS. 61A and 61B show (S_{Id}/Id²) of various transistors as a function of temperature;

FIGS. 62A and 62B show mobility as a function of temperature; and

FIGS. 63A and 63B show drain current-dependent activation energy of (S_{Id}/Id²).

### BEST MODE FOR CARRYING OUT THE INVENTION

Embodiments will be described in detail with reference to drawings. Note that the present invention is not limited to the description below, and it is easily understood by those skilled in the art that various changes and modifications can be made without departing from the spirit and scope of the present invention. Accordingly, the present invention should not be interpreted as being limited to the content of the embodiments below. Note that in the structures of the invention described below, the same portions or portions having similar functions are denoted by the same reference numerals in different drawings, and the description of such portions is not repeated in some cases. It is also to be noted that the same components are denoted by different hatching patterns in different drawings, or the hatching patterns are omitted in some cases.

For example, in this specification and the like, an explicit description “X and Y are connected” means that X and Y are electrically connected, X and Y are functionally connected, and X and Y are directly connected. Accordingly, another element may be provided between elements having a connection relation illustrated in drawings and texts, without limitation on a predetermined connection relation, for example, the connection relation illustrated in the drawings and the texts.

Here, X and Y each denote an object (e.g., a device, an element, a circuit, a line, an electrode, a terminal, a conductive film, a layer, or the like).

Examples of the case where X and Y are directly connected include the case where an element that allows an electrical connection between X and Y (e.g., a switch, a transistor, a capacitor, an inductor, a resistor, a diode, a display element, a light-emitting element, and a load) is not connected between X and Y, and the case where X and Y are connected without the element that allows the electrical connection between X and Y provided therebetween.

For example, in the case where X and Y are electrically connected, one or more elements that enable electrical connection between X and Y (e.g., a switch, a transistor, a capacitor, an inductor, a resistor, a diode, a display element, a light-emitting element, or a load) can be connected between X and Y. A switch is controlled to be on or off. That is, a switch is conducting or not conducting (is turned on or off) to determine whether current flows therethrough or not. Alternatively, the switch has a function of selecting and changing a current path. Note that the case where X and Y are electrically connected includes the case where X and Y are directly connected.

For example, in the case where X and Y are functionally connected, one or more circuits that enable functional connection between X and Y (e.g., a logic circuit such as an inverter, a NAND circuit, or a NOR circuit; a signal converter circuit such as a DA converter circuit, an AD converter circuit, or a gamma correction circuit; a potential level converter circuit such as a power supply circuit (e.g., a step-up circuit or a step-down circuit) or a level shifter circuit for changing the potential level of a signal; a voltage source; a current source; a switching circuit; an amplifier circuit such as a circuit that can increase signal amplitude, the amount of current, or the like, an operational amplifier, a differential amplifier circuit, a source follower circuit, or a buffer circuit; a signal generation circuit; a memory circuit; and/or a control circuit) can be connected between X and Y. Note that for example, when a signal output from Xis transmitted to Y, it can be said that X and Y are functionally connected even if another circuit is provided between X and Y. Note that the case where X and Y are functionally connected includes the case where X and Y are directly connected and the case where X and Y are electrically connected.

Note that in this specification and the like, an explicit description “X and Y are electrically connected” means that X and Y are electrically connected (i.e., the case where X and Y are connected with another element or circuit provided therebetween), X and Y are functionally connected (i.e., the case where X and Y are functionally connected with another circuit provided therebetween), and X and Y are directly connected (i.e., the case where X and Y are connected without another element or circuit provided therebetween). That is, in this specification and the like, the explicit expression “X and Y are electrically connected” is the same as the explicit simple expression “X and Y are connected”.

For example, any of the following expressions can be used for the case where a source (or a first terminal or the like) of a transistor is electrically connected to X through (or not through) Z1 and a drain (or a second terminal or the like) of the transistor is electrically connected to Y through (or not through) Z2, or the case where a source (or a first terminal or the like) of a transistor is directly connected to one part of Z1 and another part of Z1 is directly connected to X while a drain (or a second terminal or the like) of the transistor is directly connected to one part of Z2 and another part of Z2 is directly connected to Y.

Examples of the expressions include, “X Y, a source (or a first terminal or the like) of a transistor, and a drain (or a second terminal or the like) of the transistor are electrically connected to each other, and X the source (or the first terminal or the like) of the transistor, the drain (or the second terminal or the like) of the transistor, and Y are electrically connected to each other in this order”, “a source (or a first terminal or the like) of a transistor is electrically connected to X a drain (or a second terminal or the like) of the transistor is electrically connected to Y, and X the source (or the first terminal or the like) of the transistor, the drain (or the second terminal or the like) of the transistor, and Y are electrically connected to each other in this order”, and “X is electrically connected to Y through a source (or a first terminal or the like) and a drain (or a second terminal or the like) of a transistor, and X, the source (or the first terminal or the like) of the transistor, the drain (or the second terminal or the like) of the transistor, and Y are provided to be connected in this order”. When the connection order in a circuit structure is defined by an expression similar to the above examples, a source (or a first terminal or the like) and a drain (or a second terminal or the like) of a transistor can be distinguished from each other to specify the technical scope.

Other examples of the expressions include, “a source (or a first terminal or the like) of a transistor is electrically connected to X through at least a first connection path, the first connection path does not include a second connection path, the second connection path is a path between the source (or the first terminal or the like) of the transistor and a drain (or a second terminal or the like) of the transistor, Z1 is on the first connection path, the drain (or the second terminal or the like) of the transistor is electrically connected to Y through at least a third connection path, the third connection path does not include the second connection path, and Z2 is on the third connection path”. It is also possible to use the expression “a source (or a first terminal or the like) of a transistor is electrically connected to X through at least Z1 on a first connection path, the first connection path does not include a second connection path, the second connection path includes a connection path through the transistor, a drain (or a second terminal or the like) of the transistor is electrically connected to Y through at least Z2 on a third connection path, and the third connection path does not include the second connection path”. Still another example of the expression is “a source (or a first terminal or the like) of a transistor is electrically connected to X through at least Z1 on a first electrical path, the first electrical path does not include a second electrical path, the second electrical path is an electrical path from the source (or the first terminal or the like) of the transistor to a drain (or a second terminal or the like) of the transistor, the drain (or the second terminal or the like) of the transistor is electrically connected to Y through at least Z2 on a third electrical path, the third electrical path does not include a fourth electrical path, and the fourth electrical path is an electrical path from the drain (or the second terminal or the like) of the transistor to the source (or the first terminal or the like) of the transistor”. When the connection path in a circuit structure is defined by an expression similar to the above examples, a source (or a first terminal or the like) and a drain (or a second terminal or the like) of a transistor can be distinguished from each other to specify the technical scope.

Note that one embodiment of the present invention is not limited to these expressions which are just examples. Here, each of X, Y, Z1, and Z2 denotes an object (e.g., a device, an element, a circuit, a wiring, an electrode, a terminal, a conductive film, or a layer).

Even when independent components are electrically connected to each other in a circuit diagram, one component has functions of a plurality of components in some cases. For example, when part of a wiring also functions as an electrode, one conductive film functions as the wiring and the electrode. Thus, “electrical connection” in this specification includes in its category such a case where one conductive film has functions of a plurality of components.

Note that the terms “film” and “layer” can be interchanged with each other depending on the case or circumstances. For example, the term “conductive layer” can be changed into the term “conductive film” in some cases. Also, the term “insulating film” can be changed into the term “insulating layer” in some cases.

### Embodiment 1

In this embodiment, an imaging device of one embodiment of the present invention will be described with reference to drawings.

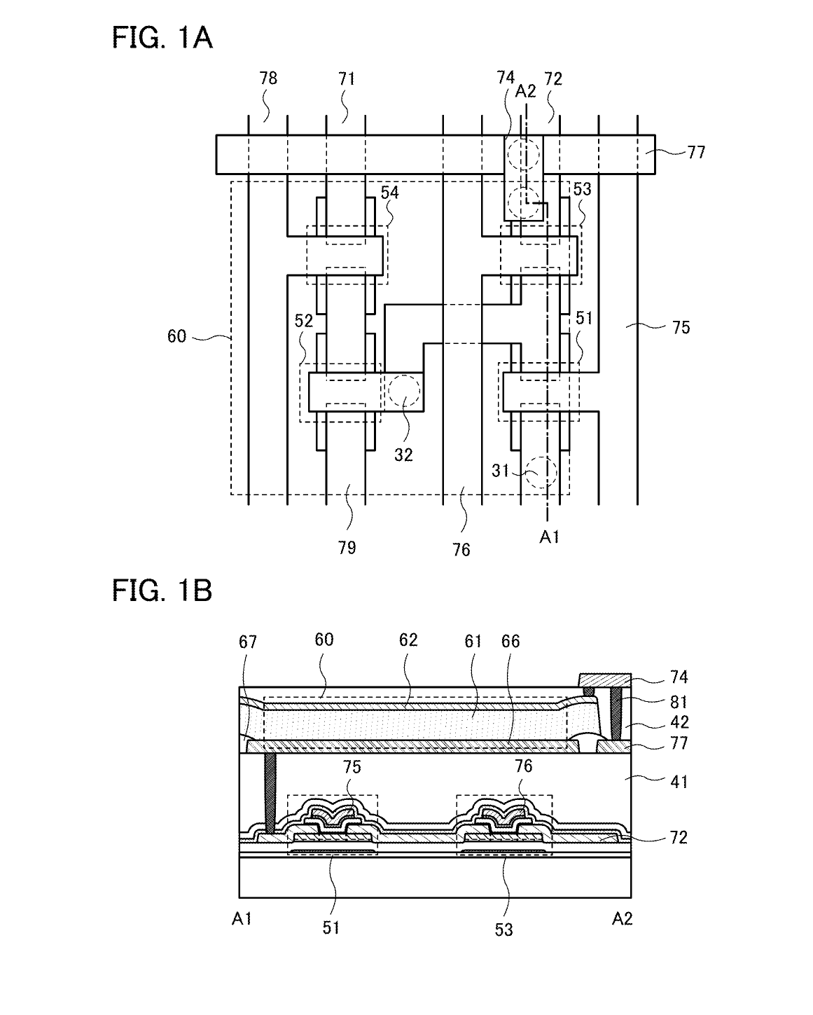

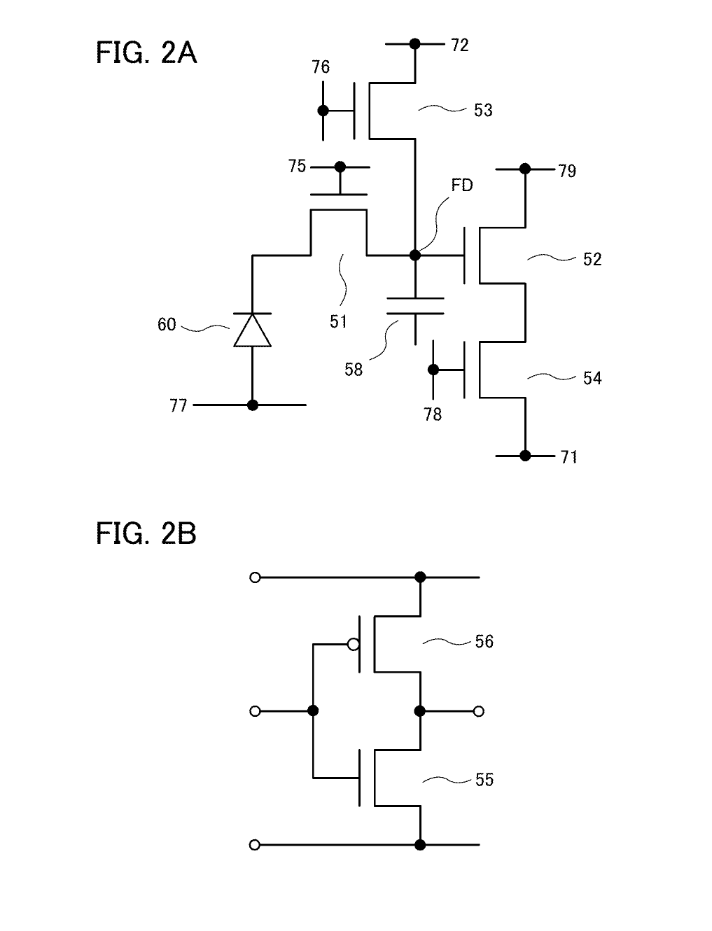

FIG. 1A is a top view of the imaging device of one embodiment of the present invention and shows an example of a specific connection between a photoelectric conversion element 60, a transistor 51, a transistor 52, a transistor 53, and a transistor 54 which are included in a pixel circuit illustrated in FIG. 2A. FIG. 1B is a cross-sectional view along line A1-A2 in FIG. 1A. Note that in the above drawings, some components are not illustrated for clarity.

The electrical connection between the above components is only an example. Although the wirings, the electrodes, and a conductor are illustrated as independent components in the drawings, some of them are provided as one component in some cases when they are electrically connected to each other. In addition, an insulating layer 41 and an insulating layer 42 that serve as interlayer insulating films or planarizing films are provided between the components.

For example, an inorganic insulating film such as a silicon oxide film or a silicon oxynitride film can be used as the insulating layers 41 and 42. Alternatively, an organic insulating film such as an acrylic resin film or a polyimide resin film may be used. The top surfaces of the insulating layers 41 and 42 are preferably planarized by a chemical mechanical polishing (CMP) method or the like.

In the pixel circuit, one of a source electrode and a drain electrode of the transistor 51 is electrically connected to one electrode 66 of the photoelectric conversion element 60. The other of the source electrode and the drain electrode of the transistor 51 is electrically connected to a gate electrode of the transistor 52. The other of the source electrode and the drain electrode of the transistor 51 is electrically connected to one of a source electrode and a drain electrode of the transistor 53. One of a source electrode and a drain electrode of the transistor 52 is electrically connected to one of a source electrode and a drain electrode of the transistor 54. Although not illustrated in FIGS. 1A and 1B, the other of the source electrode and the drain electrode of the transistor 51 may be electrically connected to one electrode of a capacitor 58 as illustrated in FIG. 2A.

The source or drain electrode of each transistor can serve as a wiring. For example, one of a wiring 71 and a wiring 79 can serve as a power source line and the other can serve as an output line. A wiring 72 can serve as a power source line. A wiring 77 can serve as a power source line (low potential). A wiring 75, a wiring 76, and a wiring 78 can serve be as a signal line for controlling on/off of the transistor. A wiring 74 can serve as a connection wiring.

The transistor 51 functions as a transfer transistor for controlling the potential of a charge storage portion (FD) in response to the output of the photoelectric conversion element 60. The transistor 52 functions as an amplifying transistor configured to output a signal corresponding to the potential of the charge storage portion (FD). The transistor 53 functions as a reset transistor for initializing the potential of the charge storage portion (FD). The transistor 54 functions as a selection transistor for selecting a pixel.

In some cases, one or more of the wirings are not provided or another wiring or transistor is included in each layer.

A transistor including an oxide semiconductor in an active layer (hereinafter referred to as an OS transistor) can be used as the transistors 51 to 54.

Extremely low off-state current characteristics of the OS transistor can widen the dynamic range of image-capturing. In the circuit shown in FIG. 2A, an increase in the intensity of light entering the photoelectric conversion element 60 reduces the potential of the charge storage portion (FD). Since the transistor using an oxide semiconductor has an extremely low off-state current, a current corresponding to the gate potential can be accurately output even when the gate potential is extremely low. Thus, it is possible to widen the detection range of illuminance, i.e., the dynamic range.

A period during which charge can be retained in the charge storage portion (FD) can be extremely long owing to the low off-state current characteristics of the transistors 51 and 53. Therefore, a global shutter system, in which charge accumulation operation is performed in all the pixel circuits at the same time, can be used without a complicated circuit configuration and operation method, and thus, an image with little distortion can be easily obtained even in the case of a moving object.

In addition, the OS transistor has lower temperature dependence of change in electrical characteristics than the Si transistor, and thus can be used in an extremely wide range of temperatures. Therefore, an imaging device and a semiconductor device which include OS transistors are suitable for use in automobiles, aircrafts, and spacecrafts.

Furthermore, the OS transistor has higher drain breakdown voltage than the Si transistor. In a photoelectric conversion element including a selenium-based material in a photoelectric conversion layer, a relatively high voltage (e.g., 10 V or more) is preferably applied to easily cause the avalanche phenomenon. Therefore, by combination of the OS transistor and the photoelectric conversion element including a selenium-based material in the photoelectric conversion layer, a highly reliable imaging device can be obtained.

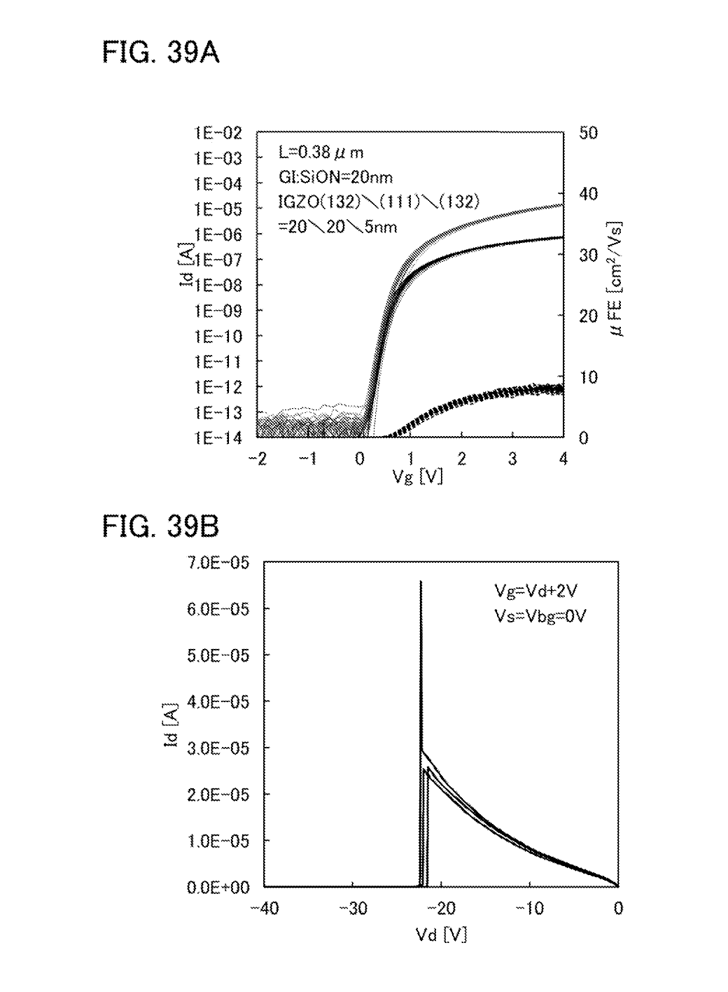

FIG. 39A shows the Id−Vg characteristics of transistors (n-channel, L/W=0.38 μm/0.81 μm, Tox=20 nm, ε=4.1). Each of the transistors includes a silicon oxynitride film as a gate insulating film and includes layered In—Ga—Zn oxide films (a 20-nm-thick oxide film with an atomic ratio of In to Ga and Zn=1:3:2, a 20-nm-thick oxide film with an atomic ratio of In to Ga and Zn=1:1:1, and a 5-nm-thick oxide film with an atomic ratio of In to Ga and Zn=1:3:2). FIG. 39B shows measurement data on the drain breakdown voltage of the transistors.

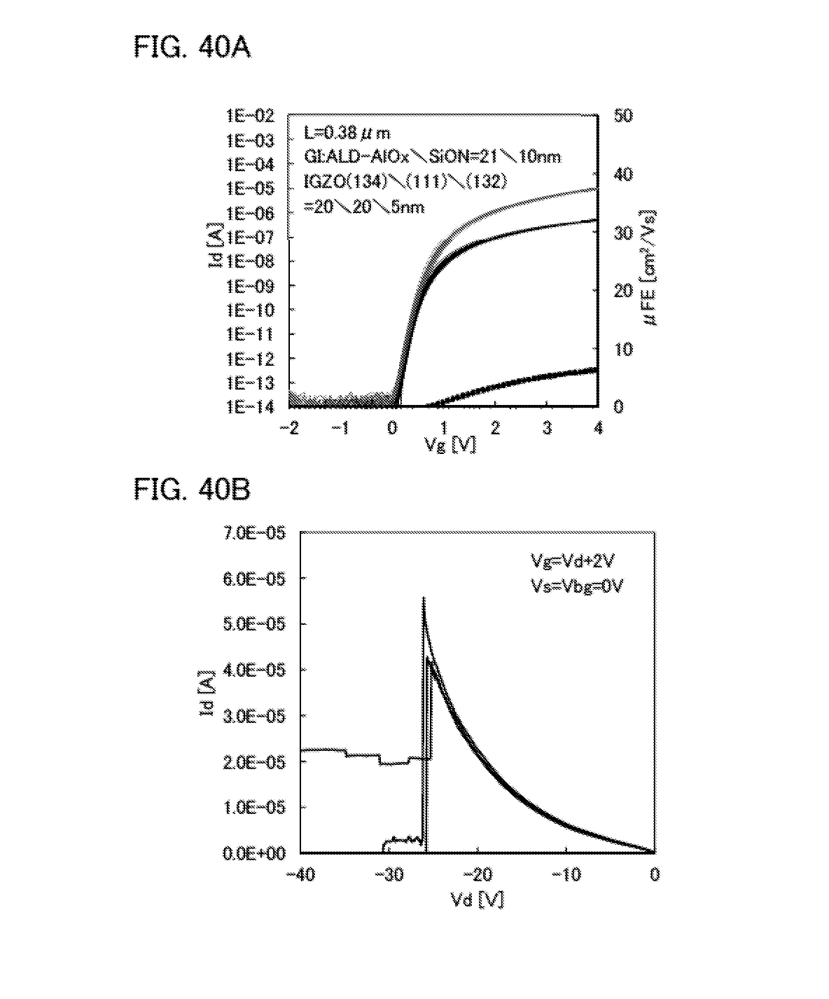

FIG. 40A shows the Id−Vg characteristics of transistors (n-channel, L/W=0.38 μm/0.81 μm, Tox=31 nm, ε=6.3). Each of the transistors includes layered gate insulating films (an aluminum oxide film and a silicon oxynitride film) and layered In—Ga—Zn oxide films (a 20-nm-thick oxide film with an atomic ratio of In to Ga and Zn=1:3:4, a 20-nm-thick oxide film with an atomic ratio of In to Ga and Zn=1:1:1, and a 5-nm-thick oxide film with an atomic ratio of In to Ga and Zn=1:3:2). FIG. 40B shows measurement data on the drain breakdown voltage of the transistors.

Note that the Id−Vg characteristics are measured at Vd=0.1 V and 3.3 V and the mobility is denoted by dotted lines. The drain breakdown voltage is measured at Vg=Vd+2 V and the vertical axis Id [A] represents gate-drain current values. The aforementioned atomic ratios are those of sputtering target materials that are used when an In—Ga—Zn oxide film is formed by a sputtering method.

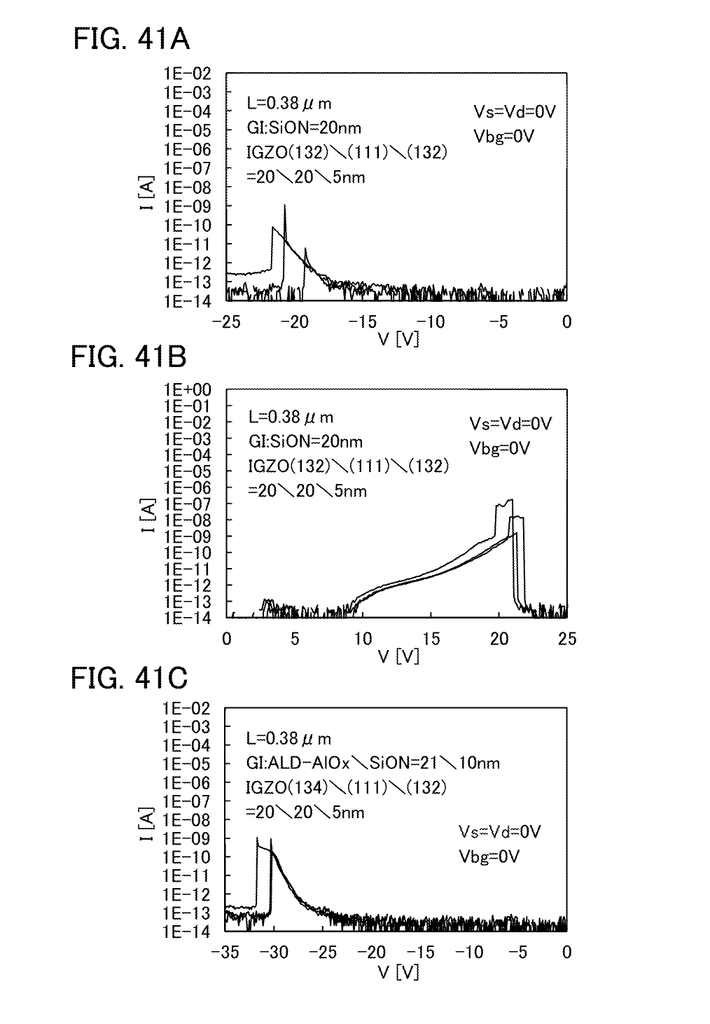

FIGS. 41A and 41B show measurement data on the gate breakdown voltage of the transistors in FIG. 39A. The data in FIG. 41A is obtained by sweeping the gate voltage in the negative direction, whereas the data in FIG. 41B is obtained by sweeping the gate voltage in the positive direction.

FIG. 41C shows measurement data on the gate breakdown voltage of the transistors in FIG. 40A, which is obtained by sweeping the gate voltage of the transistors in the negative direction.

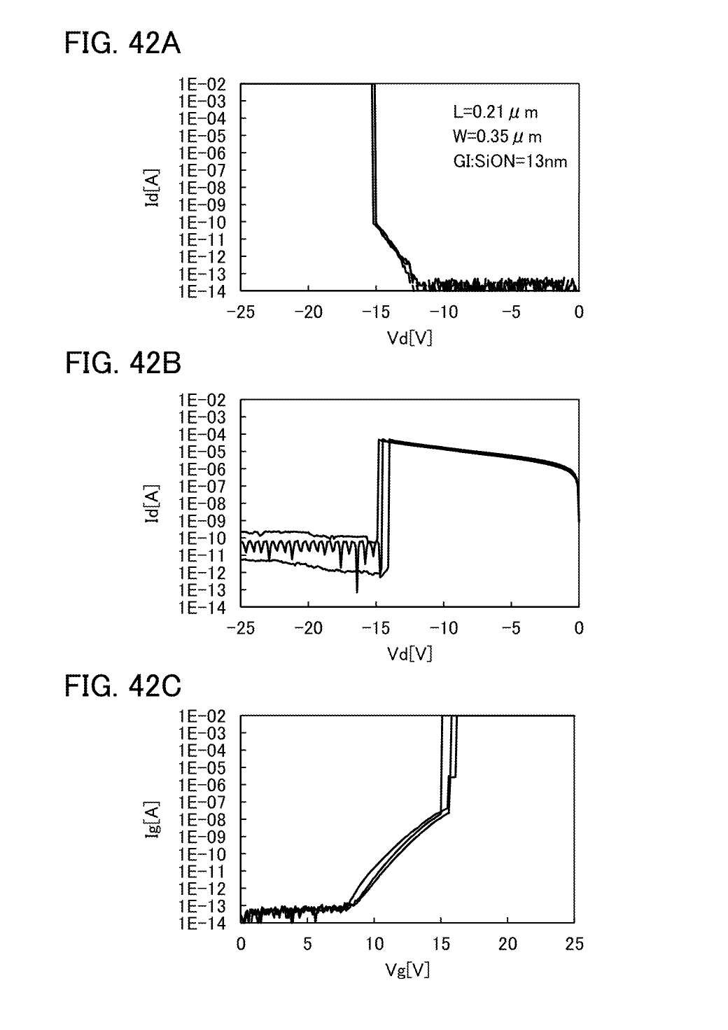

FIGS. 42A to 42C show the breakdown voltage characteristics of minute transistors each of which has an L of 0.21 μm and W of 0.35 μm and includes a 13-nm-thick silicon oxynitride film as a gate insulating film. FIG. 42A shows drain breakdown voltage. FIG. 42B shows gate breakdown voltage obtained by sweeping the gate voltage in the negative direction. FIG. 42C shows gate breakdown voltage obtained by sweeping the gate voltage in the positive direction.

The above indicates that OS transistors have extremely high drain breakdown voltage and gate breakdown voltage.

In order to quite precisely determine the charge accumulated in the charge storage portion (FD), a transistor connected to the charge storage portion (FD) needs to have a low noise level.

The error due to noise occurs at random, whereas the error of device electrical characteristics is in relation to time. The error in relation to time can be removed relatively easily by, for example, signal processing using a correlated double sampling circuit or the like.

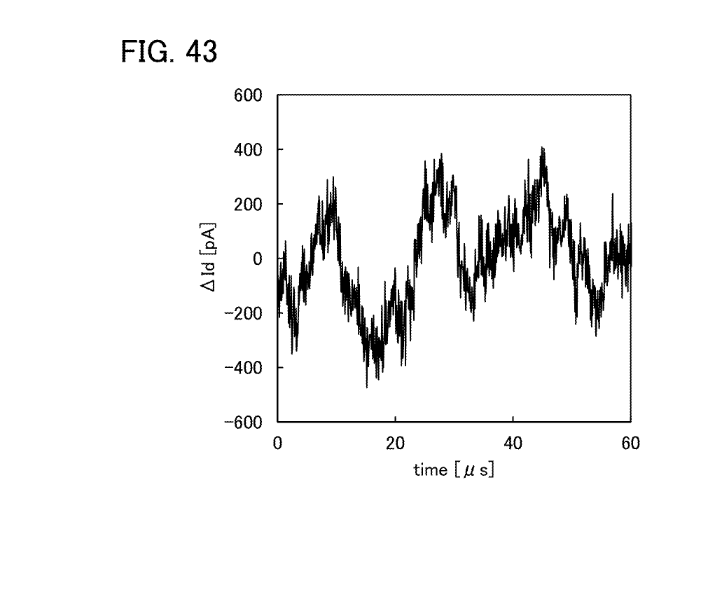

FIG. 43 shows the amount of change in drain current due to noise with time, which indicates that the drain current varies randomly with time.

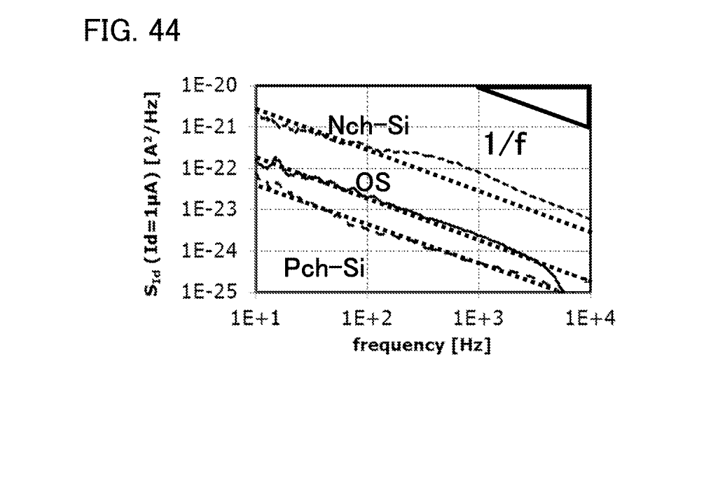

If 1/f noise is the main factor of noise included in the current values shown in FIG. 43, the noise should be in relation to frequency. FIG. 44 shows the relationship between frequency in the range of 10 Hz to 10 kHz and drain current spectral density (hereinafter referred to as S_{Id}), which is calculated from the data in FIG. 43. FIG. 44 indicates that S_{Id} is reduced by one digit with one-digit increase in frequency, i.e., S_{Id} is inversely proportional to frequency (1/f).

There have been proposed two models of such a noise: a carrier number fluctuation model due to carrier creation and annihilation (also referred to as carrier generation and re-combination), and a mobility fluctuation model due to phonon scattering.

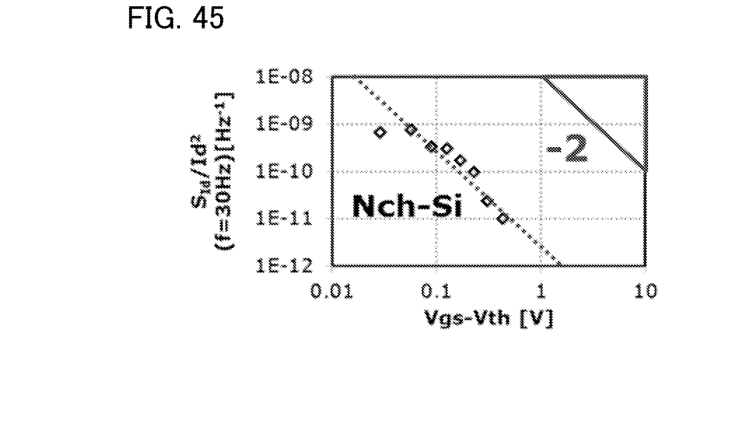

In the case of the carrier number fluctuation model due to carrier creation and annihilation, as shown in FIG. 45, S_{Id} normalized on Id (the value obtained by dividing S_{Id} by Id²) has a slope of −2 with respect to a voltage obtained by subtracting the threshold voltage (hereinafter referred to as Vth) of a transistor from Vgs. This suggests that a relation of 1/(Vgs−Vth)² is satisfied. This model is probably applied to an n-channel silicon transistor (hereinafter referred to as Si transistor).

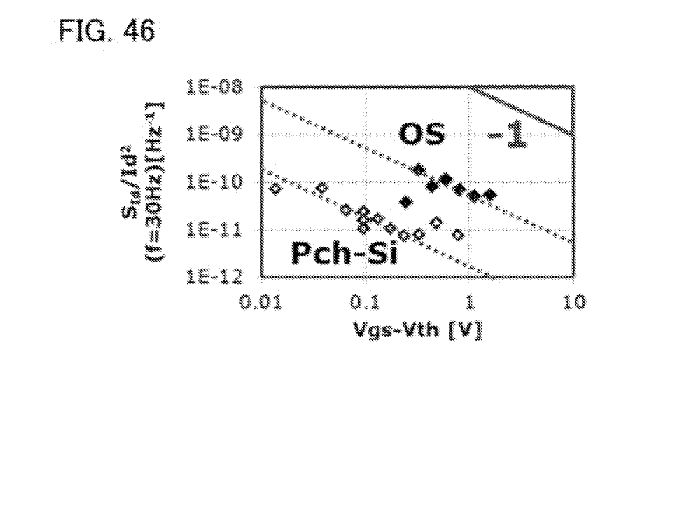

In the case of the mobility fluctuation model due to phonon scattering, as shown in FIG. 46, S_{Id} normalized on Id has a slope of −1 with respect to a voltage obtained by subtracting Vth from Vgs. This suggests that a relation of 1/(Vgs−Vth) is satisfied. This model is probably applied to a p-channel Si transistor and could also be applied to an n-channel OS transistor.

Furthermore, in the mobility fluctuation model, S_{Id} normalized on Id is proportional to Id, which means that noise is reduced as a function of Id. Such a feature is advantageous to OS transistors which operate with lower current than Si transistors and the like, and low noise and high performance image sensor and memory could be achieved.

A hump in the graph showing the relationship between S_{Id} and frequency is generally considered due to creation and annihilation. In FIG. 44, S_{Id} of an n-channel Si transistor goes over an auxiliary line of 1/f at around 100 Hz to 1 kHz. In contrast, no hump is observed in the graph of an OS transistor. These facts also support the results shown in FIG. 45 and FIG. 46. That is, creation and annihilation are unlikely to occur in the OS transistor and charge generated in the photoelectric conversion element 60 is unlikely to increase and decrease in the transistor 51.

The 1/f noise characteristics of the n-channel OS transistor were measured using a test transistor, and the results will be described below.

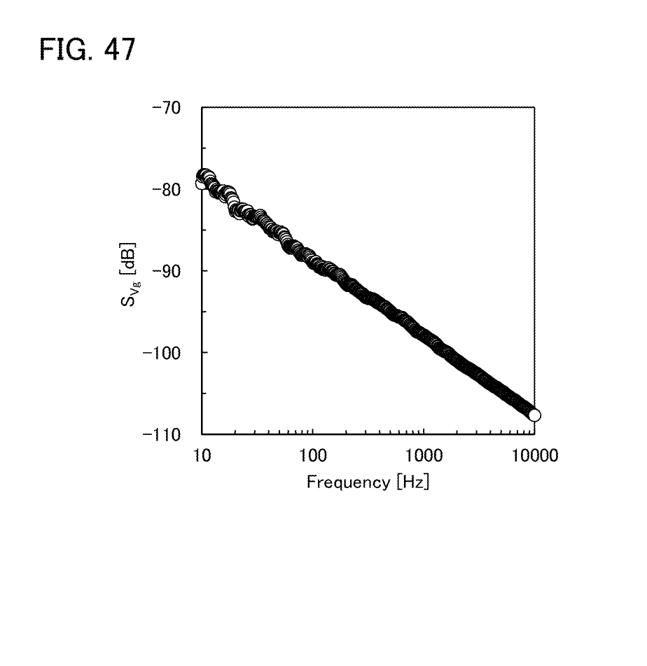

The test transistor has an L/W of 0.8 μm/0.8 μm (the thickness of active layer d: 20 nm). FIG. 47 shows the 1/f noise characteristics. In FIG. 47, the horizontal axis represents frequency in the range of 10 Hz to 10 kHz, and the vertical axis represents power spectral density of gate voltage (hereinafter referred to as Sv_{g}).

The measurement was performed at a substrate temperature of room temperature, a source-drain voltage (Vd) of 1.8 V, and a constant source-gate voltage (Vg). In these conditions, a change in Sv_{g}, i.e., frequency-Sv_{g} characteristics were measured.

Note that the measurement was performed using a semiconductor device analyzer, Agilent B1500, and a signal source analyzer, Agilent E5052B. The measurement range is within the specifications of voltage and current of the analyzers (200 V/1 A or 100 V/100 mA) and the specifications of frequency (5 Hz to 40 MHz).

As shown in FIG. 47, Sv_{g} is approximately −80 dB at 10 Hz, approximately −90 dB at 100 Hz, approximately −100 dB at 1 kHz, and approximately −110 dB at 10 kHz. That is, Sv_{g} is inversely proportional to frequency; 1/f noise is reduced by approximately 10 dB as frequency is increased by one digit.

In pixel circuits illustrated in FIGS. 2A and 2B, to correctly set the potential of the gate of the transistor 52 (the potential of the charge storage portion FD), noise due to a transistor (such as the transistor 51) needs to have a predetermined value or less. In other words, the transistor noise has to be low enough to satisfy the circuit specifications. The noise affecting circuits operating in the frequency range except high frequency is mainly 1/f noise.

For example, in the case where N [level] is represented by a potential difference E [V] and no special correction is performed, the potential difference for one gray level is E/N [V]. Hence, the circuit noise needs to be lower than at least the potential difference for one gray level. Specifically, the noise is preferably as close to 0 as possible, i.e., 1/10 times (−10 dB), preferably 1/100 times (−20 dB), more preferably 1/1000 times (−30 dB) of the potential difference for one gray level.

The 1/f noise converted from the current of a transistor including an oxide semiconductor is approximately −80 dB at 10 Hz. Accordingly, a 1/f noise V2 for a signal V1 is V2≈V1×10^{(-80[dB]/20)}=V1×10⁻⁴.

In the case where the potential difference for one gray level, the minimum gray level, is 10 mV, the potential error due to 1/f noise is 10 mV×10⁻⁴=0.001 mV. This value is equivalent to 10⁻⁴ gray levels; thus, the gray level error due to noise is considered to be extremely close to 0. Accordingly, the 1/f noise of the transistor including an oxide semiconductor can sufficiently meet the noise standard necessary for the potential difference for one gray level.

In the case where the potential difference for 256 gray levels, the maximum gray level, is 256×10 mV=2560 mV, the potential error due to 1/f noise is 2560 mV×10⁻⁴=0.256 mV. This value is equivalent to 0.256 mV/10 mV=0.0256 gray levels; thus, the 1/f noise of the transistor including an oxide semiconductor can sufficiently meet the noise standard necessary for the potential difference for 256 gray levels.

In addition, the gray level error due to noise can be considered to be sufficiently close to 0 because the electrical characteristics affecting a device size and components have an error of several percent to ten percent. For example, in the case where the electrical characteristics of a device have an error of 1%, the gray level error is 2560 mV×0.01=25 mV (2.5 gray levels); and in the case of an error of 10%, the gray level error is 2560 mV×0.1=250 mV (25 gray levels). In contrast, the gray level error due to 1/f noise is sufficiently as low as approximately 1/100 to 1/1000.

In order to reduce noise, it is preferable to reduce factors contributing to generation of noise between elements in the circuit. For example, in the case where a noise causing factor exists in an electrical connection portion between the photoelectric conversion element 60 and one of the source electrode and the drain electrode of the transistor 51 through which a low current flows, charge in the charge storage portion (FD) cannot be output accurately. The same problem arises also in the case where a noise causing factor exists in a connection portion between the charge storage portion (FD) and the other of the source electrode and the drain electrode of the transistor 51.

In the case where a noise causing factor exists in a connection portion between the transistor 53 and the charge storage portion (FD), the initialization of the charge storage portion (FD) cannot be performed accurately. In the case where a noise causing factor exists in a connection portion between the source and drain electrodes of the transistor 52 and components connected thereto, a correct output value cannot be obtained in some cases even when the charge storage portion (FD) has a correct potential. Further, in the case where a noise causing factor exists in a connection portion between the source and drain electrodes of the transistor 54 and components connected thereto, a correct output value cannot be obtained in some cases even when the transistor 52 outputs a correct value.

To solve the above problems, elements are preferably electrically connected to each other in a single region. In the case where electrical connection is performed in plural regions, different noises are generated in the respective regions. Hence, the electrical connection between elements is preferably performed in a single region to prevent generation of plural kinds of noises.

Furthermore, the amount of noise is proportional to the area of a region where elements are electrically connected, and therefore the area is preferably as small as possible. For example, the region preferably has a substantially square or circular top shape whose one side or diameter is less than a wiring design rule. Specifically, the side or diameter of the region is preferably less than the width of a wiring.

In general, except when an electrode or the like of an element extends to be shared with an electrode of another element, the elements are electrically connected by providing a plurality of openings in an insulating film in contact with the electrodes of the elements and providing a contact plug or a wiring in the openings. The plurality of openings prevent defect openings and the like redundantly. However, the plurality of openings are not necessarily provided if the yield of the opening is sufficiently high.

Hence, in one embodiment of the present invention, one of the source electrode and the drain electrode of the transistor 51 is electrically connected to one electrode of the photoelectric conversion element 60 in a single opening 31 as illustrated in FIG. 1A. The opening 31 is provided in an insulating layer formed between the one of the source electrode and the drain electrode of the transistor 51 and the one electrode of the photoelectric conversion element 60.

Moreover, the other of the source electrode and the drain electrode of the transistor 51 is electrically connected to the gate electrode of the transistor 52 in a single opening 32. The opening 32 is provided in an insulating layer formed between the other of the source electrode and the drain electrode of the transistor 51 and the gate electrode of the transistor 52. The insulating layer specifically serves as a gate insulating film of the transistors.

A source electrode and a drain electrode of an OS transistor have a favorable contact surface with an oxide semiconductor layer and also serve as wirings. Therefore, a circuit including the OS transistor has a smaller number of noise causing factors between elements in the circuit than a circuit including a Si transistor.

In addition, the use of an oxide semiconductor for the transistor 51 which controls the storage operation in the pixel circuit makes noise as close to 0 as possible as described above. In such a circuit configuration, charge accumulated in the gate of the transistor 52 can be determined quite precisely. That is, the pixel circuit of one embodiment of the present invention allows incident light to be converted into a correct electric signal.

In the photoelectric conversion element 60, a selenium-based material, which has high external quantum efficiency to visible light, is preferably used for a photoelectric conversion layer 61. Such a photoelectric conversion element can be a highly sensitive sensor in which the amount of amplification of electrons with respect to the amount of incident light is large because of avalanche multiplication. In other words, the use of a selenium-based material for the photoelectric conversion layer 61 allows a sufficient amount of photocurrent to be obtained even when the pixel area is reduced. Moreover, because of being highly sensitive to light, the photoelectric conversion element using a selenium-based material is also suitable for image-capturing in a low-illuminance environment. Furthermore, the selenium-based material has a high light-absorption coefficient, making the photoelectric conversion layer 61 thin easily.

Amorphous selenium or crystalline selenium can be used as the selenium-based material. Crystalline selenium can be obtained by, for example, depositing amorphous selenium and then performing heat treatment. When the crystal grain size of crystalline selenium is smaller than a pixel pitch, variation in characteristics between pixels can be reduced. Moreover, crystalline selenium has higher spectral sensitivity and light-absorption coefficient than those of amorphous selenium.

The photoelectric conversion layer 61 may include a compound of copper, indium, and selenium (CIS). Alternatively, a layer including a compound of copper, indium, gallium, and selenium (CIGS) may be used. A photoelectric conversion element including the CIS layer or the CIGS layer can also utilize avalanche multiplication like the photoelectric conversion element including selenium alone.

In the photoelectric conversion element 60 using the selenium-based material, for example, the photoelectric conversion layer 61 can be provided between a light-transmitting conductive layer 62 and the electrode 66 formed using a metal material or the like. Furthermore, to prevent leakage current and the like, an oxide semiconductor layer containing zinc oxide or the like may be provided in contact with the photoelectric conversion layer 61.

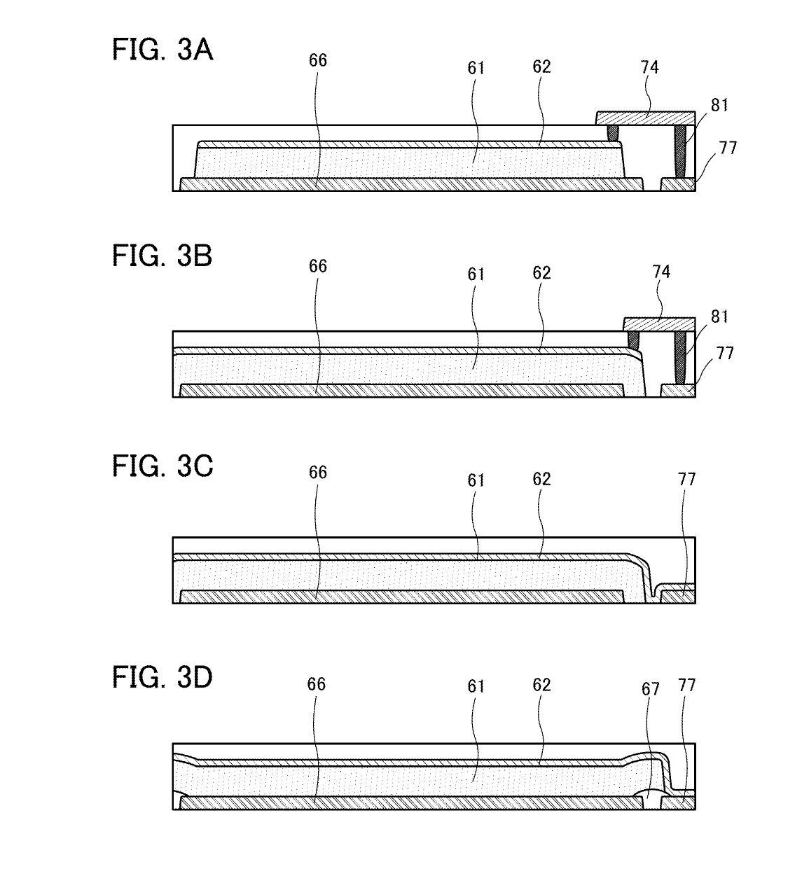

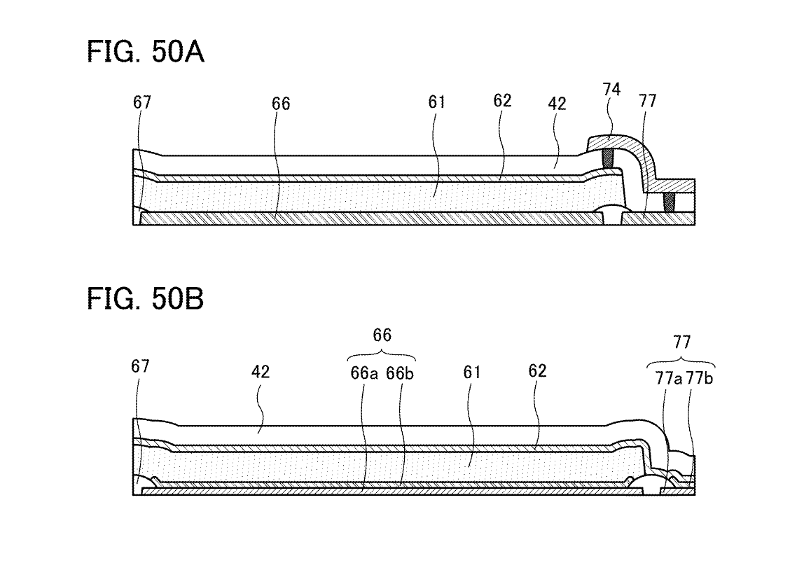

Although the photoelectric conversion layer 61 and the light-transmitting conductive layer 62 are not divided between pixels in FIGS. 1A and 1B, they may be divided between circuits as illustrated in the cross-sectional view of FIG. 3A. In a region between pixels where the wiring 77 and the electrode 66 are not provided, a partition wall 67 formed of an insulator is preferably provided as illustrated in FIG. 1B, thereby preventing generation of a crack in the photoelectric conversion layer 61 and the light-transmitting conductive layer 62. However, the partition wall 67 is not necessarily provided as illustrated in FIG. 3B. Alternatively, as illustrated in FIGS. 3C and 3D, the light-transmitting conductive layer 62 may be in direct contact with the wiring 77. The insulating layer 42 is not necessarily planarized as illustrated in FIG. 50A

The electrode 66, the wiring 77, and the like may each be a multilayer. For example, as illustrated in FIG. 50B, the electrode 66 can include two conductive layers 66a and 66b and the wiring 77 can include two conductive layers 77a and 77b. In the structure in FIG. 50B, for example, the conductive layers 66a and 77a may be made of a low-resistance metal or the like, and the conductive layers 66b and 77b may be made of a metal or the like that exhibits an excellent contact property with the photoelectric conversion layer 61. Such a structure improves the electrical properties of the photoelectric conversion element. Furthermore, even when the conductive layer 77a contains a metal that causes electrolytic corrosion, which occurs when some kinds of metal are in contact with the light-transmitting conductive layer 62, the electrolytic corrosion can be prevented because the conductive layer 77b is between the conductive layer 77a and the light-transmitting conductive layer 62.

The conductive layers 66b and 77b can be formed using, for example, a metal such as molybdenum or tungsten, or a conductive oxide such as indium tin oxide (ITO) or zinc oxide. The conductive layers 66a and 77a can be formed using, for example, aluminum, titanium, or a stack of titanium, aluminum, and titanium that are layered in this order.

Note that the partition wall 67 can be formed using an inorganic insulator, an insulating organic resin, or the like. The partition wall 67 may be colored black or the like in order to shield the transistors and the like from light and/or to determine the area of a light-receiving portion in each pixel.

A diode element formed using a silicon substrate with a PN junction or a PIN junction can be used as the photoelectric conversion element 60. Alternatively, a PIN diode element formed using an amorphous silicon film, a microcrystalline silicon film, or the like may be used.

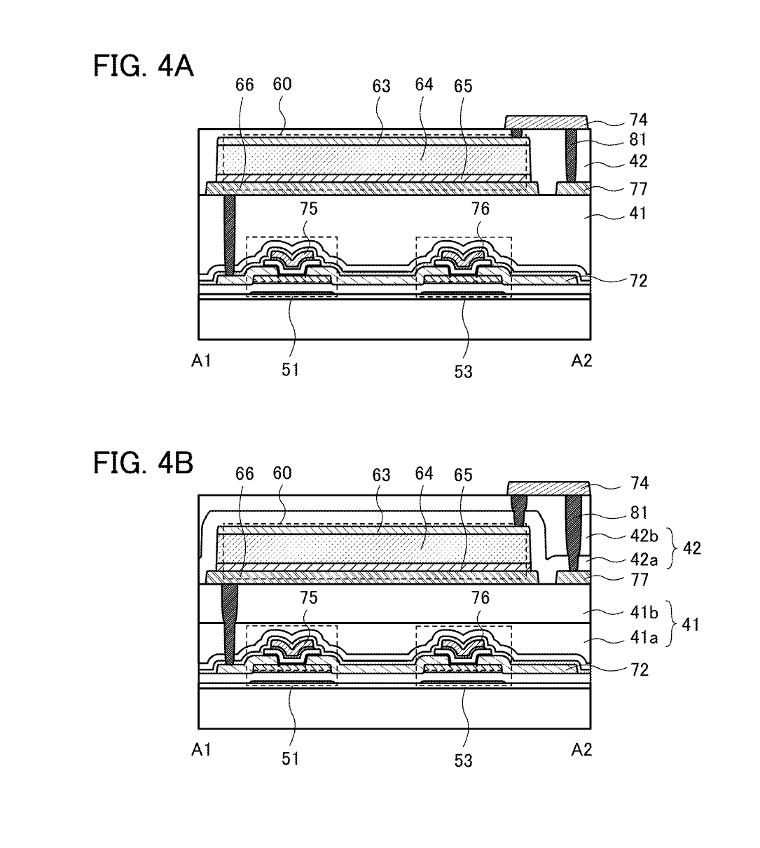

FIG. 4A shows an example in which a thin film PIN photodiode is used as the photoelectric conversion element 60. In the photodiode, an n-type semiconductor layer 65, an i-type semiconductor layer 64, and a p-type semiconductor layer 63 are stacked in this order. The i-type semiconductor layer 64 is preferably formed using amorphous silicon. The p-type semiconductor layer 63 and the n-type semiconductor layer 65 can each be formed using amorphous silicon, microcrystalline silicon, or the like which includes a dopant imparting the corresponding conductivity type. A photodiode in which a photoelectric conversion layer is formed using amorphous silicon has high sensitivity in a visible light wavelength region, and therefore can easily sense weak visible light.

In the photoelectric conversion element 60 illustrated in FIG. 4A, the n-type semiconductor layer 65 functioning as a cathode is electrically connected to the electrode 66 which is electrically connected to the transistor 51. Furthermore, the p-type semiconductor layer 63 functioning as an anode is electrically connected to the wiring 77.

Note that in the circuit illustrated in FIG. 2A, the photoelectric conversion element 60 may be connected in a manner opposite to that illustrated in FIG. 2A. Therefore, the anode and the cathode are connected to the electrode and the wiring in a manner opposite to that in FIG. 2A in some cases.

In any case, the photoelectric conversion element 60 is preferably formed so that the p-type semiconductor layer 63 serves as a light-receiving surface. When the p-type semiconductor layer 63 serves as a light-receiving surface, the output current of the photoelectric conversion element 60 can be increased.

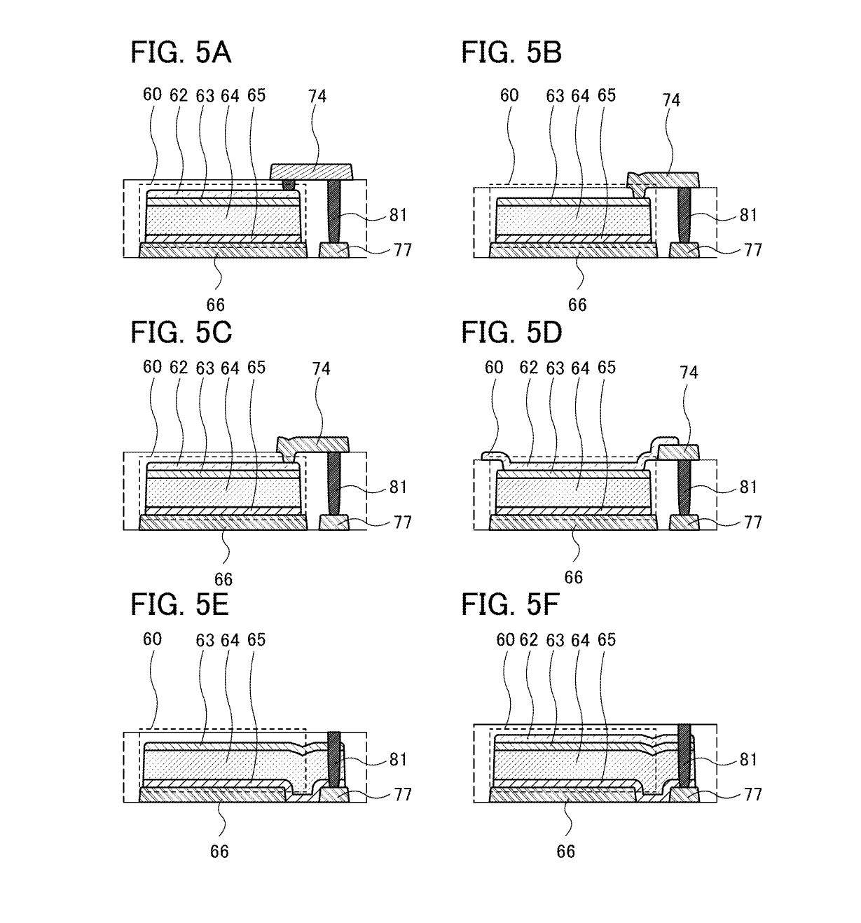

FIGS. 5A to 5F show another examples of the structure of the photoelectric conversion element 60 having a configuration of a PIN thin film photodiode and the connection configuration between the photoelectric conversion element 60 and the wirings. Note that the structure of the photoelectric conversion element 60 and the connection configuration between the photoelectric conversion element 60 and the wirings are not limited thereto and other configurations may be applied.

FIG. 5A illustrates a structure of the photoelectric conversion element 60 that includes the light-transmitting conductive layer 62 in contact with the p-type semiconductor layer 63. The light-transmitting conductive layer 62 serves as an electrode and can increase the output current of the photoelectric conversion element 60.

For the light-transmitting conductive layer 62, the following can be used: indium tin oxide; indium tin oxide containing silicon; indium oxide containing zinc; zinc oxide; zinc oxide containing gallium; zinc oxide containing aluminum; tin oxide; tin oxide containing fluorine; tin oxide containing antimony; graphene; or the like. The light-transmitting conductive layer 62 is not limited to a single layer, and may be a stacked layer of different films.

FIG. 5B illustrates a structure of the photoelectric conversion element 60 in which the p-type semiconductor layer 63 is electrically connected directly to the wiring 74.

FIG. 5C illustrates a structure of the photoelectric conversion element 60 that includes the light-transmitting conductive layer 62 in contact with the p-type semiconductor layer 63 and in which the wiring 74 is electrically connected to the light-transmitting conductive layer 62.

FIG. 5D illustrates a structure in which an opening exposing the p-type semiconductor layer 63 is provided in an insulating layer covering the photoelectric conversion element 60, and the light-transmitting conductive layer 62 that covers the opening is electrically connected to the wiring 74.

FIG. 5E illustrates a structure including a conductor 81 which penetrates the photoelectric conversion element 60. In the structure, the wiring 77 is electrically connected to the p-type semiconductor layer 63 through the conductor 81. Note that in the drawing, the wiring 77 appears to be electrically connected to the electrode 66 through the n-type semiconductor layer 65. However, because of a high resistance in the lateral direction of the n-type semiconductor layer 65, the resistance between the wiring 77 and the electrode is extremely high when there is an appropriate distance therebetween. Thus, the photoelectric conversion element 60 can have diode characteristics without a short circuit between the anode and the cathode.

FIG. 5F illustrates a structure in which the photoelectric conversion element 60 in FIG. 5E is provided with the light-transmitting conductive layer 62 in contact with the p-type semiconductor layer 63.

Note that each of the photoelectric conversion elements 60 illustrated in FIGS. 5D to 5F has an advantage of having a large light-receiving area because wirings and the like do not overlap with a light-receiving region.

As illustrated in FIG. 4B, the insulating layers 41 and 42 may each be a multilayer. As illustrated in the drawing, the conductor 81 has a step in the case where the insulating layer 41 includes an insulating layer 41a and an insulating layer 41b that have different etching rates. The same applies to the case where the insulating layer 42 includes an insulating layer 42a and an insulating layer 42b.

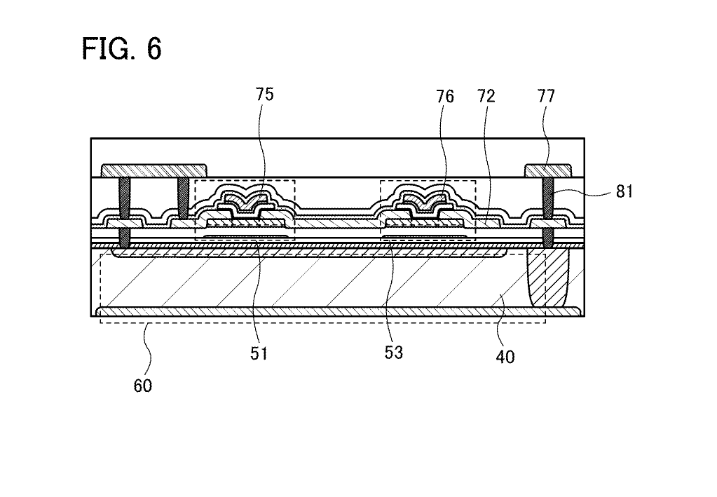

Alternatively, as illustrated in FIG. 6, the photoelectric conversion element 60 may be a photodiode including a silicon substrate 40 used as a photoelectric conversion layer.

The photoelectric conversion element 60 formed using the aforementioned selenium-based material, amorphous silicon, or the like can be fabricated through general semiconductor manufacturing processes such as a deposition process, a lithography process, and an etching process. In addition, because the resistance of the selenium-based material is high, the photoelectric conversion layer 61 does not need to be divided between circuits as illustrated in FIG. 1B. Hence, the imaging device of one embodiment of the present invention can be manufactured with a high yield at low cost. In contrast, a photodiode including a crystalline silicon substrate used as the photoelectric conversion layer requires difficult processes such as a polishing process and a bonding process.

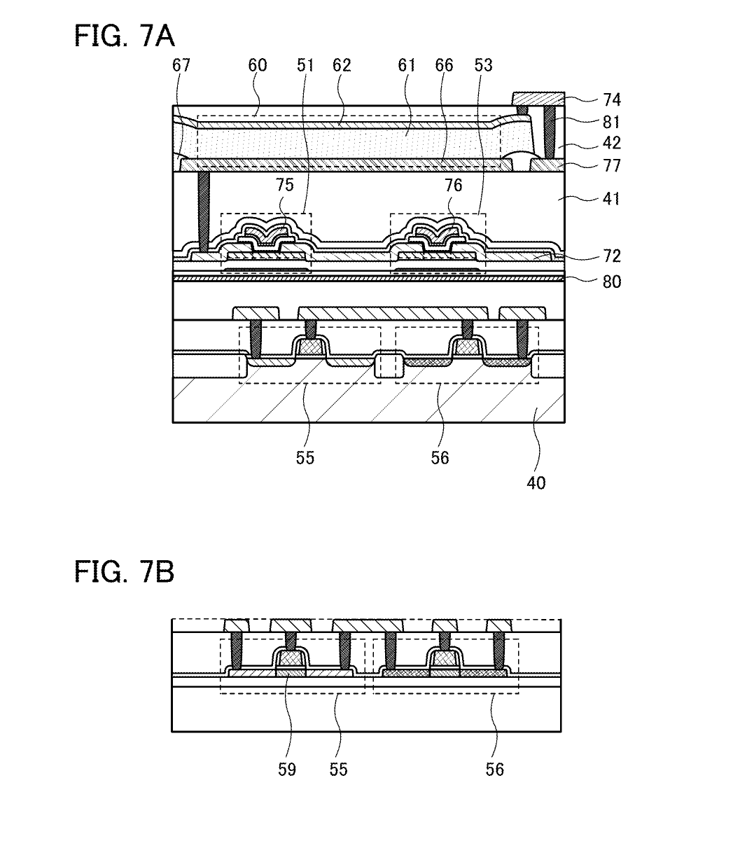

Furthermore, the imaging device of one embodiment of the present invention may be stacked over the silicon substrate 40 including circuits. For example, as illustrated in FIGS. 7A and 7B, the pixel circuit may overlap with a transistor 55 and a transistor 56 whose active regions are formed in the silicon substrate 40.

The circuit formed in the silicon substrate 40 can be configured to read a signal output from the pixel circuit and convert the signal; for example, the circuit may include a CMOS inverter as illustrated in the circuit diagram in FIG. 2B. A gate of the transistor 55 (n-channel) is electrically connected to a gate of the transistor 56 (p-channel). One of a source and a drain of one of the transistors 55 and 56 is electrically connected to one of a source and a drain of the other transistor. The other of the source and the drain of each transistor is electrically connected to a different wiring.

The silicon substrate 40 is not limited to a bulk silicon substrate and can be a substrate made of germanium, silicon germanium, silicon carbide, gallium arsenide, aluminum gallium arsenide, indium phosphide, gallium nitride, or an organic semiconductor.

As illustrated in FIG. 7B, the transistors 55 and 56 may each include an active layer 59 formed of a silicon thin film. The active layer 59 can be formed using polycrystalline silicon or single crystal silicon of a silicon-on-insulator (SOI) structure.

In the above stack, an insulating layer 80 is provided between a layer including the transistors 55 and 56 and a layer including the transistors 51 and 53.

Dangling bonds of silicon are terminated with hydrogen in insulating layers provided in the vicinities of the active regions of the transistors 55 and 56. Therefore, the hydrogen has an effect of improving the reliability of the transistors 55 and 56. Meanwhile, hydrogen in insulating layers provided in the vicinity of the oxide semiconductor layer that is the active layer of the transistor 51 or the like causes generation of carriers in the oxide semiconductor layer, and therefore may reduce the reliability of the transistor 51 or the like. Thus, the insulating layer 80 having a function of preventing diffusion of hydrogen is preferably provided between one layer including the transistor using a silicon-based semiconductor material and another layer stacked thereon that includes the transistor using an oxide semiconductor. Hydrogen is confined in the one layer by the insulating layer 80, increasing the reliability of the transistors 55 and 56. Furthermore, diffusion of hydrogen from the one layer to the other layer is inhibited, increasing also the reliability of the transistor 51 or the like.

The insulating layer 80 can be formed using, for example, aluminum oxide, aluminum oxynitride, gallium oxide, gallium oxynitride, yttrium oxide, yttrium oxynitride, hafnium oxide, hafnium oxynitride, or yttria-stabilized zirconia (YSZ).

Note that in the structures illustrated in FIGS. 7A and 7B, the circuit formed in the silicon substrate 40 (such as a driver circuit), the transistor 51 and the like, and the photoelectric conversion element 60 can be formed to overlap with each other, resulting in a higher integration degree of pixels, i.e., a higher resolution of the imaging device. Such a structure is suitable for an imaging device with, for example, 4K2K, 8K4K, or 16K8K pixels.

In the imaging device in FIG. 7A, the silicon substrate 40 is not provided with a photoelectric conversion element. Therefore, an optical path to the photoelectric conversion element 60 can be made without being influenced by the transistors or wirings, increasing the aperture ratio of a pixel.

Note that the structure of the transistor and the photoelectric conversion element included in the imaging device in this embodiment is an example. Therefore, for example, one or more of the transistors 51 to 54 may include silicon or the like in an active region or an active layer. Furthermore, one or both of the transistors 55 and 56 may include an oxide semiconductor layer as an active layer.

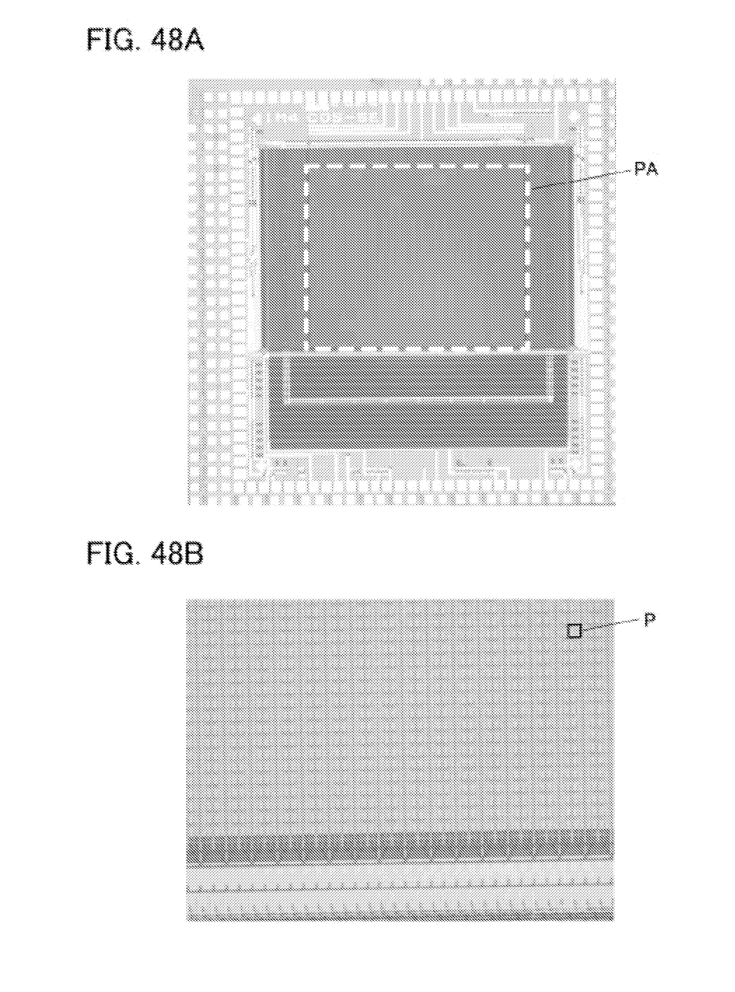

FIG. 48A is a photograph showing a top surface of an imaging device having the structure illustrated in FIG. 7A and 7B before the formation of the photoelectric conversion layer 61. A region PA surrounded by a white dotted line is a pixel region including 174×144 pixels (20 μm×20 μm per pixel). FIG. 48B is an enlarged photograph of part of the pixel region. A region P with a black frame in the photograph is one pixel whose uppermost layer corresponds to the electrode 66.

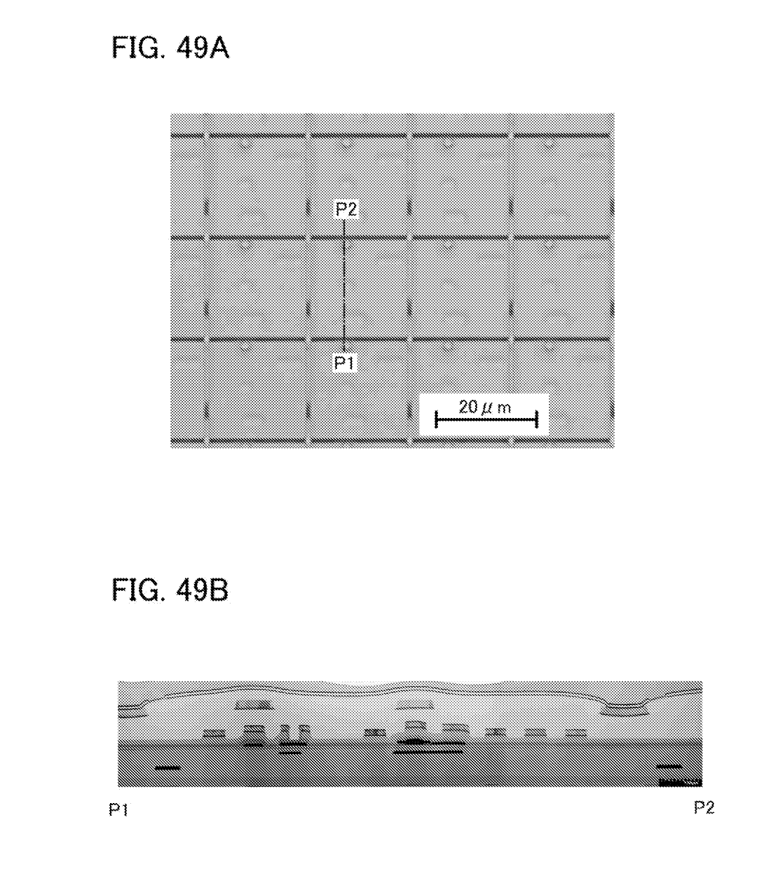

FIG. 49A is a further enlarged photograph of the pixel region, and FIG. 49B shows a cross section along dashed-dotted line P1-P2.

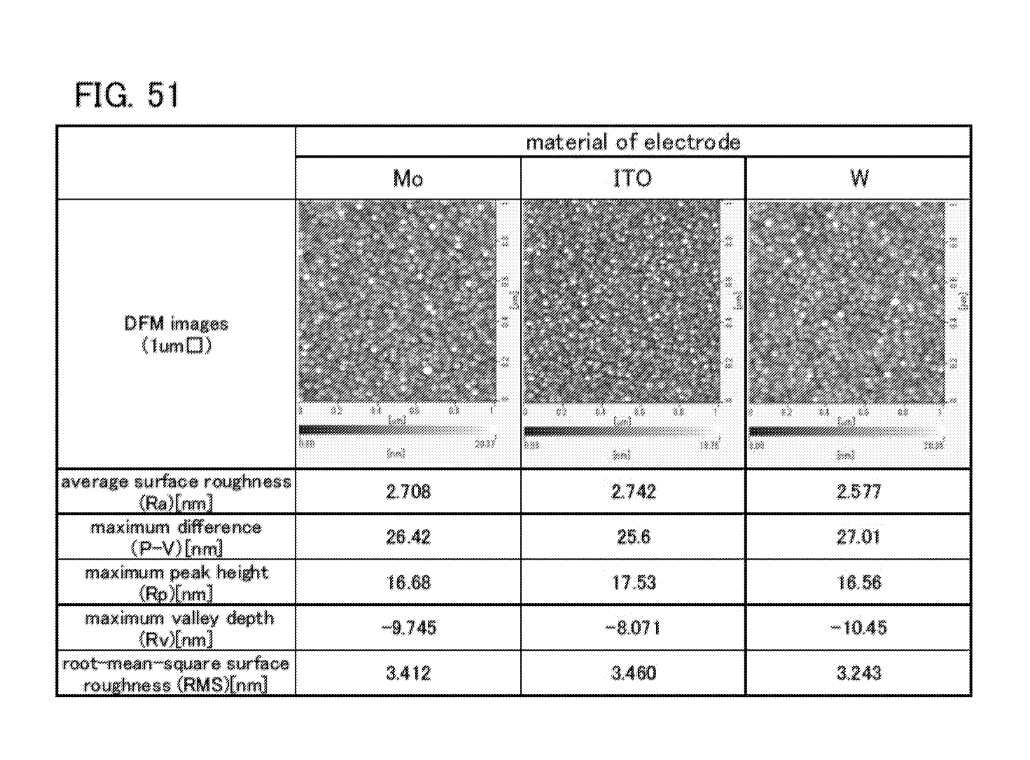

Note that the electrode 66 preferably has high planarity in order to prevent a short circuit with a counter electrode (the light-transmitting conductive layer 62). For example, the maximum difference (P-V) measured using a scanning probe microscope (such as DFM) is preferably less than or equal to 100 nm, more preferably less than or equal to 50 nm, still more preferably less than or equal to 30 nm. The electrode 66 of the imaging device manufactured above, which uses tungsten, exhibits a high planarity surface as shown in FIG. 51 as a measurement result of DFM. Note that FIG. 51 also shows that a high planarity surface can be formed using molybdenum or ITO.

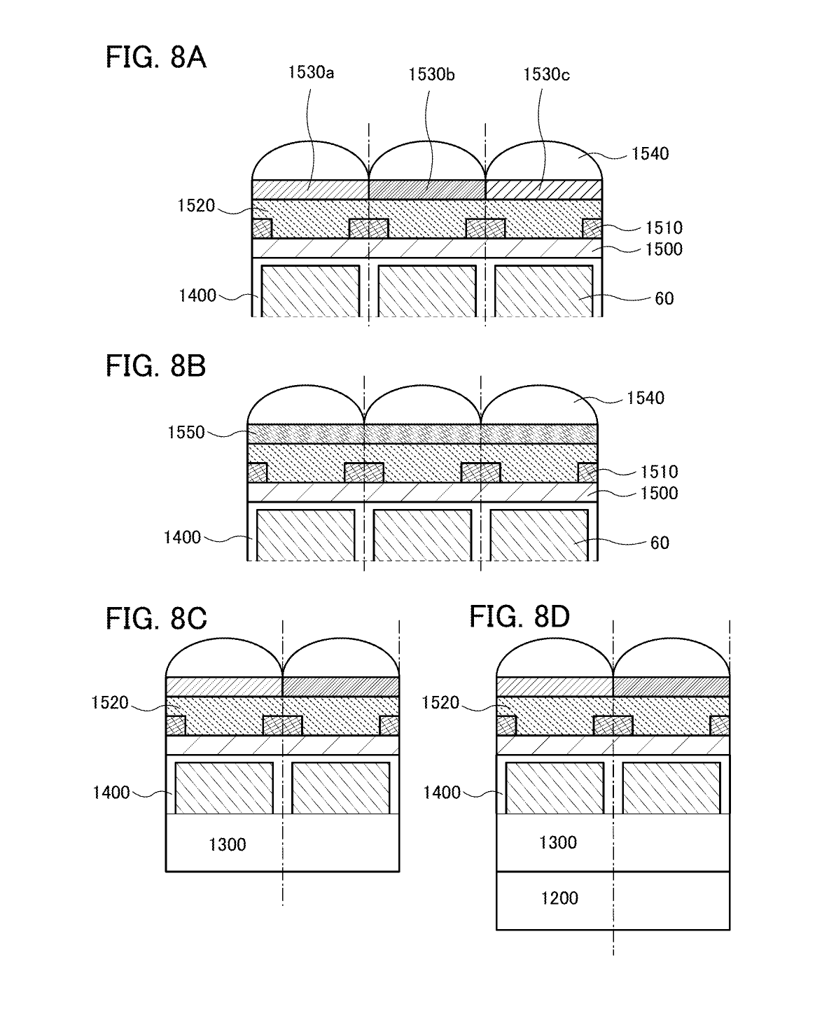

FIG. 8A is a cross-sectional view of an example of a mode in which a color filter and the like are added to the imaging device in FIGS. 1A and 1B, which illustrates part of a region including a pixel circuit for three pixels. An insulating layer 1500 is formed over a region 1400 in which the photoelectric conversion element 60 is formed. As the insulating layer 1500, for example, a silicon oxide film with a high visible-light transmitting property can be used. In addition, a silicon nitride film may be stacked as a passivation film. Furthermore, a dielectric film of hafnium oxide or the like may be stacked as an anti-reflection film.

A light-blocking layer 1510 is formed over the insulating layer 1500. The light-blocking layer 1510 has a function of inhibiting color mixing of light passing through the color filter. The light-blocking layer 1510 can be formed of a metal layer of aluminum, tungsten, or the like, or a stack including the metal layer and a dielectric film functioning as an anti-reflection film.

An organic resin layer 1520 is formed as a planarization film over the insulating layer 1500 and the light-blocking layer 1510. A color filter 1530a, a color filter 1530b, and a color filter 1530c are formed for the respective pixels. Each of the color filters has any of colors of R (red), G (green), B (blue), Y (yellow), C (cyan), and M (magenta), whereby a color image can be obtained.

A microlens array 1540 is provided over the color filters 1530a, 1530b, and 1530c. Thus, light penetrating lenses included in the microlens array 1540 go through the color filters positioned therebelow to reach the photoelectric conversion element. Note that the microlens array 1540 is not necessarily provided.

In the structure of the above imaging device, an optical conversion layer 1550 (see FIG. 8B) may be used instead of the color filters 1530a, 1530b, and 1530c. Such a structure enables the imaging device to capture images in various wavelength regions.

For example, when a filter that blocks light having a wavelength shorter than or equal to that of visible light is used as the optical conversion layer 1550, an infrared imaging device can be obtained. When a filter that blocks light having a wavelength shorter than or equal to that of near infrared light is used as the optical conversion layer 1550, a far-infrared imaging device can be obtained. When a filter that blocks light having a wavelength longer than or equal to that of visible light is used as the optical conversion layer 1550, an ultraviolet imaging device can be obtained.

Furthermore, when a scintillator is used as the optical conversion layer 1550, an imaging device that takes an image visualizing the intensity of radiation and is used for an X-ray imaging device or the like can be obtained. Radiation such as X-rays passes through a subject to enter a scintillator, and then is converted into light (fluorescence) such as visible light or ultraviolet light owing to a phenomenon known as photoluminescence. Then, the photoelectric conversion element 60 detects the light to obtain image data. Furthermore, the imaging device having the structure may be used in a radiation detector or the like.

A scintillator is formed of a substance that, when irradiated with radiation such as X-rays or gamma-rays, absorbs energy of the radial rays to emit visible light or ultraviolet light or a material containing the substance. For example, materials such as Gd₂O₂S:Tb, Gd₂O₂S:Pr, Gd₂O₂S:Eu, BaFCl:Eu, NaI, CsI, CaF₂, BaF₂, CeF₃, LiF, LiI, and ZnO and a resin or ceramics in which any of the materials is dispersed can be used.

In the photoelectric conversion element 60 using a selenium-based material, radiation such as X-rays can be directly converted into electrical charges; thus, the scintillator is not necessarily used.

Note that in an imaging device of one embodiment of the present invention, a region 1300 including an OS transistor may be provided under the region 1400 as illustrated in FIG. 8C. The region 1300 and the region 1400 can have, for example, any of the structures illustrated in FIGS. 1A and 1B, FIGS. 4A and 4B, and FIG. 6.

In another imaging device of one embodiment of the present invention, the region 1300 including an OS transistor may be provided under the region 1400 and a region 1200 including a Si transistor may be provided under the region 1300 as illustrated in FIG. 8D. The region 1200, the region 1300, and the region 1400 can have, for example, any of the structures illustrated in FIGS. 7A and 7B.

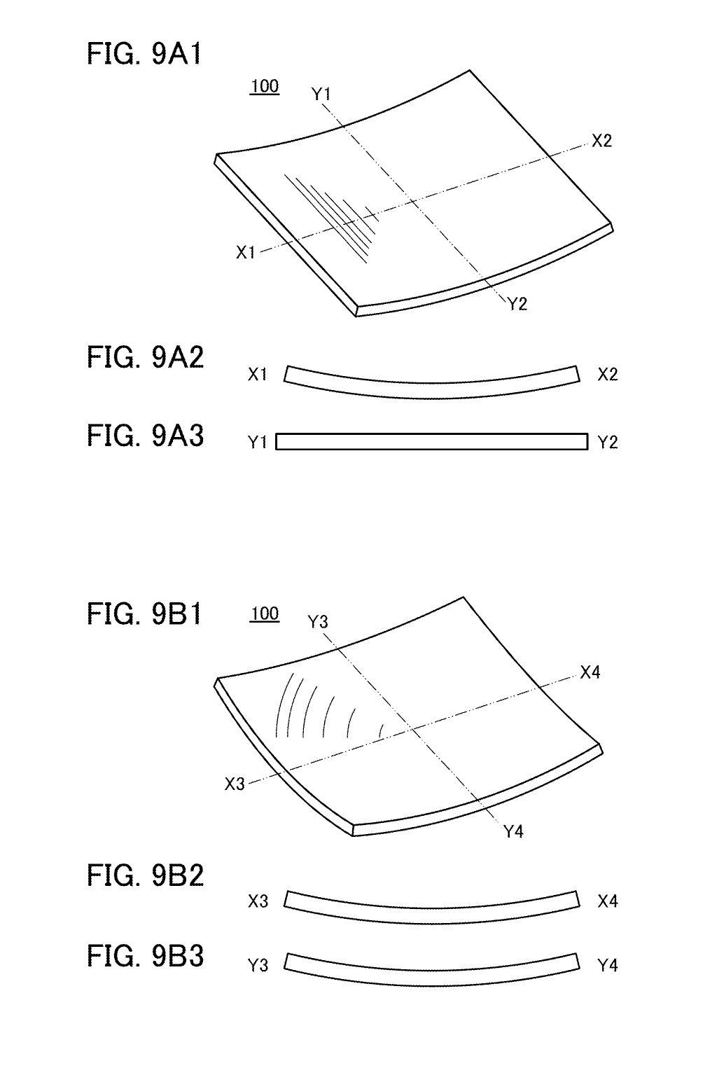

As illustrated in FIGS. 9A1 and 9B1, the imaging device may be bent. FIG. 9A1 illustrates a state in which the imaging device is bent in the direction of dashed-two dotted line X1-X2. FIG. 9A2 is a cross-sectional view illustrating a portion indicated by dashed-two dotted line X1-X2 in FIG. 9A1. FIG. 9A3 is a cross-sectional view illustrating a portion indicated by dashed-two dotted line Y1-Y2 in FIG. 9A1.

FIG. 9B1 illustrates a state where the imaging device is bent in the direction of dashed-two dotted line X3-X4 and the direction of dashed-two dotted line Y3-Y4. FIG. 9B2 is a cross-sectional view illustrating a portion indicated by dashed-two dotted line X3-X4 in FIG. 9B1. FIG. 9B3 is a cross-sectional view illustrating a portion indicated by dashed-two dotted line Y3-Y4 in FIG. 9B1.

Bending the imaging device can reduce field curvature and astigmatism. Thus, the optical design of lens and the like, which are used in combination of the imaging device, can be facilitated. For example, the number of lenses used for aberration correction can be reduced; accordingly, the size or weight of semiconductor devices including the imaging device can be easily reduced. In addition, the quality of a captured image can be improved.

In this embodiment, one embodiment of the present invention has been described. Other embodiments of the present invention are described in the other embodiments. Note that one embodiment of the present invention is not limited thereto. Although an example in which one embodiment of the present invention is applied to an imaging device is described, one embodiment of the present invention is not limited thereto. Depending on circumstances or conditions, one embodiment of the present invention is not necessarily applied to an imaging device. One embodiment of the present invention may be applied to a semiconductor device with another function, for example.

This embodiment can be combined with any of the structures described in the other embodiments and example as appropriate.

### Embodiment 2

In this embodiment, the pixel circuit shown in Embodiment 1 will be described.

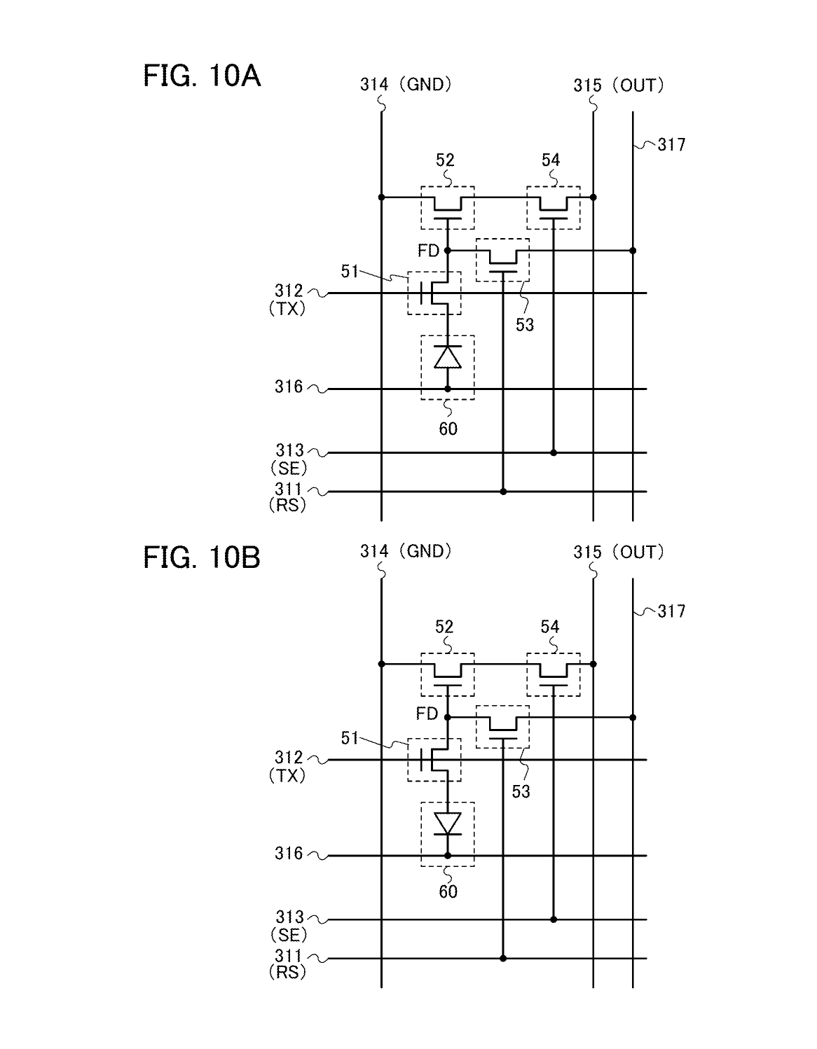

FIG. 10A specifically shows the connection between the pixel circuit in FIG. 2A and a variety of wirings. The circuit in FIG. 10A includes the photoelectric conversion element 60, the transistor 51, the transistor 52, the transistor 53, and the transistor 54.

An anode of the photoelectric conversion element 60 is connected to a wiring 316, and a cathode of the photoelectric conversion element 60 is electrically connected to one of the source and the drain of the transistor 51. The other of the source and the drain of the transistor 51 is connected to the charge storage portion (FD), and a gate of the transistor 51 is connected to a wiring 312 (TX). One of the source and the drain of the transistor 52 is connected to a wiring 314 (GND), the other of the source and the drain of the transistor 52 is connected to one of the source and the drain of the transistor 54, and the gate of the transistor 52 is connected to the charge storage portion (FD). One of the source and the drain of the transistor 53 is connected to the charge storage portion (FD), the other of the source and the drain of the transistor 53 is connected to a wiring 317, and a gate of the transistor 53 is connected to a wiring 311 (RS). The other of the source and the drain of the transistor 54 is connected to a wiring 315 (OUT), and a gate of the transistor 54 is electrically connected to a wiring 313 (SE). Note that all the above connections are electrical connections.

A potential such as GND, VSS, or VDD may be supplied to the wiring 314. Here, a potential or a voltage has a relative value. Therefore, the potential GND is not necessarily 0 V.

The photoelectric conversion element 60 is a light-receiving element and has a function of generating current corresponding to the amount of light incident on the pixel circuit. The transistor 51 has a function of controlling supply of charge from the photoelectric conversion element 60 to the charge storage portion (FD). The transistor 52 has a function of outputting a signal which corresponds to the potential of the charge storage portion (FD). The transistor 53 has a function of resetting the potential of the charge storage portion (FD). The transistor 54 has a function of controlling selection of the pixel circuit at the time of reading.

Note that the charge storage portion (FD) is a charge retention node and retains charge that varies with the amount of light received by the photoelectric conversion element 60.

Note that the transistor 52 and the transistor 54 only need to be connected in series between the wiring 315 and the wiring 314. Hence, the wiring 314, the transistor 52, the transistor 54, and the wiring 315 may be arranged in order, or the wiring 314, the transistor 54, the transistor 52, and the wiring 315 may be arranged in order.

The wiring 311 (RS) functions as a signal line for controlling the transistor 53. The wiring 312 (TX) functions as a signal line for controlling the transistor 51. The wiring 313 (SE) functions as a signal line for controlling the transistor 54. The wiring 314 (GND) functions as a signal line for supplying a reference potential (e.g., GND). The wiring 315 (OUT) functions as a signal line for reading a signal output from the transistor 52. The wiring 316 functions as a signal line for outputting charge from the charge storage portion (FD) through the photoelectric conversion element 60 and is a low-potential line in the circuit in FIG. 10A. The wiring 317 functions as a signal line for resetting the potential of the charge storage portion (FD) and is a high-potential line in the circuit in FIG. 10A.

The relation with the wirings illustrated in FIGS. 1A and 1B and FIG. 2A is as follows. The wiring 76 corresponds to the wiring 311 (RS); the wiring 75, the wiring 312 (TX); the wiring 78, the wiring 313 (SE); the wiring 79, the wiring 314 (GND); the wiring 71, the wiring 315 (OUT); and the wiring 77, the wiring 316.

The pixel circuit of one embodiment of the present invention may have a configuration illustrated in FIG. 10B. The circuit illustrated in FIG. 10B includes the same components as those in the circuit in FIG. 10A but is different from the circuit in FIG. 10A in that the anode of the photoelectric conversion element 60 is electrically connected to one of the source and the drain of the transistor 51 and the cathode of the photoelectric conversion element 60 is electrically connected to the wiring 316. In this case, the wiring 316 functions as a signal line for supplying charge to the charge storage portion (FD) through the photoelectric conversion element 60 and is a high-potential line in the circuit in FIG. 10B. Furthermore, the wiring 317 is a low-potential line.

Next, a structure of each component illustrated in FIGS. 10A and 10B is described.

As described in Embodiment 1, an element formed using a selenium-based material and a conductive layer or an element in which a PIN junction is formed using a silicon layer can be used as the photoelectric conversion element 60.

The transistors 51 to 54 are preferably formed using an oxide semiconductor, though they can also be formed using a silicon semiconductor such as amorphous silicon, microcrystalline silicon, polycrystalline silicon, or single crystal silicon. A transistor in which a channel formation region is formed of an oxide semiconductor has an extremely low off-state current.

In particular, when the transistors 51 and 53 connected to the charge storage portion (FD) has a high leakage current, charge accumulated in the charge storage portion (FD) cannot be retained for a sufficiently long time. The use of an oxide semiconductor at least for the transistors 51 and 53 prevents unwanted leakage of charge from the charge storage portion (FD).

Unwanted leakage of charge also occurs in the wiring 314 or the wiring 315 when the transistor 52 and the transistor 54 have a high leakage current; thus, transistors including an oxide semiconductor in a channel formation region are preferably used as these transistors.

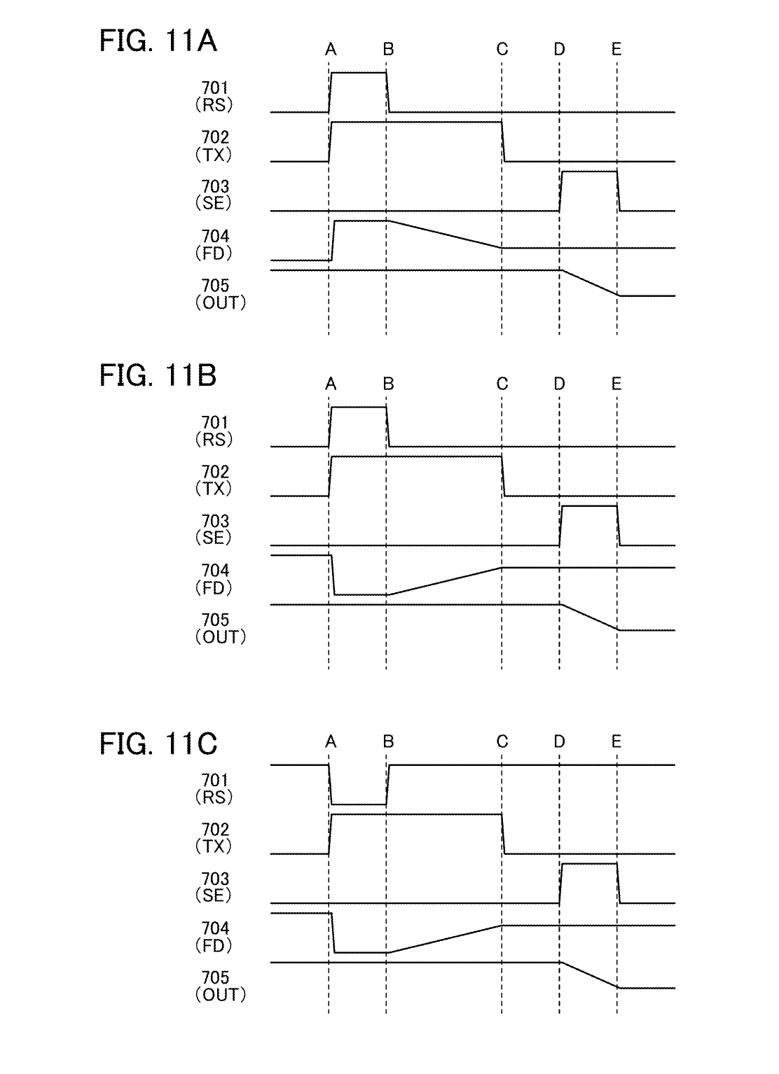

An example of the operation of the circuit in FIG. 10A is described using a timing chart shown in FIG. 11A.

In FIG. 11A, the potential of each wiring is denoted as a signal which varies between two levels for simplicity. Note that because each potential is an analog signal, the potential is not limited to two levels and can, in practice, have various levels in accordance with situations. In the drawing, a signal 701 corresponds to the potential of the wiring 311 (RS); a signal 702, the potential of the wiring 312 (TX); a signal 703, the potential of the wiring 313 (SE); a signal 704, the potential of the charge storage portion (FD); and a signal 705, the potential of the wiring 315 (OUT). Note that the potential of the wiring 316 is always at low level, and the potential of the wiring 317 is always at high level.

At time A, the potential of the wiring 311 (signal 701) is at high level and the potential of the wiring 312 (signal 702) is at high level, so that the potential of the charge storage portion (FD) (signal 704) is initialized to the potential of the wiring 317 (high level), and reset operation is started. Note that the potential of the wiring 315 (signal 705) is precharged to high level.

At time B, the potential of the wiring 311 (signal 701) is set at low level, whereby the reset operation is terminated to start accumulation operation. Here, a reverse bias is applied to the photoelectric conversion element 60, whereby the potential of the charge storage portion (FD) (signal 704) starts to decrease due to a reverse current. Since irradiation of the photoelectric conversion element 60 with light increases the reverse current, the rate of decrease in the potential of the charge storage portion (FD) (signal 704) increases with on the amount of the light irradiation. In other words, channel resistance between the source and the drain of the transistor 52 changes with the amount of light emitted to the photoelectric conversion element 60.

At time C, the potential of the wiring 312 (signal 702) is set to low level to complete the accumulation operation, so that the potential of the charge storage portion (FD) (signal 704) becomes constant. Here, the potential is determined by the amount of electrical charge generated by the photoelectric conversion element 60 during the accumulation operation. That is, the potential changes with the amount of light emitted to the photoelectric conversion element 60. Since the transistor 51 and the transistor 53 each include a channel formation region formed of an oxide semiconductor layer and have an extremely small off-state current, the potential of the charge storage portion (FD) can be kept constant until a subsequent selection operation (read operation) is performed.

Note that when the potential of the wiring 312 (signal 702) is set at low level, the potential of the charge storage portion (FD) might change owing to parasitic capacitance between the wiring 312 and the charge storage portion (FD). In the case where this potential change is large, the amount of electrical charge generated by the photoelectric conversion element 60 during the accumulation operation cannot be obtained accurately. Examples of effective measures to reduce the amount of change in the potential include reducing the capacitance between the gate and the source (or between the gate and the drain) of the transistor 51, increasing the gate capacitance of the transistor 52, and providing a storage capacitor for the charge storage portion (FD). Note that in this embodiment, the change in the potential can be ignored by these measures.

At time D, the potential of the wiring 313 (signal 703) is set at high level to turn on the transistor 54, whereby selection operation starts and the wiring 314 and the wiring 315 are electrically connected to each other through the transistor 52 and the transistor 54. Also, the potential of the wiring 315 (signal 705) starts to decrease. Note that precharge of the wiring 315 is terminated before the time D. Here, the rate at which the potential of the wiring 315 (signal 705) decreases depends on the current between the source and the drain of the transistor 52. That is, the potential of the wiring 315 (signal 705) changes with the amount of light emitted to the photoelectric conversion element 60 during the accumulation operation.

At time E, the potential of the wiring 313 (signal 703) is set at low level to turn off the transistor 54, so that the selection operation is terminated and the potential of the wiring 315 (signal 705) becomes a constant value. Here, the constant value changes with the amount of light emitted to the photoelectric conversion element 60. Therefore, the amount of light emitted to the photoelectric conversion element 60 during the accumulation operation can be determined by measuring the potential of the wiring 315.

More specifically, when the photoelectric conversion element 60 is irradiated with light with higher intensity, the potential of the charge storage portion (FD), that is, the gate voltage of the transistor 52 is lower. Therefore, current flowing between the source and the drain of the transistor 52 becomes small; as a result, the potential of the wiring 315 (signal 705) gradually decreases. Thus, a relatively high potential can be read from the wiring 315.

In contrast, when the photoelectric conversion element 60 is irradiated with light with lower intensity, the potential of the charge storage portion (FD), that is, the gate voltage of the transistor 52 is higher. Therefore, the current flowing between the source and the drain of the transistor 52 becomes large; thus, the potential of the wiring 315 (signal 705) rapidly decreases. Thus, a relatively low potential can be read from the wiring 315.

Next, an example of the operation of the circuit in FIG. 10B is described with reference to a timing chart in FIG. 11B. Note that the wiring 316 is always at high level, and the potential of the wiring 317 is always at low level.

At time A, the potential of the wiring 311 (signal 701) is at high level and the potential of the wiring 312 (signal 702) is at high level, so that the potential of the charge storage portion (FD) (signal 704) is initialized to the potential of the wiring 317 (low level), and reset operation is started. Note that the potential of the wiring 315 (signal 705) is precharged to high level.

At time B, the potential of the wiring 311 (signal 701) is set at low level, whereby the reset operation is terminated to start accumulation operation. Here, a reverse bias is applied to the photoelectric conversion element 60, whereby the potential of the charge storage portion (FD) (signal 704) starts to increase due to a reverse current.

The description of the timing chart of FIG. 11A can be referred to for operations at and after the time C. The amount of light emitted to the photoelectric conversion element 60 during the accumulation operation can be determined by measuring the potential of the wiring 315 at time E.

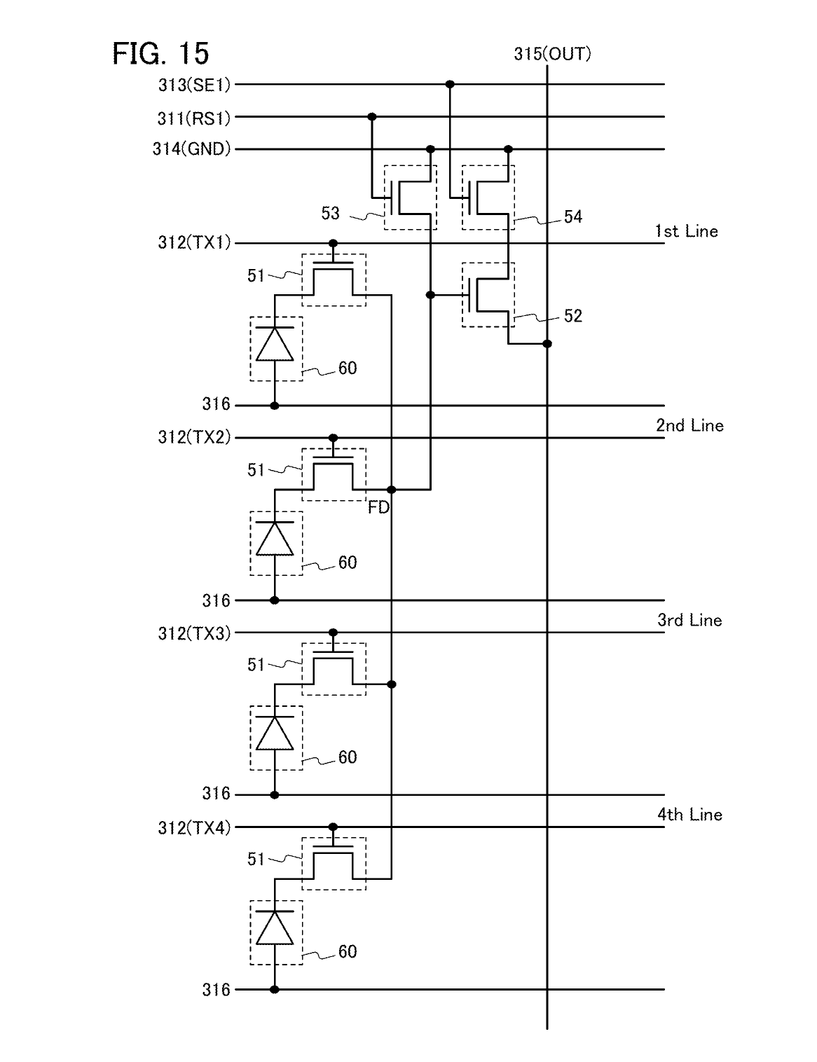

Note that the pixel circuit in FIG. 10A may have a configuration in which the transistors 52 to 54 are shared among a plurality of pixels as illustrated in FIG. 15. FIG. 15 illustrates a configuration in which the transistors 52 to 54 are shared among a plurality of pixels in the perpendicular direction; however, the transistors 52 to 54 may be shared among a plurality of pixels in the horizontal direction or in the horizontal and perpendicular direction. Such a structure reduces the number of transistors in one pixel. Although the transistors 52 to 54 are shared among four pixels in FIG. 15, the transistors 52 to 54 may be shared among two pixels, three pixels, five pixels or more. The pixel circuit in FIG. 10B can have a configuration similar to that of the pixel circuit in FIG. 15.

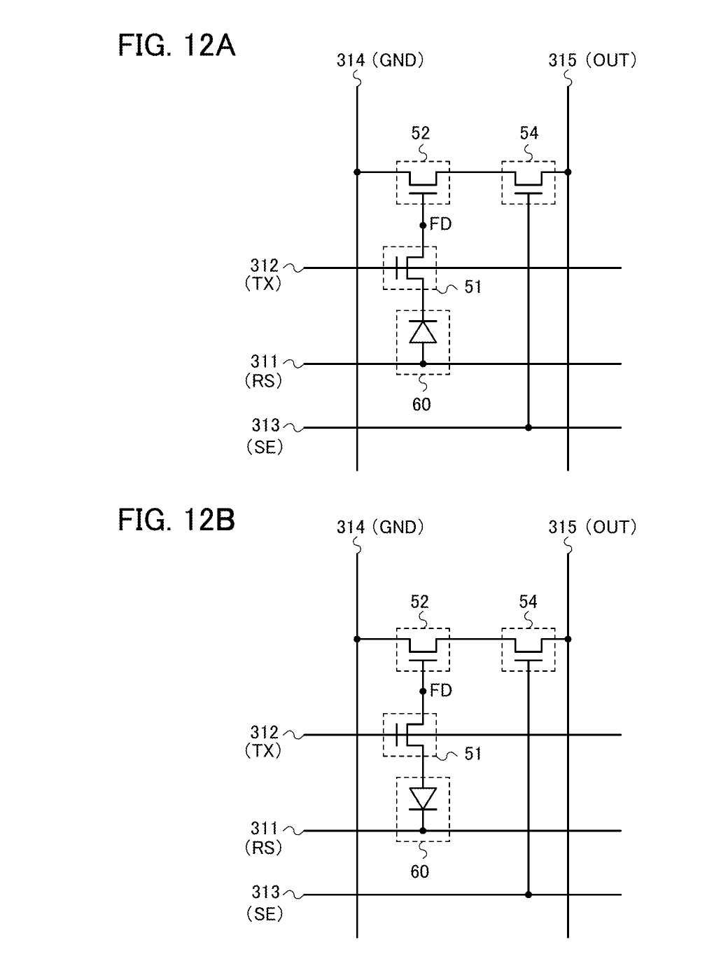

The pixel circuit of one embodiment of the present invention may have a configuration illustrated in FIGS. 12A and 12B.

The configuration of a circuit in FIG. 12A is different from that of the circuit in FIG. 10A in that the transistor 53, the wiring 316, and the wiring 317 are not provided, and the wiring 311 (RS) is electrically connected to the anode of the photoelectric conversion element 60. The other structures are the same as those in the circuit in FIG. 10A.

The circuit in FIG. 12B includes the same components as those in the circuit in FIG. 12A but is different from the circuit in FIG. 12A in that the anode of the photoelectric conversion element 60 is electrically connected to one of the source and the drain of the transistor 52 and the cathode of the photoelectric conversion element 60 is electrically connected to the wiring 311 (RS).

Like the circuit in FIG. 10A, the circuit in FIG. 12A can be operated in accordance with the timing chart shown in FIG. 11A.

At time A, the potential of the wiring 311 (signal 701) is set at high level and the potential of the wiring 312 (signal 702) is set at high level, whereby a forward bias is applied to the photoelectric conversion element 60 and the potential of the charge storage portion (FD) (signal 704) is set at high level. In other words, the potential of the charge storage portion (FD) is initialized to the potential of the wiring 311 (RS) (high level) and brought into a reset state. The above is the start of the reset operation. Note that the potential of the wiring 315 (signal 705) is precharged to high level.

At time B, the potential of the wiring 311 (signal 701) is set at low level, whereby the reset operation is terminated to start accumulation operation. Here, a reverse bias is applied to the photoelectric conversion element 60, whereby the potential of the charge storage portion (FD) (signal 704) starts to decrease due to a reverse current.

The description of the circuit operation of FIG. 10A can be referred to for operations at and after time C. The amount of light emitted to the photoelectric conversion element 60 during the accumulation operation can be determined by measuring the potential of the wiring 315 at time E.

The circuit in FIG. 12B can be operated in accordance with the timing chart shown in FIG. 11C.

At time A, the potential of the wiring 311 (signal 701) is set at low level and the potential of the wiring 312 (signal 702) is set at high level, whereby a forward bias is applied to the photoelectric conversion element 60 and the potential of the charge storage portion (FD) (signal 704) is reset to low level. The above is the start of the reset operation. Note that the potential of the wiring 315 (signal 705) is precharged to high level.

At time B, the potential of the wiring 311 (signal 701) is set at high level, whereby the reset operation is terminated to start accumulation operation. Here, a reverse bias is applied to the photoelectric conversion element 60, whereby the potential of the charge storage portion (FD) (signal 704) starts to increase due to a reverse current.

The description of the circuit operation of FIG. 10A can be referred to for operations at and after time C. The amount of light emitted to the photoelectric conversion element 60 during the accumulation operation can be determined by measuring the potential of the wiring 315 at time E.

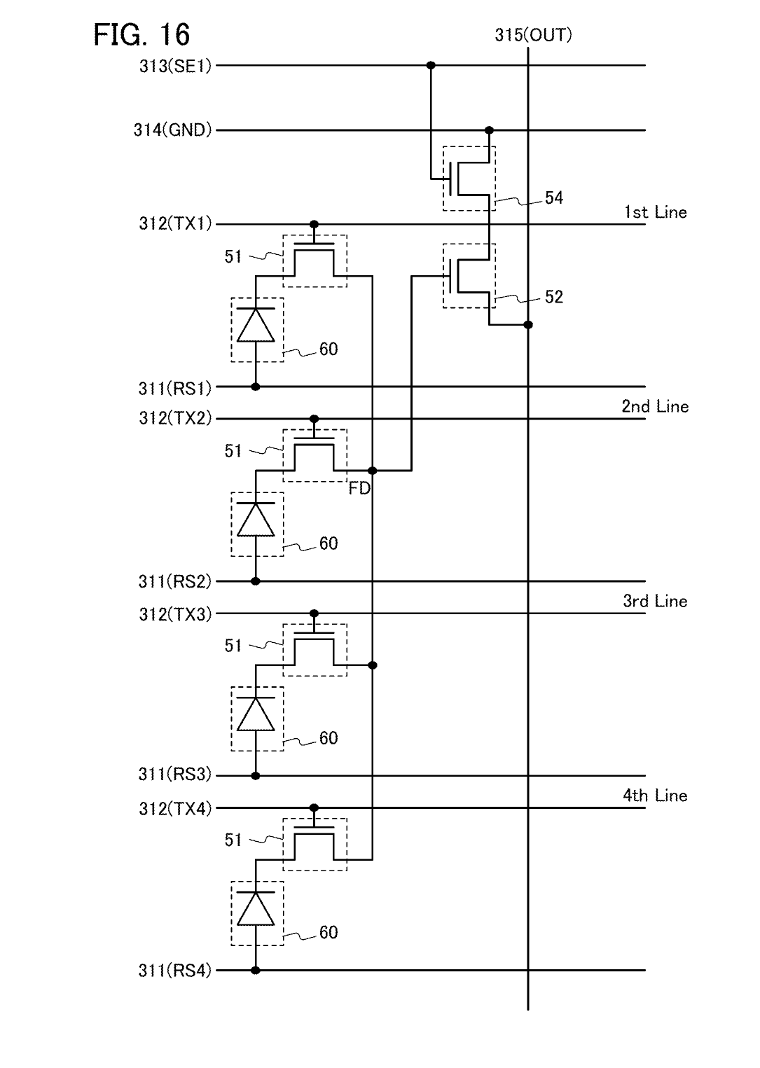

Note that the pixel circuit in FIG. 12A may have a configuration in which the transistors 52 and 54 are shared among a plurality of pixels as illustrated in FIG. 16. FIG. 16 illustrates a configuration in which the transistors 52 and 54 are shared among a plurality of pixels in the perpendicular direction; however, the transistors 52 and 54 may be shared among a plurality of pixels in the horizontal direction or in the horizontal and perpendicular direction. Although the transistors 52 and 54 are shared among four pixels in FIG. 16, the transistors 52 and 54 may be shared among two pixels, three pixels, five pixels or more. The pixel circuit in FIG. 12B can have a configuration similar to that of the pixel circuit in FIG. 16.

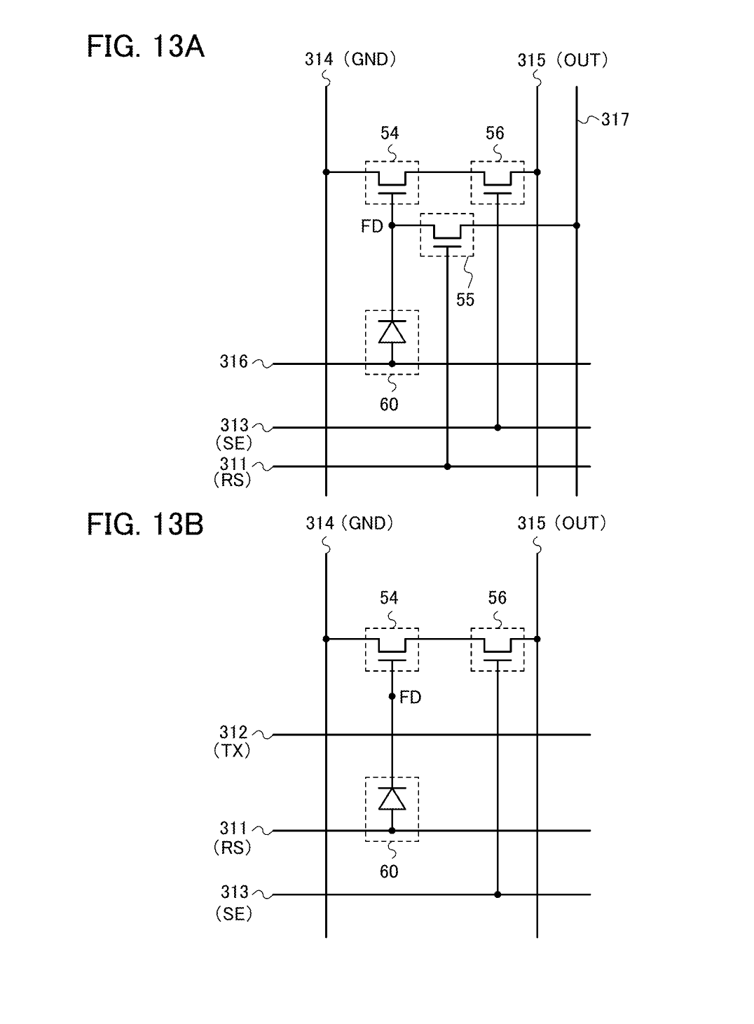

Although the transistor 51 is provided in FIGS. 10A and 10B and FIGS. 12A and 12B, one embodiment of the present invention is not limited to example. The transistor 51 can be omitted as shown in FIGS. 13A and 13B.

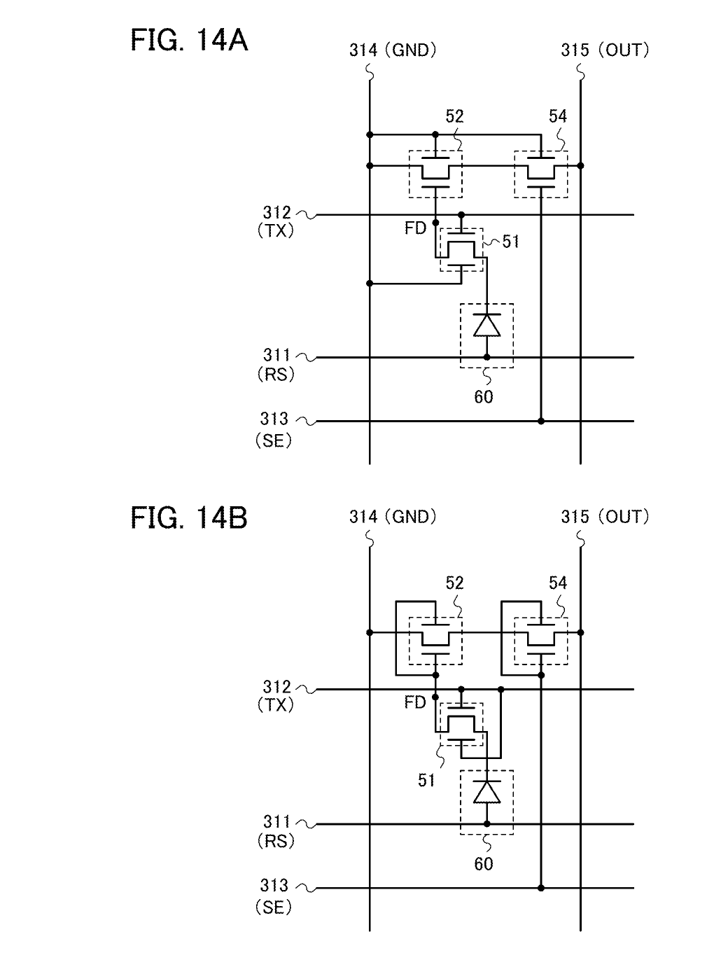

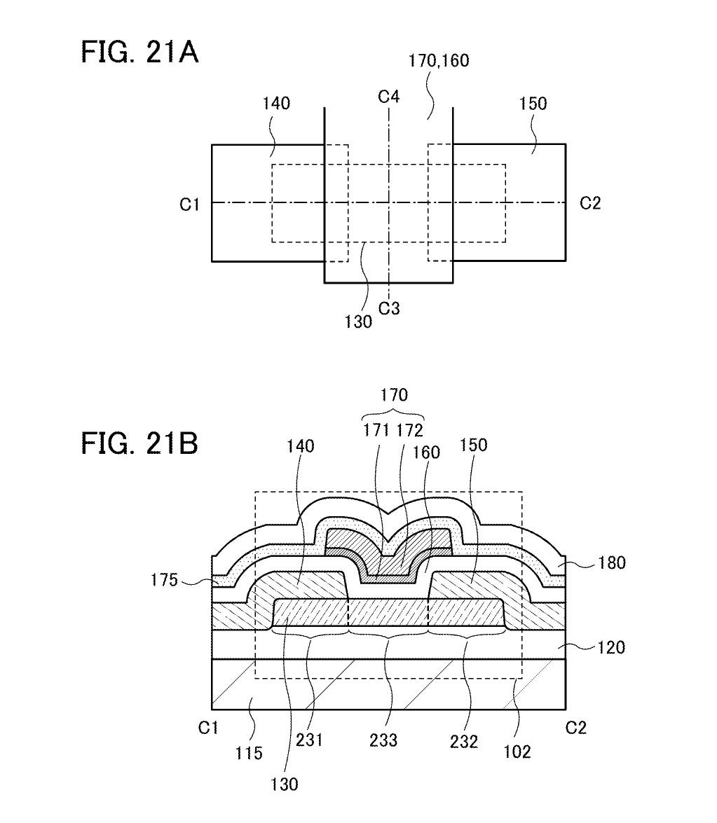

The transistor 51, the transistor 52, and the transistor 54 in the pixel circuit may each have a back gate as illustrated in FIGS. 14A and 14B. FIG. 14A illustrates a configuration of applying a constant potential to the back gates, which enables control of the threshold voltages. FIG. 14B illustrates a configuration in which the back gates are supplied with the same potential as their respective front gates, which enables an increase in on-state current. Although the back gates are electrically connected to the wiring 314 (GND) in FIG. 14A, they may be electrically connected to a different wiring to which a constant potential is supplied. Furthermore, although FIGS. 14A and 14B each illustrate an example in which back gates are provided in the transistors of the circuit in FIG. 21A, the circuits in FIGS. 10A and 10B, FIG. 12B, and FIGS. 13A and 13B may have a similar configuration. Moreover, a configuration of applying the same potential to a front gate and a back gate, a configuration of applying a constant potential to a back gate, and a configuration without a back gate may be arbitrarily combined as necessary for the transistors in one circuit.

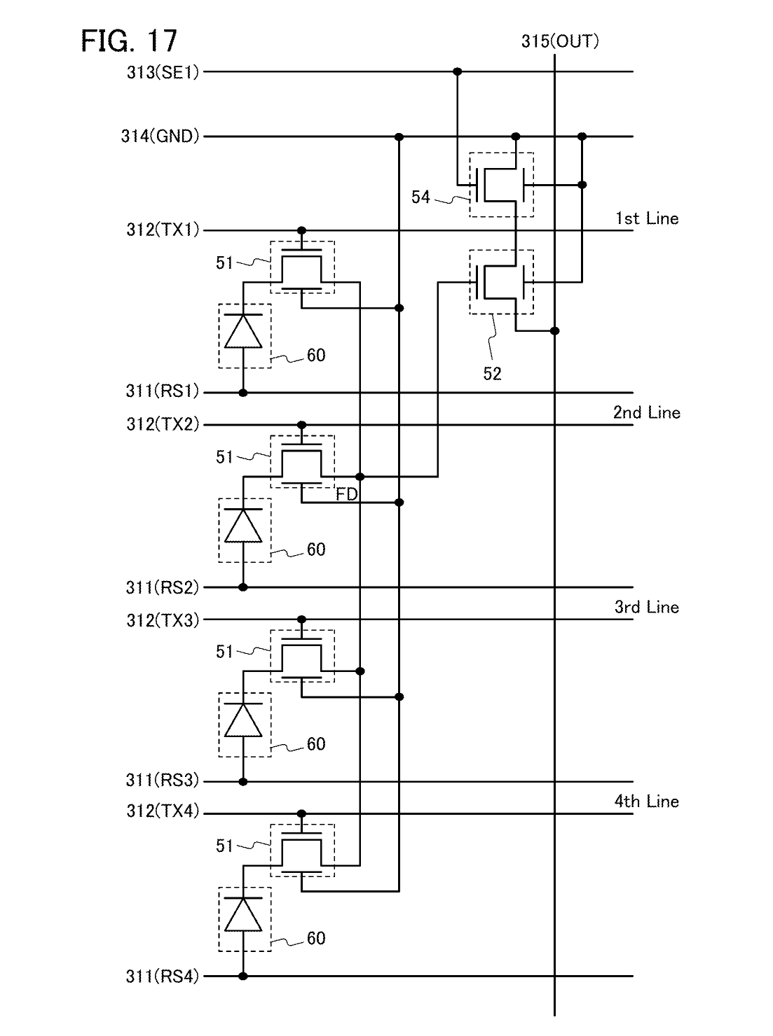

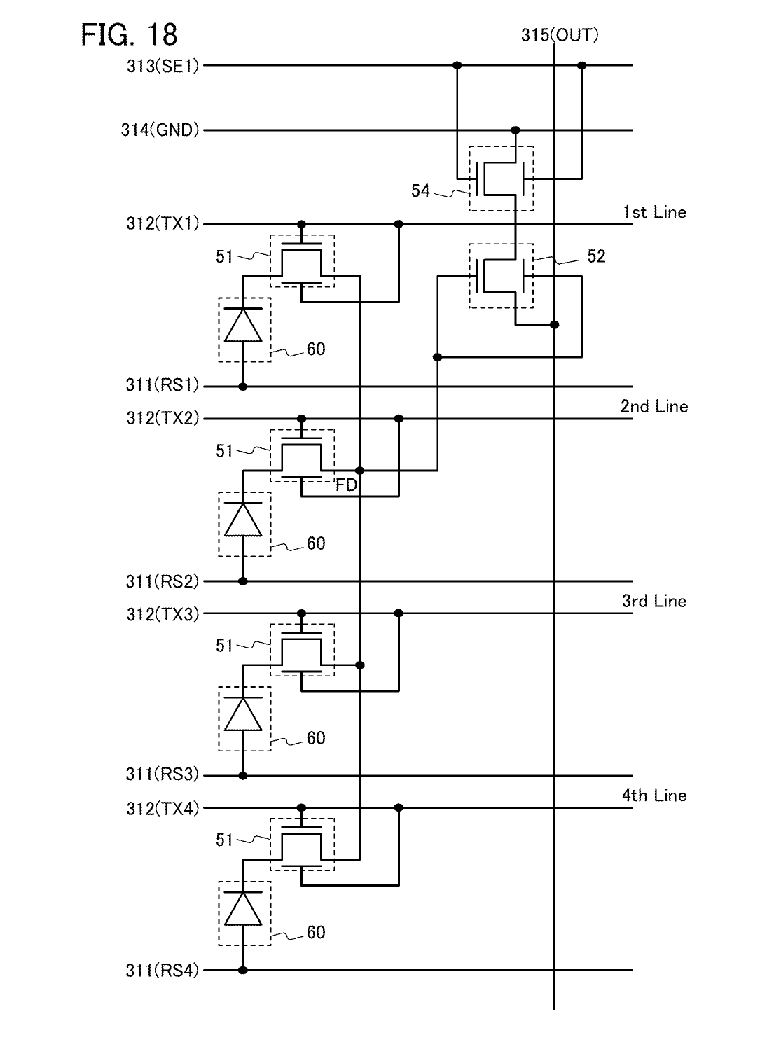

Note that the pixel circuit in FIG. 14A may have a configuration in which the transistors 51 and 54 are shared among a plurality of pixels as illustrated in FIG. 17. Furthermore, the pixel circuit in FIG. 14B may have a configuration in which the transistors 52 and 54 are shared among a plurality of pixels as illustrated in FIG. 18.

This embodiment can be combined with any of the structures described in the other embodiments and example as appropriate.

### Embodiment 3

In this embodiment, an example of a driving method of a pixel circuit will be described.

As described in Embodiment 2, the operation of the pixel circuit is repetition of the reset operation, the accumulation operation, and the selection operation. As imaging modes for controlling the whole pixel matrix, a global shutter system and a rolling shutter system are known.

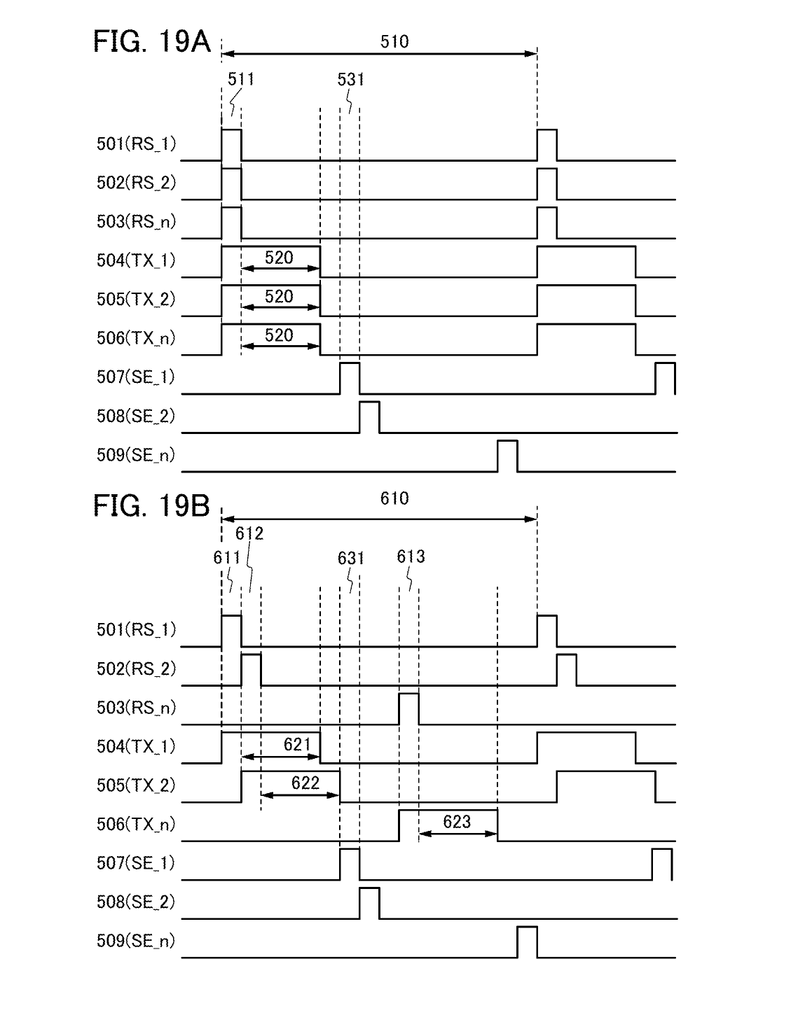

FIG. 19A shows a timing chart in a global shutter system. FIG. 19A shows operations of an imaging device in which a plurality of pixel circuits illustrated in FIG. 10A are arranged in a matrix. Specifically, FIG. 19A show operations of the pixel circuits from the first row to the n-th row (n is a natural number of three or more). The following description for operation can be applied to any of the circuits in FIG. 10B, FIGS. 12A and 12B, and FIGS. 13A and 13B.

In FIG. 19A, a signal 501, a signal 502, and a signal 503 are input to the wiring 311 (RS) connected to the pixel circuits in the first row, the second row, and the n-th row, respectively. A signal 504, a signal 505, and a signal 506 are input to the wiring 312 (TX) connected to the pixel circuits in the first row, the second row, and the n-th row, respectively. A signal 507, a signal 508, and a signal 509 are input to the wiring 313 (SE) connected to the pixel circuits in the first row, the second row, and the n-th row, respectively.

In a period 510, image-capturing is performed once. In a period 511, the reset operation is performed in the pixel circuits in each row at the same time. In a period 520, the accumulation operation is performed in the pixel circuits in each row at the same time. Note that the selection operation is sequentially performed in the pixel circuits for each row. For example, in a period 531, the selection operation is performed in the pixel circuits in the first row. As described above, in the global shutter system, the reset operation is performed in all the pixel circuits substantially at the same time, the accumulation operation is performed in all the pixel circuits substantially at the same time, and then the read operation is sequentially performed for each row.

That is, in the global shutter system, since the accumulation operation is performed in all the pixel circuits substantially at the same time, image-capturing is simultaneously performed in the pixel circuits in all the rows. Therefore, an image with little distortion can be obtained even in the case of a moving object.

On the other hand, FIG. 19B shows a timing chart in a rolling shutter system. The description of FIG. 19A can be referred to for the signals 501 to 509. In a period 610, image-capturing is performed once. A period 611, a period 612, and a period 613 are reset periods in the first row, the second row, and the n-th row, respectively. A period 621, a period 622, and a period 623 are accumulation operation periods in the first row, the second row, and the n-th row, respectively. In a period 631, the selection operation is performed in the pixel circuits in the first row. As described above, in the rolling shutter system, the accumulation operation is not performed at the same time in all the pixel circuits but is sequentially performed for each row; thus, image-capturing is not simultaneously performed in the pixel circuits in all the rows. Therefore, the timing of image-capturing in the first row is different from that of image-capturing in the last row, so that an image with large distortion is obtained in the case of a moving object.

To perform the global shutter system, the potential of the charge storage portion (FD) needs to be kept for a long time until reading of signals from all the pixels is terminated. When a transistor including an oxide semiconductor in a channel formation region and having an extremely low off-state current is used as the transistor 51 and the like, the potential of the charge storage portion (FD) can be kept for a long time. In the case where a transistor including silicon or the like in a channel formation region is used as the transistor 51 and the like, the potential of the charge storage portion (FD) cannot be kept for a long time because of a high off-state current, which makes it difficult to use the global shutter system.

As described above, the global shutter system can be easily performed by using transistors including an oxide semiconductor in a channel formation region for the pixel circuits.

This embodiment can be combined with any of the structures described in the other embodiments and example as appropriate.

### Embodiment 4

In this embodiment, a transistor including an oxide semiconductor that can be used in one embodiment of the present invention will be described with reference to drawings. In the drawings in this embodiment, some components are enlarged, reduced in size, or omitted for easy understanding.

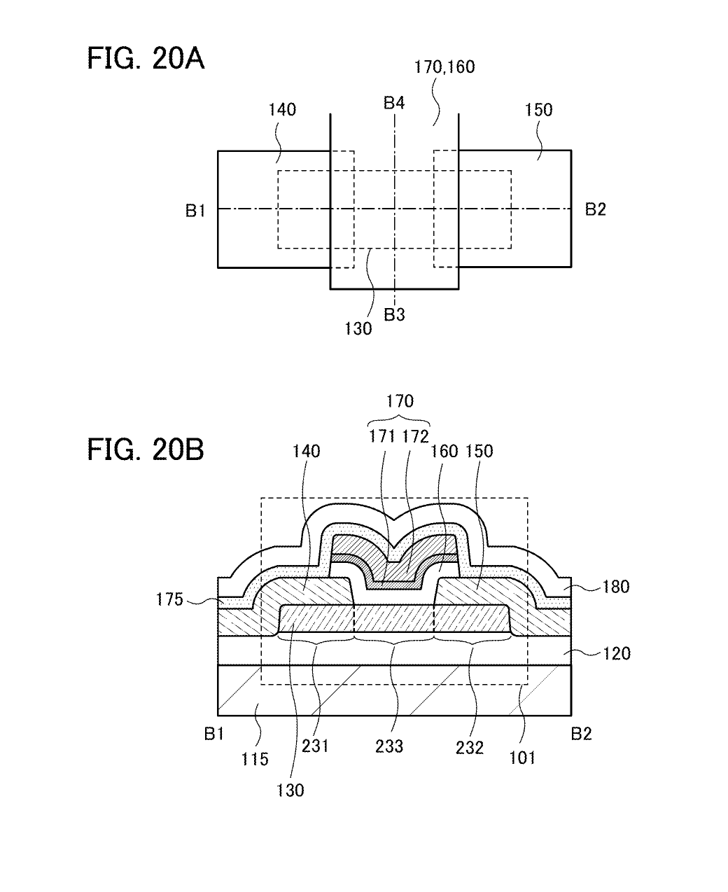

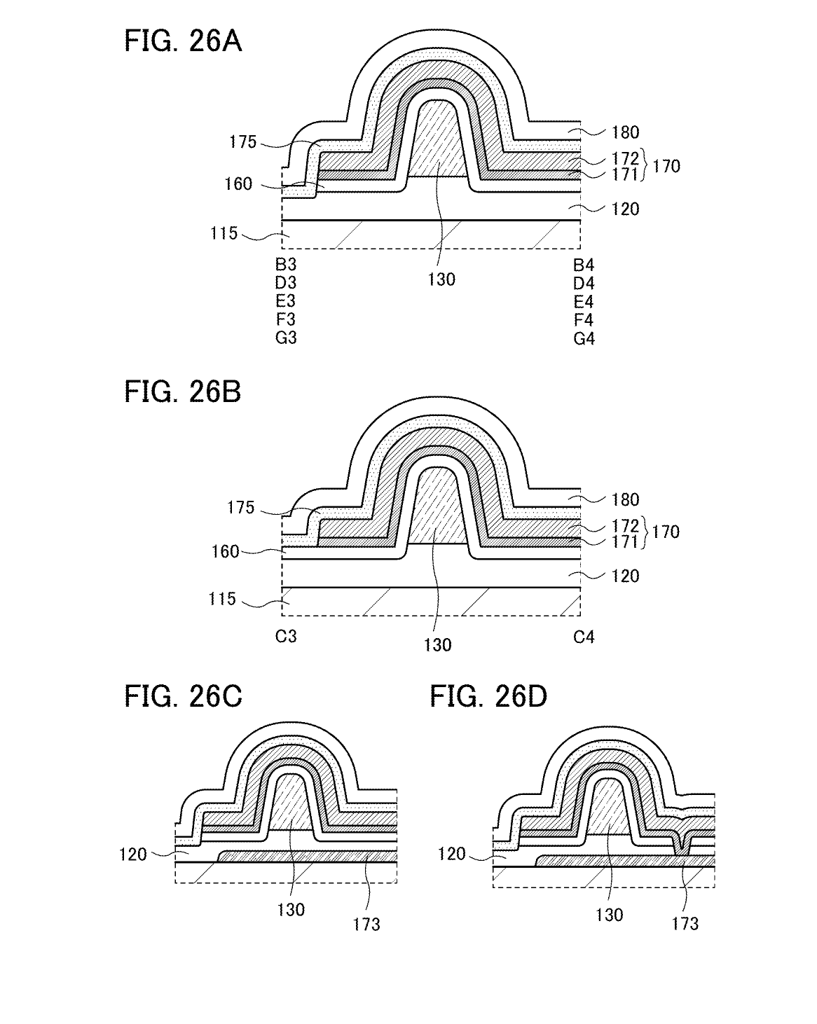

FIGS. 20A and 20B are a top view and a cross-sectional view illustrating a transistor 101 of one embodiment of the present invention. FIG. 20A is the top view, and FIG. 20B illustrates a cross section taken along dashed-dotted line B1-B2 in FIG. 20A. A cross section in the direction of dashed-dotted line B3-B4 in FIG. 20A is illustrated in FIG. 26A. The direction of dashed-dotted line B1-B2 is referred to as a channel length direction, and the direction of dashed-dotted line B3-B4 is referred to as a channel width direction.

The transistor 101 includes an insulating layer 120 in contact with a substrate 115; an oxide semiconductor layer 130 in contact with the insulating layer 120; conductive layers 140 and 150 electrically connected to the oxide semiconductor layer 130; an insulating layer 160 in contact with the oxide semiconductor layer 130 and the conductive layers 140 and 150; a conductive layer 170 in contact with the insulating layer 160; an insulating layer 175 in contact with the conductive layers 140 and 150, the insulating layer 160, and the conductive layer 170; and an insulating layer 180 in contact with the insulating layer 175. The insulating layer 180 may function as a planarization film as necessary.

Here, the conductive layer 140, the conductive layer 150, the insulating layer 160, and the conductive layer 170 can function as a source electrode, a drain electrode, a gate insulating film, and a gate electrode, respectively.

A region 231, a region 232, and a region 233 in FIG. 20B can function as a source region, a drain region, and a channel formation region, respectively. The region 231 and the region 232 are in contact with the conductive layer 140 and the conductive layer 150, respectively. When a conductive material that is easily bonded to oxygen is used for the conductive layers 140 and 150, the resistance of the regions 231 and 232 can be reduced.

Specifically, since the oxide semiconductor layer 130 is in contact with the conductive layers 140 and 150, an oxygen vacancy is generated in the oxide semiconductor layer 130, and interaction between the oxygen vacancy and hydrogen that remains in the oxide semiconductor layer 130 or diffuses into the oxide semiconductor layer 130 from the outside changes the regions 231 and 232 to n-type regions with low resistance.

Note that functions of a “source” and a “drain” of a transistor are sometimes interchanged with each other when a transistor of an opposite conductivity type is used or when the direction of current flow is changed in circuit operation, for example. Therefore, the terms “source” and “drain” can be interchanged with each other in this specification. In addition, the term “electrode ” can be changed into the term “wiring”.

The conductive layer 170 includes two layers, conductive layers 171 and 172, but also may be a single layer or a stack of three or more layers. The same applies to the other transistors described in this embodiment.

Each of the conductive layers 140 and 150 is a single layer, but also may be a stack of two or more layers. The same applies to the other transistors described in this embodiment.

The transistor in one embodiment of the present invention may have a structure illustrated in FIGS. 21A and 21B. FIG. 21A is a top view of a transistor 102. A cross section in the direction of dashed-dotted line C1-C2 in FIG. 21A is illustrated in FIG. 21B. A cross section in the direction of dashed-dotted line C3-C4 in FIG. 21A is illustrated in FIG. 26B. The direction of dashed-dotted line C1-C2 is referred to as a channel length direction, and the direction of dashed-dotted line C3-C4 is referred to as a channel width direction.

The transistor 102 has the same structure as the transistor 101 except that an end portion of the insulating layer 160 functioning as a gate insulating film is not aligned with an end portion of the conductive layer 170 functioning as a gate electrode. In the transistor 102, wide areas of the conductive layers 140 and 150 are covered with the insulating layer 160 and accordingly the resistance between the conductive layer 170 and the conductive layers 140 and 150 is high; therefore, the transistor 102 has a low gate leakage current.

The transistors 101 and 102 each have a top-gate structure including a region where the conductive layer 170 overlaps with the conductive layers 140 and 150. To reduce parasitic capacitance, the width of the region in the channel length direction is preferably greater than or equal to 3 nm and less than 300 nm. Since an offset region is not formed in the oxide semiconductor layer 130 in this structure, a transistor with a high on-state current can be easily formed.

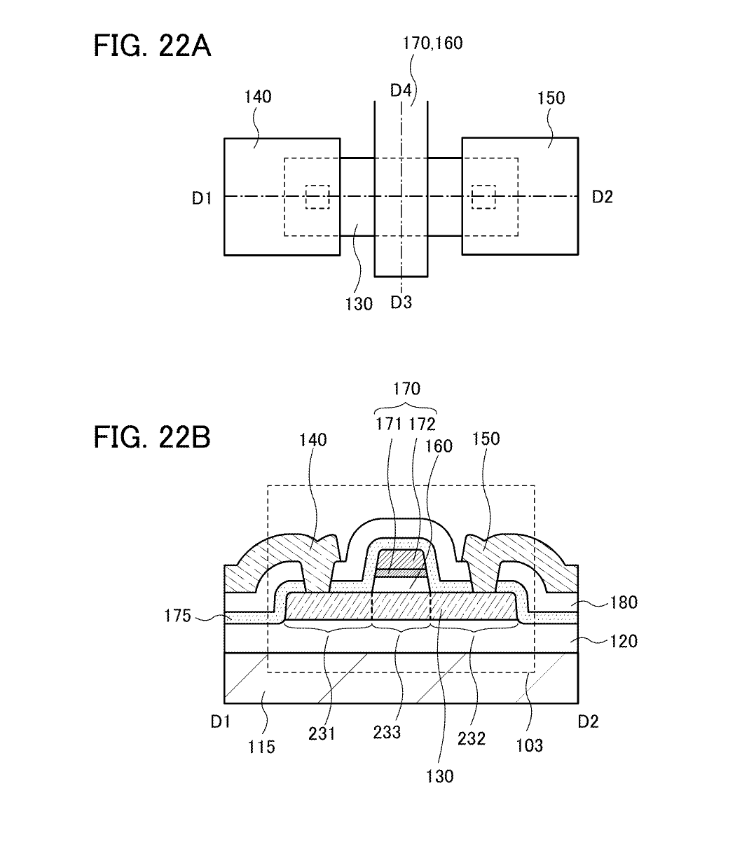

The transistor in one embodiment of the present invention may have a structure illustrated in FIGS. 22A and 22B. FIG. 22A is a top view of a transistor 103. A cross section in the direction of dashed-dotted line D1-D2 in FIG. 22A is illustrated in FIG. 22B. A cross section in the direction of dashed-dotted line D3-D4 in FIG. 22A is illustrated in FIG. 26A. The direction of dashed-dotted line D1-D2 is referred to as a channel length direction, and the direction of dashed-dotted line D3-D4 is referred to as a channel width direction.

The transistor 103 includes the insulating layer 120 in contact with the substrate 115; the oxide semiconductor layer 130 in contact with the insulating layer 120; the insulating layer 160 in contact with the oxide semiconductor layer 130; the conductive layer 170 in contact with the insulating layer 160; the insulating layer 175 covering the oxide semiconductor layer 130, the insulating layer 160, and the conductive layer 170; the insulating layer 180 in contact with the insulating layer 175; and the conductive layers 140 and 150 electrically connected to the oxide semiconductor layer 130 through openings provided in the insulating layers 175 and 180. The transistor 103 may further include, for example, an insulating layer (planarization film) in contact with the insulating layer 180 and the conductive layers 140 and 150 as necessary.

Here, the conductive layer 140, the conductive layer 150, the insulating layer 160, and the conductive layer 170 can function as a source electrode, a drain electrode, a gate insulating film, and a gate electrode, respectively.

The region 231, the region 232, and the region 233 in FIG. 22B can function as a source region, a drain region, and a channel formation region, respectively. The regions 231 and 232 are in contact with the insulating layer 175. When an insulating material containing hydrogen is used for the insulating layer 175, for example, the resistance of the regions 231 and 232 can be reduced.

Specifically, interaction between an oxygen vacancy generated in the regions 231 and 232 by the steps up to formation of the insulating layer 175 and hydrogen that diffuses into the regions 231 and 232 from the insulating layer 175 changes the regions 231 and 232 to n-type regions with low resistance. As the insulating material containing hydrogen, for example, silicon nitride, aluminum nitride, or the like can be used.

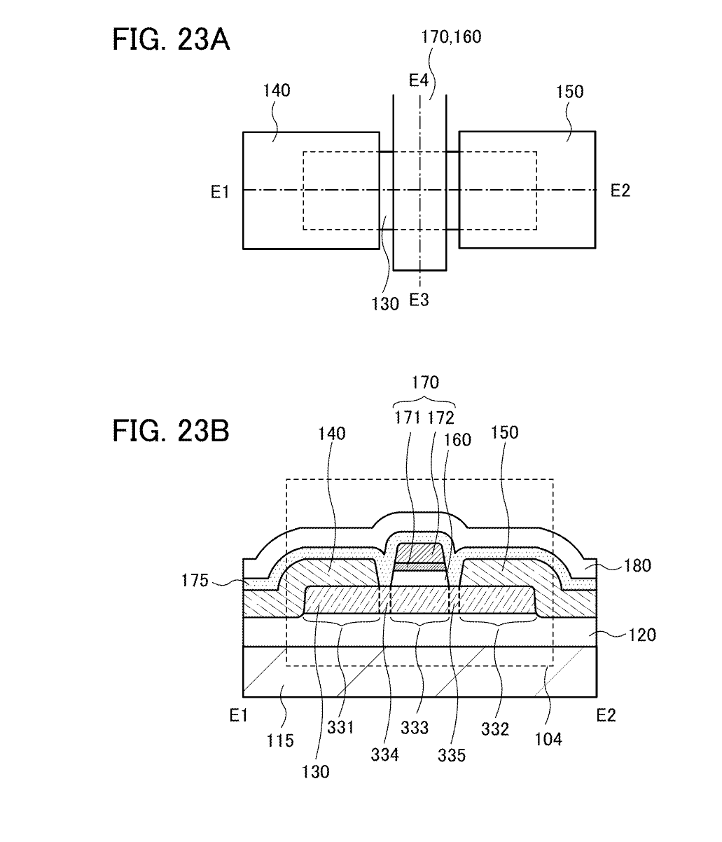

The transistor in one embodiment of the present invention may have a structure illustrated in FIGS. 23A and 23B. FIG. 23A is a top view of a transistor 104. A cross section in the direction of dashed-dotted line E1-E2 in FIG. 23A is illustrated in FIG. 23B. A cross section in the direction of dashed-dotted line E3-E4 in FIG. 23A is illustrated in FIG. 26A. The direction of dashed-dotted line E1-E2 is referred to as a channel length direction, and the direction of dashed-dotted line E3-E4 is referred to as a channel width direction.

The transistor 104 has the same structure as the transistor 103 except that the conductive layers 140 and 150 in contact with the oxide semiconductor layer 130 cover end portions of the oxide semiconductor layer 130.

In FIG. 23B, regions 331 and 334 can function as a source region, regions 332 and 335 can function as a drain region, and a region 333 can function as a channel formation region.

The resistance of the regions 331 and 332 can be reduced in a manner similar to that of the regions 231 and 232 in the transistor 101.

The resistance of the regions 334 and 335 can be reduced in a manner similar to that of the regions 231 and 232 in the transistor 103. In the case where the length of the regions 334 and 335 in the channel length direction is less than or equal to 100 nm, preferably less than or equal to 50 nm, a gate electric field prevents a significant decrease in on-state current. Therefore, a reduction in resistance of the regions 334 and 335 is not performed in some cases.

The transistors 103 and 104 each have a self-aligned structure that does not include a region where the conductive layer 170 overlaps with the conductive layers 140 and 150. A transistor with a self-aligned structure, which has extremely low parasitic capacitance between a gate electrode and source and drain electrodes, is suitable for applications that require high-speed operation.

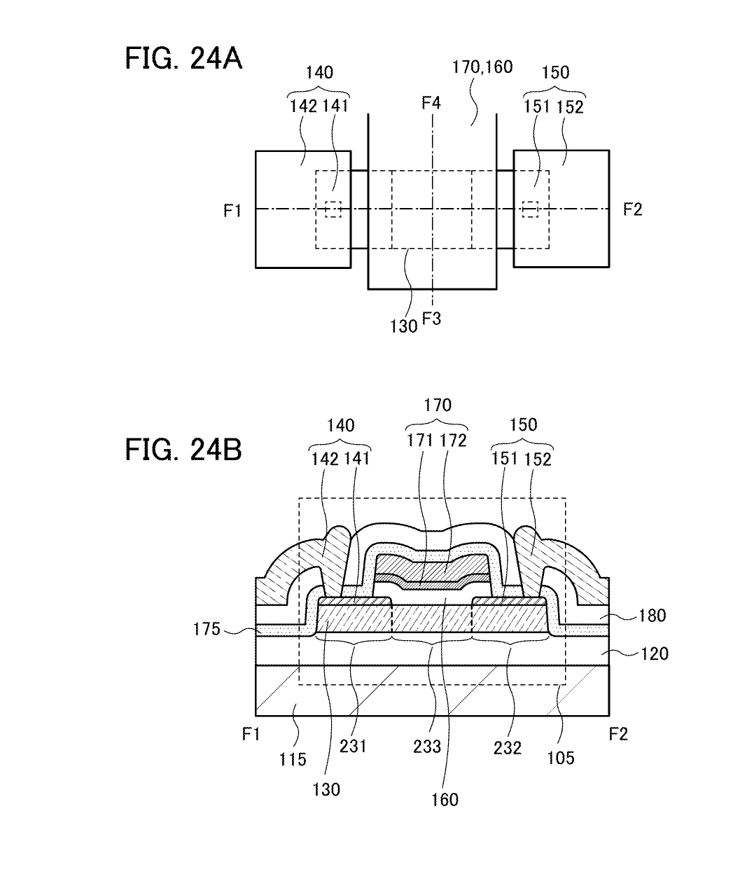

The transistor in one embodiment of the present invention may have a structure illustrated in FIGS. 24A and 24B. FIG. 24A is a top view of a transistor 105. A cross section in the direction of dashed-dotted line F1-F2 in FIG. 24A is illustrated in FIG. 24B. A cross section in the direction of dashed-dotted line F3-F4 in FIG. 24A is illustrated in FIG. 26A. The direction of dashed-dotted line F1-F2 is referred to as a channel length direction, and the direction of dashed-dotted line F3-F4 is referred to as a channel width direction.

The transistor 105 includes the insulating layer 120 in contact with the substrate 115; the oxide semiconductor layer 130 in contact with the insulating layer 120; conductive layers 141 and 151 electrically connected to the oxide semiconductor layer 130; the insulating layer 160 in contact with the oxide semiconductor layer 130 and the conductive layers 141 and 151; the conductive layer 170 in contact with the insulating layer 160; the insulating layer 175 in contact with the oxide semiconductor layer 130, the conductive layers 141 and 151, the insulating layer 160, and the conductive layer 170; the insulating layer 180 in contact with the insulating layer 175; and conductive layers 142 and 152 electrically connected to the conductive layers 141 and 151, respectively, through openings provided in the insulating layers 175 and 180. The transistor 105 may further include, for example, an insulating layer in contact with the insulating layer 180 and the conductive layers 142 and 152 as necessary.

Here, the conductive layers 141 and 151 are in contact with the top surface of the oxide semiconductor layer 130 and are not in contact with side surfaces of the oxide semiconductor layer 130.

The transistor 105 has the same structure as the transistor 101 except that the conductive layers 141 and 151 are provided, that openings are provided in the insulating layers 175 and 180, and that the conductive layers 142 and 152 electrically connected to the conductive layers 141 and 151, respectively, through the openings are provided. The conductive layer 140 (the conductive layers 141 and 142) can function as a source electrode, and the conductive layer 150 (the conductive layers 151 and 152) can function as a drain electrode.

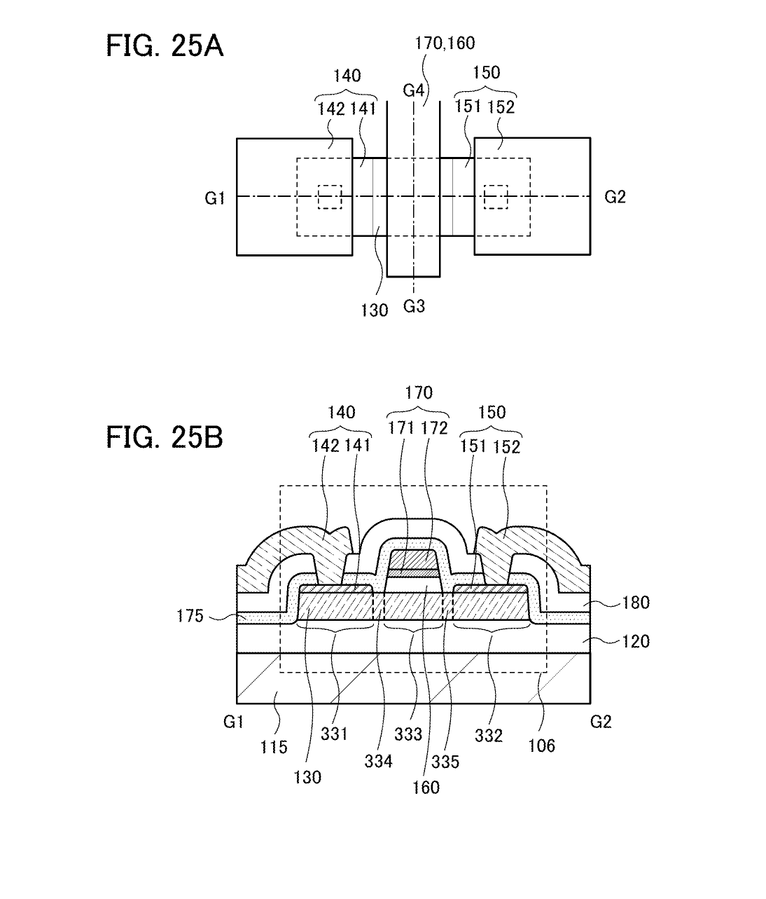

The transistor in one embodiment of the present invention may have a structure illustrated in FIGS. 25A and 25B. FIG. 25A is a top view of a transistor 106. A cross section in the direction of dashed-dotted line G1-G2 in FIG. 25A is illustrated in FIG. 25B. A cross section in the direction of dashed-dotted line G3-G4 in FIG. 25A is illustrated in FIG. 26A. The direction of dashed-dotted line G1-G2 is referred to as a channel length direction, and the direction of dashed-dotted line G3-G4 is referred to as a channel width direction.

The transistor 106 includes the insulating layer 120 in contact with the substrate 115; the oxide semiconductor layer 130 in contact with the insulating layer 120; the conductive layers 141 and 151 electrically connected to the oxide semiconductor layer 130; the insulating layer 160 in contact with the oxide semiconductor layer 130; the conductive layer 170 in contact with the insulating layer 160; the insulating layer 175 in contact with the insulating layer 120, the oxide semiconductor layer 130, the conductive layers 141 and 151, the insulating layer 160, and the conductive layer 170; the insulating layer 180 in contact with the insulating layer 175; and the conductive layers 142 and 152 electrically connected to the conductive layers 141 and 151, respectively, through openings provided in the insulating layers 175 and 180. The transistor 106 may further include, for example, an insulating layer (planarization film) in contact with the insulating layer 180 and the conductive layers 142 and 152 as necessary.

Here, the conductive layers 141 and 151 are in contact with the top surface of the oxide semiconductor layer 130 and are not in contact with side surfaces of the oxide semiconductor layer 130.

The transistor 106 has the same structure as the transistor 103 except that the conductive layers 141 and 151 are provided. The conductive layer 140 (the conductive layers 141 and 142) can function as a source electrode, and the conductive layer 150 (the conductive layers 151 and 152) can function as a drain electrode.

In the structures of the transistors 105 and 106, the conductive layers 140 and 150 are not in contact with the insulating layer 120. These structures make the insulating layer 120 less likely to be deprived of oxygen by the conductive layers 140 and 150 and facilitate oxygen supply from the insulating layer 120 to the oxide semiconductor layer 130.

An impurity for forming an oxygen vacancy to increase conductivity may be added to the regions 231 and 232 in the transistor 103 and the regions 334 and 335 in the transistors 104 and 106. As an impurity for forming an oxygen vacancy in an oxide semiconductor layer, for example, one or more of the following can be used: phosphorus, arsenic, antimony, boron, aluminum, silicon, nitrogen, helium, neon, argon, krypton, xenon, indium, fluorine, chlorine, titanium, zinc, and carbon. As a method for adding the impurity, plasma treatment, ion implantation, ion doping, plasma immersion ion implantation, or the like can be used.

When the above element is added as an impurity element to the oxide semiconductor layer, a bond between a metal element and oxygen in the oxide semiconductor layer is cut, so that an oxygen vacancy is formed. Interaction between an oxygen vacancy in the oxide semiconductor layer and hydrogen that remains in the oxide semiconductor layer or is added to the oxide semiconductor layer later can increase the conductivity of the oxide semiconductor layer.

When hydrogen is added to an oxide semiconductor in which an oxygen vacancy is formed by addition of an impurity element, hydrogen enters an oxygen vacant site and forms a donor level in the vicinity of the conduction band. Consequently, an oxide conductor can be formed. Here, an oxide conductor refers to an oxide semiconductor having become a conductor. Note that the oxide conductor has a light-transmitting property like the oxide semiconductor.

The oxide conductor is a degenerated semiconductor and it is suggested that the conduction band edge equals or substantially equals the Fermi level. For that reason, an ohmic contact is made between an oxide conductor layer and conductive layers functioning as a source electrode and a drain electrode; thus, contact resistance between the oxide conductor layer and the conductive layers functioning as a source electrode and a drain electrode can be reduced.

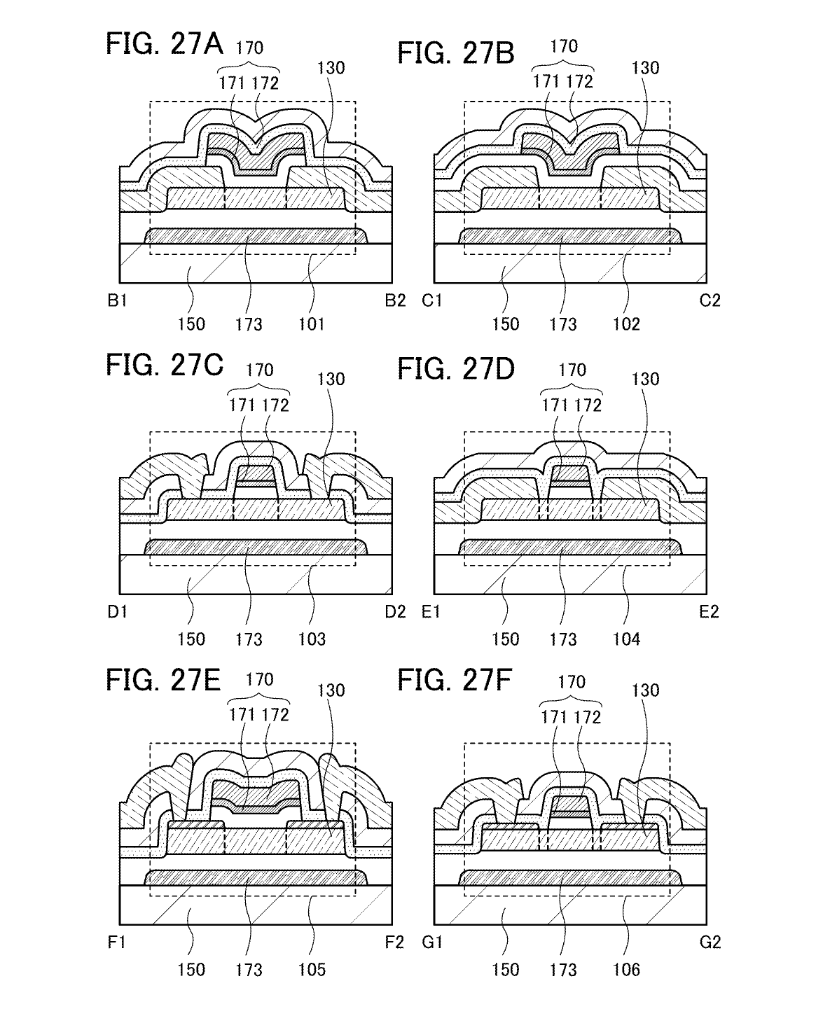

The transistor in one embodiment of the present invention may include a conductive layer 173 between the oxide semiconductor layer 130 and the substrate 115 as illustrated in cross-sectional views in the channel length direction in FIGS. 27A to 27F and cross-sectional views in the channel width direction in FIGS. 26C and 26D. When the conductive layer 173 is used as a second gate electrode (back gate), the on-state current can be increased or the threshold voltage can be controlled. In the cross-sectional views in FIGS. 27A to 27F, the width of the conductive layer 173 may be shorter than that of the oxide semiconductor layer 130. Moreover, the width of the conductive layer 173 may be shorter than that of the conductive layer 170.

In order to increase the on-state current, for example, the conductive layers 170 and 173 are made to have the same potential, and the transistor is driven as a double-gate transistor. Furthermore, in order to control the threshold voltage, a fixed potential that is different from the potential of the conductive layer 170 is applied to the conductive layer 173. To set the conductive layers 170 and 173 at the same potential, for example, as illustrated in FIG. 26D, the conductive layers 170 and 173 may be electrically connected to each other through a contact hole.

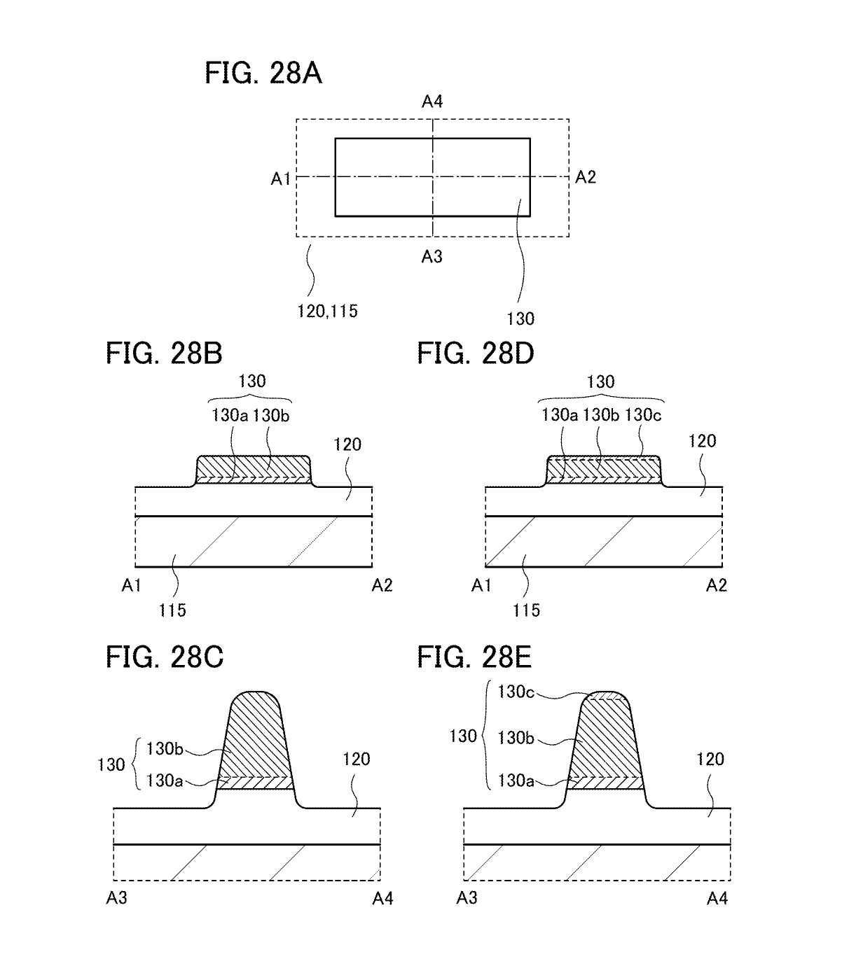

Although the transistors 101 to 106 in FIGS. 20A and 20B, FIGS. 21A and 21B, FIGS. 22A and 22B, FIGS. 23A and 23B, FIGS. 24A and 24B, and FIGS. 25A and 25B are examples in which the oxide semiconductor layer 130 is a single layer, the oxide semiconductor layer 130 may be a stacked layer. The oxide semiconductor layer 130 in the transistors 101 to 106 can be replaced with the oxide semiconductor layer 130 in FIGS. 28B and 28C or FIGS. 28D and 28E.

FIG. 28A is a top view of the oxide semiconductor layer 130, and FIGS. 28B and 28C are cross-sectional views of the oxide semiconductor layer 130 with a two-layer structure. FIGS. 28D and 28E are cross-sectional views of the oxide semiconductor layer 130 with a three-layer structure.

Oxide semiconductor layers with different compositions, for example, can be used as an oxide semiconductor layer 130a, an oxide semiconductor layer 130b, and an oxide semiconductor layer 130c.

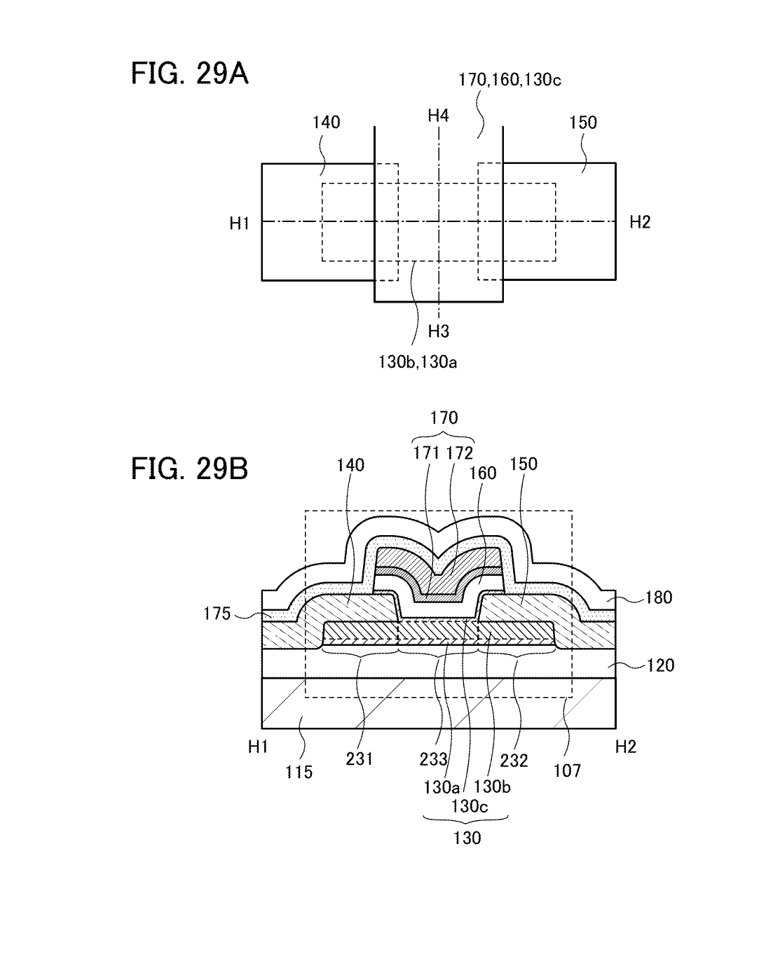

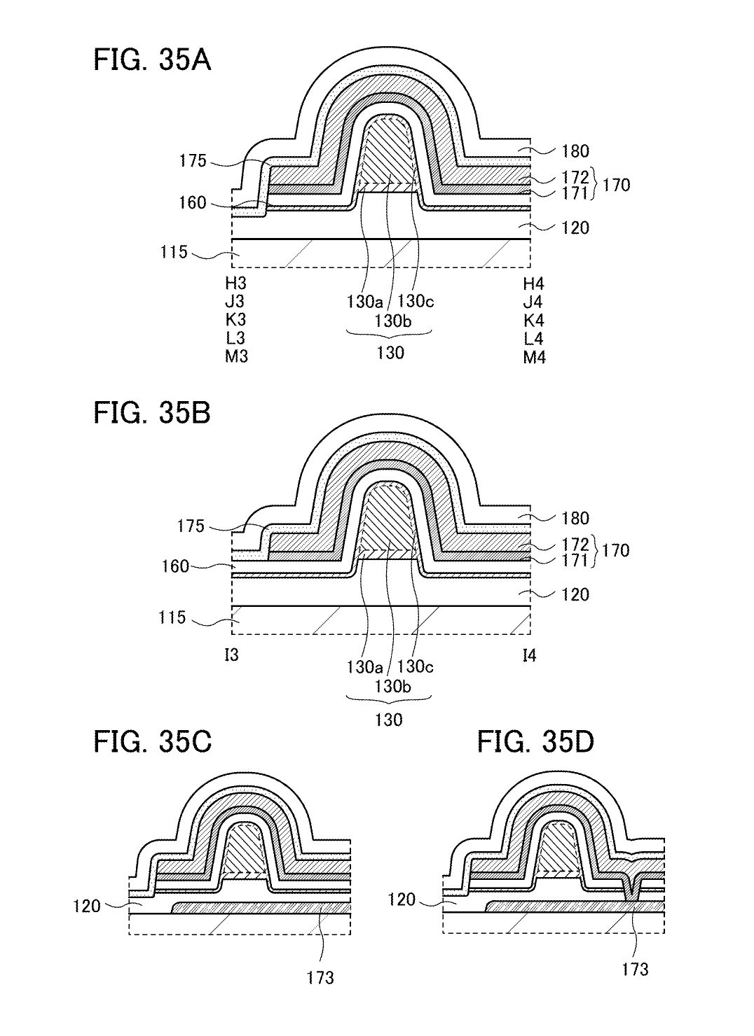

The transistor in one embodiment of the present invention may have a structure illustrated in FIGS. 29A and 29B. FIG. 29A is a top view of a transistor 107. A cross section in the direction of dashed-dotted line H1-H2 in FIG. 29A is illustrated in FIG. 29B. A cross section in the direction of dashed-dotted line H3-H4 in FIG. 29A is illustrated in FIG. 35A. The direction of dashed-dotted line H1-H2 is referred to as a channel length direction, and the direction of dashed-dotted line H3-H4 is referred to as a channel width direction.

The transistor 107 includes the insulating layer 120 in contact with the substrate 115; a stack of the oxide semiconductor layers 130a and 130b in contact with the insulating layer 120; the conductive layers 140 and 150 electrically connected to the stack; the oxide semiconductor layer 130c in contact with the stack and the conductive layers 140 and 150; the insulating layer 160 in contact with the oxide semiconductor layer 130c; the conductive layer 170 in contact with the insulating layer 160; the insulating layer 175 in contact with the conductive layers 140 and 150, the oxide semiconductor layer 130c, the insulating layer 160, and the conductive layer 170; and the insulating layer 180 in contact with the insulating layer 175. The insulating layer 180 may function as a planarization film as necessary.

The transistor 107 has the same structure as the transistor 101 except that the oxide semiconductor layer 130 includes two layers (the oxide semiconductor layers 130a and 130b) in the regions 231 and 232, that the oxide semiconductor layer 130 includes three layers (the oxide semiconductor layers 130a to 130c) in the region 233, and that part of the oxide semiconductor layer (the oxide semiconductor layer 130c) exists between the insulating layer 160 and the conductive layers 140 and 150.

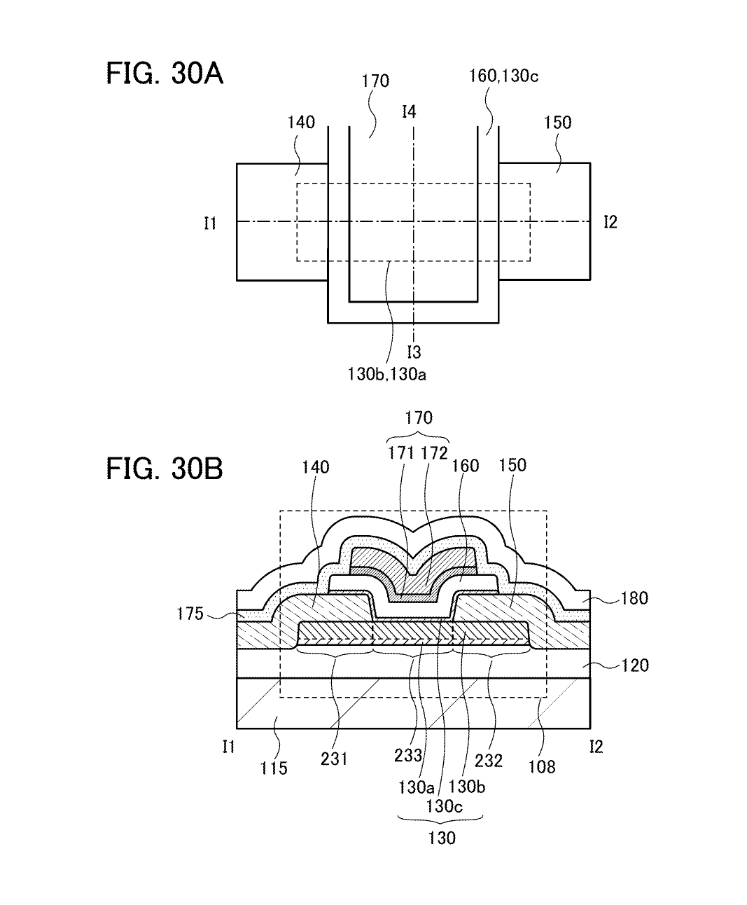

The transistor in one embodiment of the present invention may have a structure illustrated in FIGS. 30A and 30B. FIG. 30A is a top view of a transistor 108. A cross section in the direction of dashed-dotted line I1-I2 in FIG. 30A is illustrated in FIG. 30B. A cross section in the direction of dashed-dotted line I3-I4 in FIG. 30A is illustrated in FIG. 35B. The direction of dashed-dotted line I1-I2 is referred to as a channel length direction, and the direction of dashed-dotted line I3-I4 is referred to as a channel width direction.

The transistor 108 differs from the transistor 107 in that end portions of the insulating layer 160 and the oxide semiconductor layer 130c are not aligned with the end portion of the conductive layer 170.

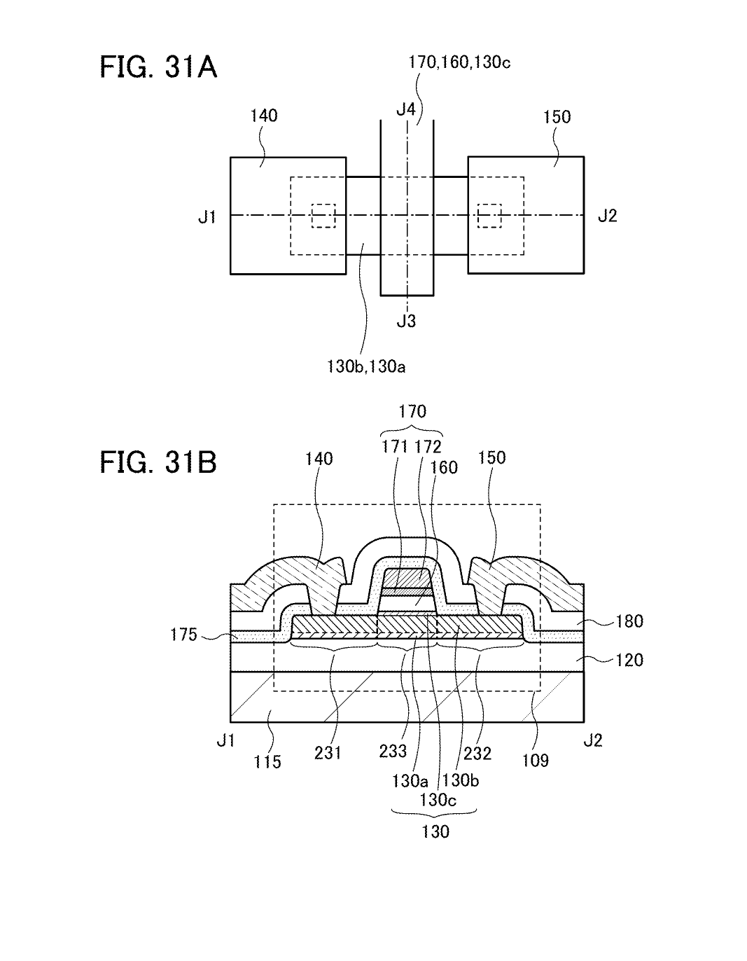

The transistor in one embodiment of the present invention may have a structure illustrated in FIGS. 31A and 31B. FIG. 31A is a top view of a transistor 109. A cross section in the direction of dashed-dotted line J1-J2 in FIG. 31A is illustrated in FIG. 31B. A cross section in the direction of dashed-dotted line J3-J4 in FIG. 31A is illustrated in FIG. 35A. The direction of dashed-dotted line J1-J2 is referred to as a channel length direction, and the direction of dashed-dotted line J3-J4 is referred to as a channel width direction.

The transistor 109 includes the insulating layer 120 in contact with the substrate 115; a stack of the oxide semiconductor layers 130a and 130b in contact with the insulating layer 120; the oxide semiconductor layer 130c in contact with the stack; the insulating layer 160 in contact with the oxide semiconductor layer 130c; the conductive layer 170 in contact with the insulating layer 160; the insulating layer 175 covering the stack, the oxide semiconductor layer 130c, the insulating layer 160, and the conductive layer 170; the insulating layer 180 in contact with the insulating layer 175; and the conductive layers 140 and 150 electrically connected to the stack through openings provided in the insulating layers 175 and 180. The transistor 109 may further include, for example, an insulating layer (planarization film) in contact with the insulating layer 180 and the conductive layers 140 and 150 as necessary.

The transistor 109 has the same structure as the transistor 103 except that the oxide semiconductor layer 130 includes two layers (the oxide semiconductor layers 130a and 130b) in the regions 231 and 232 and that the oxide semiconductor layer 130 includes three layers (the oxide semiconductor layers 130a to 130c) in the region 233.

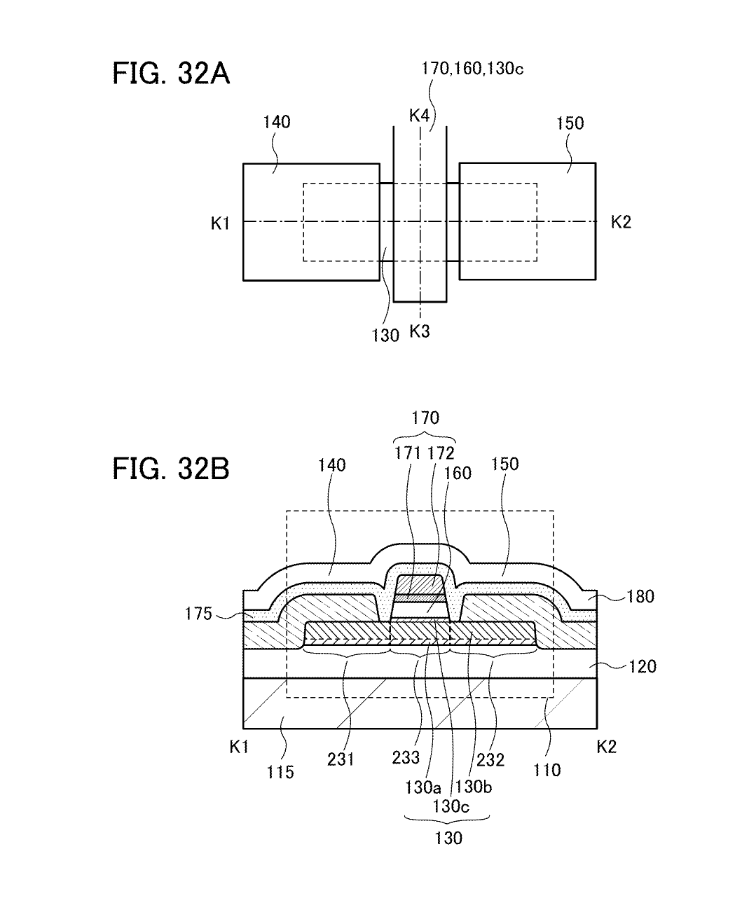

The transistor in one embodiment of the present invention may have a structure illustrated in FIGS. 32A and 32B. FIG. 32A is a top view of a transistor 110. A cross section in the direction of dashed-dotted line K1-K2 in FIG. 32A is illustrated in FIG. 32B. A cross section in the direction of dashed-dotted line K3-K4 in FIG. 32A is illustrated in FIG. 35A. The direction of dashed-dotted line K1-K2 is referred to as a channel length direction, and the direction of dashed-dotted line K3-K4 is referred to as a channel width direction.

The transistor 110 has the same structure as the transistor 104 except that the oxide semiconductor layer 130 includes two layers (the oxide semiconductor layers 130a and 130b) in the regions 231 and 232 and that the oxide semiconductor layer 130 includes three layers (the oxide semiconductor layers 130a to 130c) in the region 233.

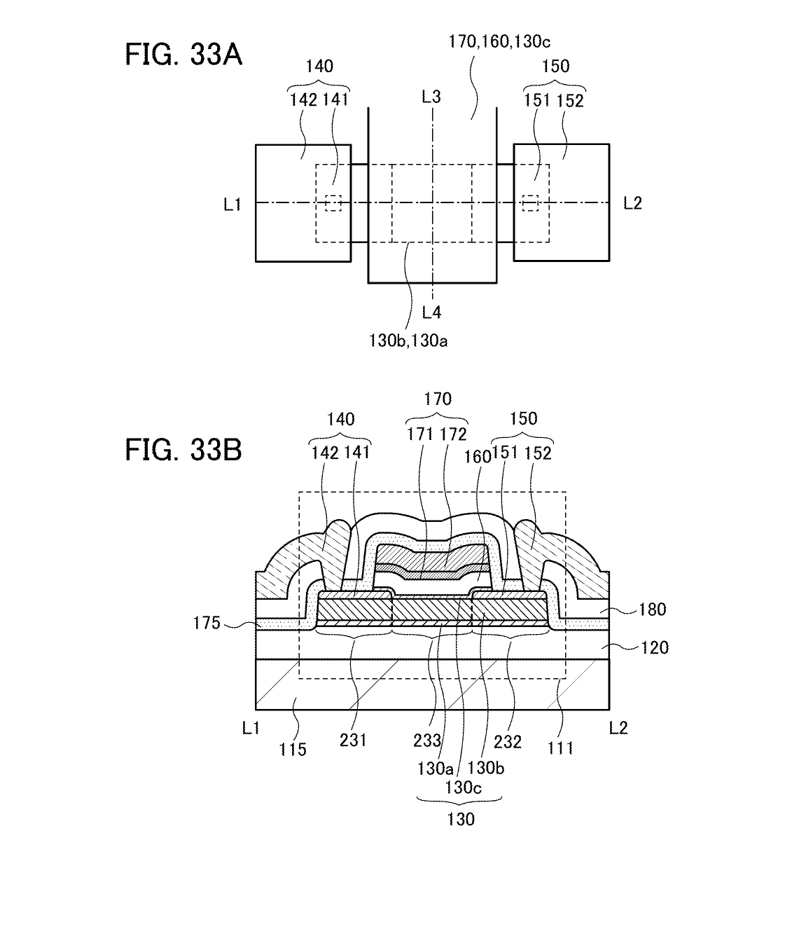

The transistor in one embodiment of the present invention may have a structure illustrated in FIGS. 33A and 33B. FIG. 33A is a top view of a transistor 111. A cross section in the direction of dashed-dotted line L1-L2 in FIG. 33A is illustrated in FIG. 33B. A cross section in the direction of dashed-dotted line L3-L4 in FIG. 33A is illustrated in FIG. 35A. The direction of dashed-dotted line L1-L2 is referred to as a channel length direction, and the direction of dashed-dotted line L3-L4 is referred to as a channel width direction.

The transistor 111 includes the insulating layer 120 in contact with the substrate 115; a stack of the oxide semiconductor layers 130a and 130b in contact with the insulating layer 120; the conductive layers 141 and 151 electrically connected to the stack; the oxide semiconductor layer 130c in contact with the stack and the conductive layers 141 and 151; the insulating layer 160 in contact with the oxide semiconductor layer 130c; the conductive layer 170 in contact with the insulating layer 160; the insulating layer 175 in contact with the stack, the conductive layers 141 and 151, the oxide semiconductor layer 130c, the insulating layer 160, and the conductive layer 170; the insulating layer 180 in contact with the insulating layer 175; and the conductive layers 142 and 152 electrically connected to the conductive layers 141 and 151, respectively, through openings provided in the insulating layers 175 and 180. The transistor 111 may further include, for example, an insulating layer (planarization film) in contact with the insulating layer 180 and the conductive layers 142 and 152 as necessary.

The transistor 111 has the same structure as the transistor 105 except that the oxide semiconductor layer 130 includes two layers (the oxide semiconductor layers 130a and 130b) in the regions 231 and 232, that the oxide semiconductor layer 130 includes three layers (the oxide semiconductor layers 130a to 130c) in the region 233, and that part of the oxide semiconductor layer (the oxide semiconductor layer 130c) exists between the insulating layer 160 and the conductive layers 141 and 151.

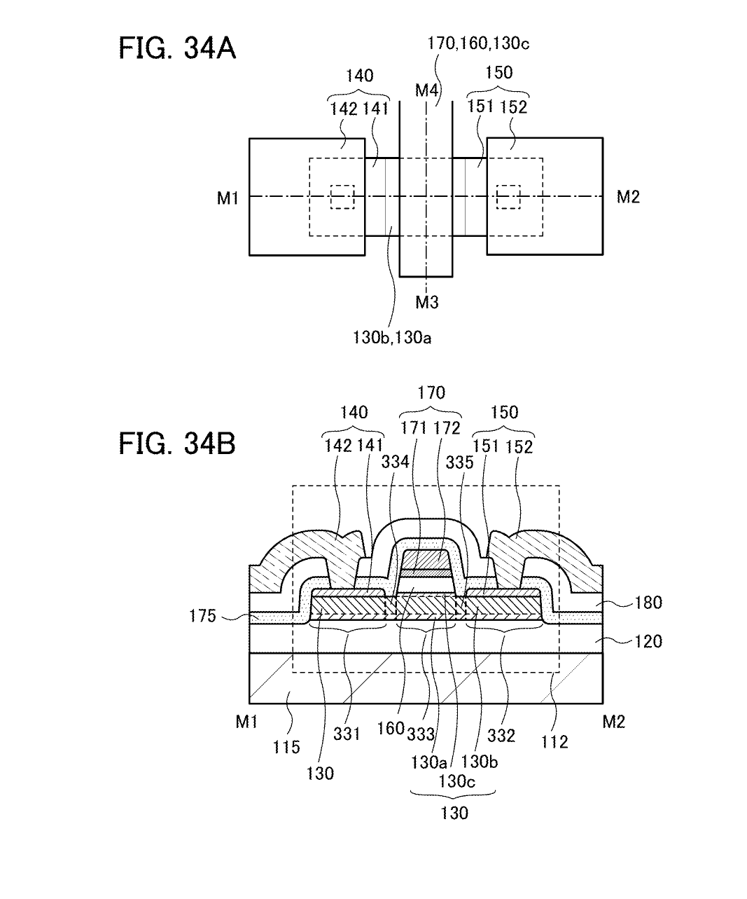

The transistor in one embodiment of the present invention may have a structure illustrated in FIGS. 34A and 34B. FIG. 34A is a top view of a transistor 112. A cross section in the direction of dashed-dotted line M1-M2 in FIG. 34A is illustrated in FIG. 34B. A cross section in the direction of dashed-dotted line M3-M4 in FIG. 34A is illustrated in FIG. 35A. The direction of dashed-dotted line M1-M2 is referred to as a channel length direction, and the direction of dashed-dotted line M3-M4 is referred to as a channel width direction.

The transistor 112 has the same structure as the transistor 106 except that the oxide semiconductor layer 130 includes two layers (the oxide semiconductor layers 130a and 130b) in the regions 331, 332, 334, and 335 and that the oxide semiconductor layer 130 includes three layers (the oxide semiconductor layers 130a to 130c) in the region 333.

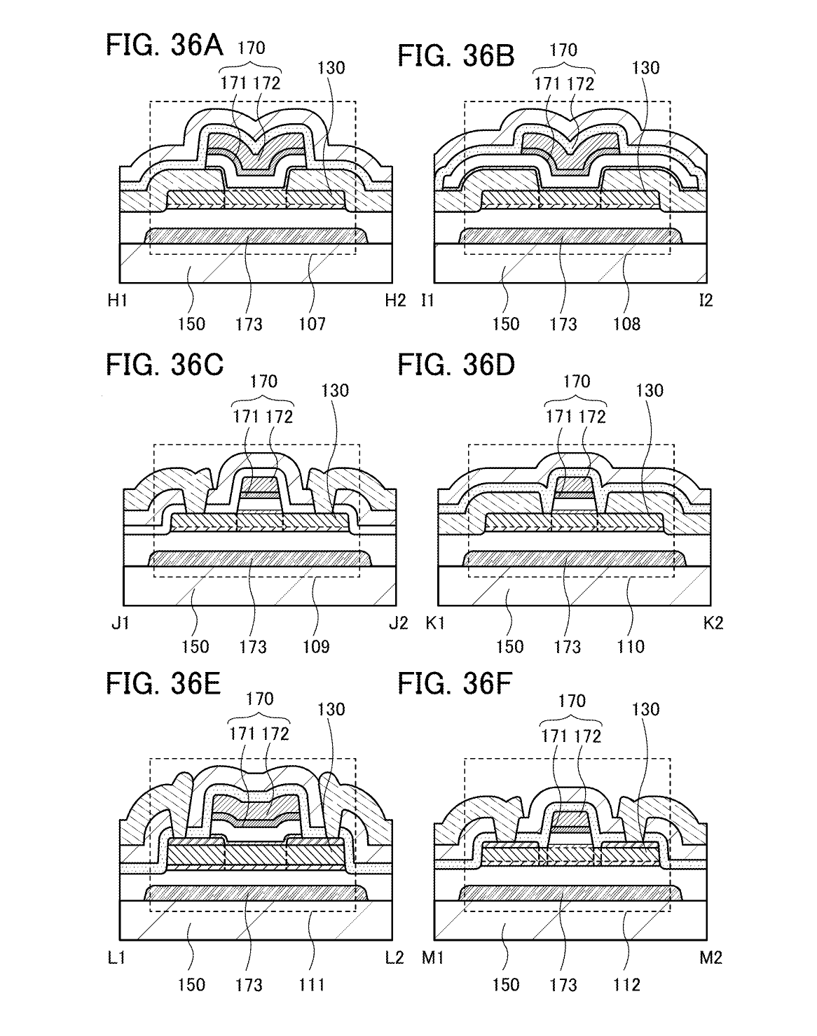

The transistor in one embodiment of the present invention may include the conductive layer 173 between the oxide semiconductor layer 130 and the substrate 115 as illustrated in cross-sectional views in the channel length direction in FIGS. 36A to 36F and cross-sectional views in the channel width direction in FIGS. 35C and 35D. When the conductive layer is used as a second gate electrode (back gate), the on-state current can be further increased or the threshold voltage can be controlled. In the cross-sectional views in FIGS. 36A to 36F, the width of the conductive layer 173 may be shorter than that of the oxide semiconductor layer 130. Moreover, the width of the conductive layer 173 may be shorter than that of the conductive layer 170.

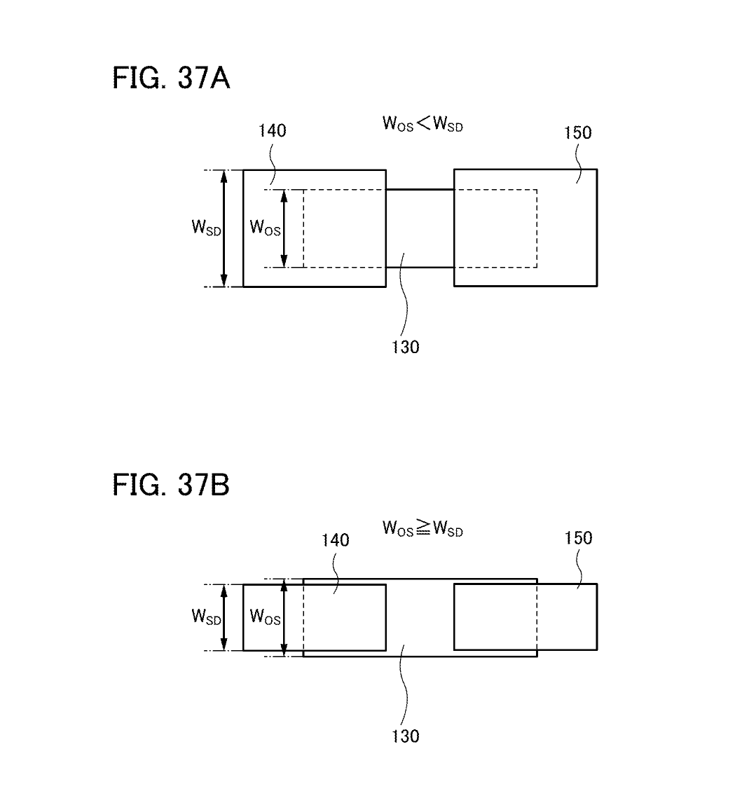

Furthermore, as shown in the top views in FIGS. 37A and 37B (showing only the oxide semiconductor layer 130, the conductive layer 140, and the conductive layer 150), the widths (W_{SD}) of the conductive layer 140 (source electrode) and the conductive layer 150 (drain electrode) in the transistor of one embodiment of the present invention may be either longer than or shorter than the width (W_{OS}) of the oxide semiconductor layer 130. When W_{OS}≧W_{SD} (W_{SD} is less than or equal to W_{OS}) is satisfied, a gate electric field is easily applied to the entire oxide semiconductor layer 130, so that electrical characteristics of the transistor can be improved.

In the transistor in one embodiment of the present invention (any of the transistors 101 to 112), the conductive layer 170 functioning as a gate electrode electrically surrounds the oxide semiconductor layer 130 in the channel width direction with the insulating layer 160 functioning as a gate insulating film positioned therebetween. This structure increases the on-state current. Such a transistor structure is referred to as a surrounded channel (s-channel) structure.

In the transistor including the oxide semiconductor layers 130a and 130b and the transistor including the oxide semiconductor layers 130a to 130c, selecting appropriate materials for the two or three layers forming the oxide semiconductor layer 130 makes current flow to the oxide semiconductor layer 130b. Since current flows to the oxide semiconductor layer 130b, the current is hardly influenced by interface scattering, leading to high on-state current. Note that increasing the thickness of the oxide semiconductor layer 130b can increase the on-state current. The thickness of the oxide semiconductor layer 130b may be, for example, 100 nm to 200 nm.

A semiconductor device including a transistor with any of the above structures can have favorable electrical characteristics.

The structures described in this embodiment can be combined with any of the structures described in the other embodiments and example as appropriate.

### Embodiment 5

In this embodiment, components of the transistors described in Embodiment 4 will be described in detail.

As the substrate 115, a glass substrate, a quartz substrate, a semiconductor substrate, a ceramic substrate, a metal substrate with an insulated surface, or the like can be used. Alternatively, a silicon substrate provided with a transistor, a photodiode, or the like can be used, and an insulating layer, a wiring, a conductor functioning as a contact plug, and the like may be provided over the silicon substrate. Note that when p-channel transistors are formed using the silicon substrate, a silicon substrate with n⁻-type conductivity is preferably used. Alternatively, an SOI substrate including an n⁻-type or i-type silicon layer may be used. In the case where a p-channel transistor is formed on the silicon substrate, it is preferable to use a silicon substrate in which a plane where the transistor is formed is a (110) plane orientation. Forming a p-channel transistor with the (110) plane can increase mobility.

The insulating layer 120 can have a function of supplying oxygen to the oxide semiconductor layer 130 as well as a function of preventing diffusion of impurities from a component included in the substrate 115. For this reason, the insulating layer 120 is preferably an insulating film containing oxygen and further preferably, the insulating layer 120 is an insulating film containing oxygen in which the oxygen content is higher than that in the stoichiometric composition. For example, the insulating layer 120 is a film of which the amount of released oxygen when converted into oxygen atoms is 1.0×10¹⁹ atoms/cm³ or more in thermal desorption spectroscopy (TDS) analysis performed such that the surface temperature is higher than or equal to 100° C. and lower than or equal to 700° C., preferably higher than or equal to 100° C. and lower than or equal to 500° C. In the case where the substrate 115 is provided with another device, the insulating layer 120 also has a function as an interlayer insulating film. In that case, the insulating layer 120 is preferably subjected to planarization treatment such as chemical mechanical polishing (CMP) treatment so as to have a flat surface.

For example, the insulating layer 120 can be formed using an oxide insulating film including aluminum oxide, magnesium oxide, silicon oxide, silicon oxynitride, gallium oxide, germanium oxide, yttrium oxide, zirconium oxide, lanthanum oxide, neodymium oxide, hafnium oxide, tantalum oxide, or the like; a nitride insulating film including silicon nitride, silicon nitride oxide, aluminum nitride, aluminum nitride oxide, or the like; or a mixed material of any of these. The insulating layer 120 may be a stack of any of the above materials.

In this embodiment, detailed description is given mainly on the case where the oxide semiconductor layer 130 of the transistor has a three-layer structure in which the oxide semiconductor layers 130a to 130c are sequentially stacked from the insulating layer 120 side.

Note that in the case where the oxide semiconductor layer 130 is a single layer, a layer corresponding to the oxide semiconductor layer 130b described in this embodiment is used.

In the case where the oxide semiconductor layer 130 has a two-layer structure, a stack in which layers corresponding to the oxide semiconductor layer 130a and the oxide semiconductor layer 130b described in this embodiment are sequentially stacked from the insulating layer 120 side is used. In such a case, the oxide semiconductor layers 130a and 130b can be replaced with each other.

In the case where the oxide semiconductor layer 130 has a layered structure of four or more layers, for example, a structure in which another oxide semiconductor layer is added to the three-layer stack of the oxide semiconductor layer 130 described in this embodiment can be employed.

For the oxide semiconductor layer 130b, for example, an oxide semiconductor whose electron affinity (an energy difference between a vacuum level and the conduction band minimum) is higher than those of the oxide semiconductor layers 130a and 130c is used. The electron affinity can be obtained by subtracting an energy difference between the conduction band minimum and the valence band maximum (what is called an energy gap) from an energy difference between the vacuum level and the valence band maximum (what is called an ionization potential).

The oxide semiconductor layers 130a and 130c each contain one or more kinds of metal elements contained in the oxide semiconductor layer 130b. For example, the oxide semiconductor layers 130a and 130c are preferably formed using an oxide semiconductor whose conduction band minimum is closer to a vacuum level than that of the oxide semiconductor layer 130b by 0.05 eV or more, 0.07 eV or more, 0.1 eV or more, or 0.15 eV or more and 2 eV or less, 1 eV or less, 0.5 eV or less, or 0.4 eV or less.

In such a structure, when an electric field is applied to the conductive layer 170, a channel is formed in the oxide semiconductor layer 130b whose conduction band minimum is the lowest in the oxide semiconductor layer 130.

Furthermore, since the oxide semiconductor layer 130a contains one or more kinds of metal elements contained in the oxide semiconductor layer 130b, an interface state is unlikely to be formed at the interface between the oxide semiconductor layers 130a and 130b, compared with the interface between the oxide semiconductor layer 130b and the insulating layer 120 on the assumption that the oxide semiconductor layer 130b is in contact with the insulating layer 120. The interface state sometimes forms a channel; therefore, the threshold voltage of the transistor is changed in some cases. Thus, with the oxide semiconductor layer 130a, variations in electrical characteristics of the transistor, such as a threshold voltage, can be reduced. Moreover, the reliability of the transistor can be improved.

Since the oxide semiconductor layer 130c contains one or more kinds of metal elements contained in the oxide semiconductor layer 130b, scattering of carriers is unlikely to occur at the interface between the oxide semiconductor layers 130b and 130c, compared with the interface between the oxide semiconductor layer 130b and the gate insulating film (the insulating layer 160) on the assumption that the oxide semiconductor layer 130b is in contact with the gate insulating film. Thus, with the oxide semiconductor layer 130c, the field-effect mobility of the transistor can be increased.

For the oxide semiconductor layers 130a and 130c, for example, a material containing Al, Ti, Ga, Ge, Y, Zr, Sn, La, Ce, or Hf with a higher atomic ratio than that used for the oxide semiconductor layer 130b can be used. Specifically, the atomic ratio of any of the above metal elements in the oxide semiconductor layers 130a and 130c is 1.5 times or more, preferably 2 times or more, further preferably 3 times or more as large as that in the oxide semiconductor layer 130b. Any of the above metal elements is strongly bonded to oxygen and thus has a function of suppressing generation of an oxygen vacancy in the oxide semiconductor layers 130a and 130c. That is, an oxygen vacancy is less likely to be generated in the oxide semiconductor layers 130a and 130c than in the oxide semiconductor layer 130b.

An oxide semiconductor that can be used for each of the oxide semiconductor layers 130a to 130c preferably contains at least In or Zn. Both In and Zn are preferably contained. In order to reduce variations in electrical characteristics of the transistor including the oxide semiconductor, the oxide semiconductor preferably contains a stabilizer in addition to In and Zn.

Examples of a stabilizer include Ga, Sn, Hf, Al, and Zr. Other examples of the stabilizer include lanthanoids such as La, Ce, Pr, Nd, Sm, Eu, Gd, Tb, Dy, Ho, Er, Tm, Yb, and Lu.

As the oxide semiconductor, for example, any of the following can be used: indium oxide, tin oxide, gallium oxide, zinc oxide, an In—Zn oxide, a Sn—Zn oxide, an Al—Zn oxide, a Zn—Mg oxide, a Sn—Mg oxide, an In—Mg oxide, an In—Ga oxide, an In—Ga—Zn oxide, an In—Al—Zn oxide, an In—Sn—Zn oxide, a Sn—Ga—Zn oxide, an Al—Ga—Zn oxide, a Sn—Al—Zn oxide, an In—Hf—Zn oxide, an In—La—Zn oxide, an In—Ce—Zn oxide, an In—Pr—Zn oxide, an In—Nd—Zn oxide, an In—Sm—Zn oxide, an In—Eu—Zn oxide, an In—Gd—Zn oxide, an In—Tb—Zn oxide, an In—Dy—Zn oxide, an In—Ho—Zn oxide, an In—Er—Zn oxide, an In—Tm—Zn oxide, an In—Yb—Zn oxide, an In—Lu—Zn oxide, an In—Sn—Ga—Zn oxide, an In—Hf—Ga—Zn oxide, an In—Al—Ga—Zn oxide, an In—Sn—Al—Zn oxide, an In—Sn—Hf—Zn oxide, and an In—Hf—Al—Zn oxide.

For example, an In—Ga—Zn oxide means an oxide containing In, Ga, and Zn as its main components. The In—Ga—Zn oxide may contain another metal element in addition to In, Ga, and Zn. In this specification, a film containing the In—Ga—Zn oxide is also referred to as an IGZO film.

A material represented by InMO₃(ZnO)ₘ (m>0, where m is not an integer) may be used. Note that M represents one or more metal elements selected from Ga, Y, Zr, La, Ce, and Nd. Alternatively, a material represented by In₂SnO₅(ZnO)ₙ (n>0, where n is an integer) may be used.

Note that when each of the oxide semiconductor layers 130a to 130c is an In—M—Zn oxide containing at least indium, zinc, and M (M is a metal such as Al, Ti, Ga, Ge, Y, Zr, Sn, La, Ce, or Hf), in the case where the oxide semiconductor layer 130a has an atomic ratio of In to M and Zn which is x₁:y₁:z₁, the oxide semiconductor layer 130b has an atomic ratio of In to M and Zn which is x₂:y₂:z₂, and the oxide semiconductor layer 130c has an atomic ratio of In to M and Zn which is x₃:y₃:z₃, each of y₁/x₁ and y₃/x₃ is preferably larger than y₂/x₂. Each of y₁/x₁ and y₃/x₃ is 1.5 times or more, preferably 2 times or more, more preferably 3 times or more as large as y₂/x₂. At this time, when y₂ is greater than or equal to x₂ in the oxide semiconductor layer 130b, the transistor can have stable electrical characteristics. However, when y₂ is 3 times or more as large as x₂, the field-effect mobility of the transistor is reduced; accordingly, y₂ is preferably smaller than 3 times x₂.

In the case where Zn and O are not taken into consideration, the proportion of In and the proportion of M in each of the oxide semiconductor layers 130a and 130c are preferably less than 50 atomic % and greater than or equal to 50 atomic %, respectively, more preferably less than 25 atomic % and greater than or equal to 75 atomic %, respectively. Furthermore, in the case where Zn and O are not taken into consideration, the proportion of In and the proportion of M in the oxide semiconductor layer 130b are preferably greater than or equal to 25 atomic % and less than 75 atomic %, respectively, more preferably greater than or equal to 34 atomic % and less than 66 atomic %, respectively.

The indium content in the oxide semiconductor layer 130b is preferably higher than those in the oxide semiconductor layers 130a and 130c. In an oxide semiconductor, the s orbital of heavy metal mainly contributes to carrier transfer, and when the proportion of In in the oxide semiconductor is increased, overlap of the s orbitals is likely to be increased. Therefore, an oxide in which the proportion of In is higher than that of M has higher mobility than an oxide in which the proportion of In is equal to or lower than that of M. Thus, with the use of an oxide having a high content of indium for the oxide semiconductor layer 130b, a transistor having high field-effect mobility can be obtained.

The thickness of the oxide semiconductor layer 130a is greater than or equal to 3 nm and less than or equal to 100 nm, preferably greater than or equal to 5 nm and less than or equal to 50 nm, more preferably greater than or equal to 5 nm and less than or equal to 25 nm. The thickness of the oxide semiconductor layer 130b is greater than or equal to 3 nm and less than or equal to 200 nm, preferably greater than or equal to 10 nm and less than or equal to 150 nm, more preferably greater than or equal to 15 nm and less than or equal to 100 nm. The thickness of the oxide semiconductor layer 130c is greater than or equal to 1 nm and less than or equal to 50 nm, preferably greater than or equal to 2 nm and less than or equal to 30 nm, more preferably greater than or equal to 3 nm and less than or equal to 15 nm. In addition, the oxide semiconductor layer 130b is preferably thicker than the oxide semiconductor layers 130a and 130c.

In order that a transistor in which a channel is formed in an oxide semiconductor layer have stable electrical characteristics, it is effective to make the oxide semiconductor layer intrinsic or substantially intrinsic by reducing the concentration of impurities in the oxide semiconductor layer. The term “substantially intrinsic” refers to a state where an oxide semiconductor layer has a carrier density lower than 1×10¹⁷/cm³, lower than 1×10¹⁵/cm³, or lower than 1×10¹³/cm³.

In the oxide semiconductor layer, hydrogen, nitrogen, carbon, silicon, and a metal element other than main components of the oxide semiconductor layer are impurities. For example, hydrogen and nitrogen form donor levels to increase the carrier density, and silicon forms impurity levels in the oxide semiconductor layer. The impurity levels serve as traps and might cause deterioration of electrical characteristics of the transistor. Therefore, it is preferable to reduce the concentration of the impurities in the oxide semiconductor layers 130a to 130c and at interfaces between the oxide semiconductor layers.

In order to make the oxide semiconductor layer intrinsic or substantially intrinsic, the oxide semiconductor layer is controlled to have a region in which the concentration of silicon estimated by secondary ion mass spectrometry (SIMS) is lower than 1×10¹⁹ atoms/cm³, preferably lower than 5×10¹⁸ atoms/cm³, more preferably lower than 1×10¹⁸ atoms/cm³. In addition, the oxide semiconductor layer is controlled to have a region in which the concentration of hydrogen is lower than or equal to 2×10²⁰ atoms/cm³, preferably lower than or equal to 5×10¹⁹ atoms/cm³, more preferably lower than or equal to 1×10¹⁹ atoms/cm³, still more preferably lower than or equal to 5×10¹⁸ atoms/cm³. Furthermore, the concentration of nitrogen at a certain depth of the oxide semiconductor layer or in a region of the oxide semiconductor layer is lower than 5×10¹⁹ atoms/cm³, preferably lower than or equal to 5×10¹⁸ atoms/cm³, more preferably lower than or equal to 1×10¹⁸ atoms/cm³, still more preferably lower than or equal to 5×10¹⁷ atoms/cm³.

The high concentration of silicon or carbon might reduce the crystallinity of the oxide semiconductor layer. In order not to lower the crystallinity of the oxide semiconductor layer, for example, the oxide semiconductor layer is controlled to have a region in which the concentration of silicon is lower than 1×10¹⁹ atoms/cm³, preferably lower than 5×10¹⁸ atoms/cm³, more preferably lower than 1×10¹⁸ atoms/cm³. Furthermore, the oxide semiconductor layer is controlled to have a region in which the concentration of carbon is lower than 1×10¹⁹ atoms/cm³, preferably lower than 5×10¹⁸ atoms/cm³, more preferably lower than 1×10¹⁸ atoms/cm³.

As described above, a transistor in which a highly purified oxide semiconductor film is used for a channel formation region exhibits an extremely low off-state current. When voltage between a source and a drain is set at about 0.1 V, 5 V, or 10 V, for example, the off-state current per channel width of the transistor can be as low as several yoctoamperes per micrometer to several zeptoamperes per micrometer.

As the gate insulating film of the transistor, an insulating film containing silicon is used in many cases; thus, it is preferable that, as in the transistor of one embodiment of the present invention, a region of the oxide semiconductor layer that serves as a channel not be in contact with the gate insulating film for the above reason. In the case where a channel is formed at the interface between the gate insulating film and the oxide semiconductor layer, scattering of carriers occurs at the interface, so that the field-effect mobility of the transistor is reduced. Also from the view of the above, it is preferable that the region of the oxide semiconductor layer that serves as a channel be separated from the gate insulating film.

Accordingly, with the oxide semiconductor layer 130 having a layered structure including the oxide semiconductor layers 130a to 130c, a channel can be formed in the oxide semiconductor layer 130b; thus, the transistor can have high field-effect mobility and stable electrical characteristics.

In a band structure, the conduction band minimums of the oxide semiconductor layers 130a to 130c are continuous. This can be understood also from the fact that the compositions of the oxide semiconductor layers 130a to 130c are close to one another and oxygen is easily diffused among the oxide semiconductor layers 130a to 130c. Thus, the oxide semiconductor layers 130a to 130c have a continuous physical property though they have different compositions and form a stack. In the drawings as shown in FIGS. 28B, 28C, 28D and 28E, for example, interfaces between the oxide semiconductor layers of the stack are indicated by dotted lines.

The oxide semiconductor layer 130 in which layers containing the same main components are stacked is formed to have not only a simple layered structure of the layers but also a continuous energy band (here, in particular, a well structure having a U shape in which the conduction band minimums are continuous (U-shape well)). In other words, the layered structure is formed such that there exists no impurity that forms a defect level such as a trap center or a recombination center at each interface. If impurities exist between the stacked oxide semiconductor layers, the continuity of the energy band is lost and carriers disappear by a trap or recombination at the interface.

For example, an In—Ga—Zn oxide whose atomic ratio of In to Ga and Zn is 1:3:2, 1:3:3, 1:3:4, 1:3:6, 1:4:5, 1:6:4, or 1:9:6 can be used for the oxide semiconductor layers 130a and 130c, and an In—Ga—Zn oxide whose atomic ratio of In to Ga and Zn is 1:1:1, 2:1:3, 5:5:6, or 3:1:2 can be used for the oxide semiconductor layer 130b. In the case where each of the oxide semiconductor layers 130a to 130c is formed using the above oxide as a sputtering target, the obtained oxide semiconductor layers 130a to 130c do not necessarily have the same atomic ratio and have a difference of about ±20%.

The oxide semiconductor layer 130b of the oxide semiconductor layer 130 serves as a well, so that a channel is formed in the oxide semiconductor layer 130b. Note that since the conduction band minimums are continuous, the oxide semiconductor layer 130 can also be referred to as a U-shaped well. Furthermore, a channel formed to have such a structure can also be referred to as a buried channel.

Note that trap levels due to impurities or defects might be formed in the vicinity of the interface between an insulating layer such as a silicon oxide film and each of the oxide semiconductor layers 130a and 130c. The oxide semiconductor layer 130b can be distanced away from the trap levels owing to the existence of the oxide semiconductor layers 130a and 130c.

However, when the energy differences between the conduction band minimum of the oxide semiconductor layer 130b and the conduction band minimum of each of the oxide semiconductor layers 130a and 130c are small, an electron in the oxide semiconductor layer 130b might reach the trap level by passing over the energy differences. When the electron is trapped in the trap level, negative charge is generated at the interface with the insulating layer, so that the threshold voltage of the transistor is shifted in the positive direction.

The oxide semiconductor layers 130a to 130c preferably include crystal parts. In particular, when crystals with c-axis alignment are used, the transistor can have stable electrical characteristics. Moreover, crystals with c-axis alignment are resistant to bending; therefore, using such crystals can improve the reliability of a semiconductor device using a flexible substrate.

As the conductive layer 140 functioning as a source electrode and the conductive layer 150 functioning as a drain electrode, for example, a single layer or a stacked layer formed using a material selected from Al, Cr, Cu, Ta, Ti, Mo, W, Ni, Mn, Nd, and Sc and alloys of any of these metal materials can be used. Typically, it is preferable to use Ti, which is particularly easily bonded to oxygen, or W, which has a high melting point and thus allows subsequent processes to be performed at relatively high temperatures. It is also possible to use a stack of any of the above materials and Cu or an alloy such as Cu—Mn, which has low resistance. In the transistors 105, 106, 111, and 112, for example, it is possible to use W for the conductive layers 141 and 151 and use a stack of Ti and Al for the conductive layers 142 and 152.

The above materials are capable of extracting oxygen from an oxide semiconductor layer. Therefore, in a region of the oxide semiconductor layer that is in contact with any of the above materials, oxygen is released from the oxide semiconductor layer and an oxygen vacancy is formed. Hydrogen slightly contained in the layer and the oxygen vacancy are bonded to each other, so that the region is markedly changed to an n-type region. Accordingly, the n-type region can serve as a source or a drain of the transistor.

In the case where W is used for the conductive layers 140 and 150, the conductive layers 140 and 150 may be doped with nitrogen. Doping with nitrogen can appropriately lower the capability of extracting oxygen and prevent the n-type region from spreading to a channel region. It is possible to prevent the n-type region from spreading to a channel region also by using a stack of W and an n-type semiconductor layer as the conductive layers 140 and 150 and putting the n-type semiconductor layer in contact with the oxide semiconductor layer. As the n-type semiconductor layer, an In—Ga—Zn oxide, zinc oxide, indium oxide, tin oxide, indium tin oxide, or the like to which nitrogen is added can be used.

The insulating layer 160 functioning as a gate insulating film can be formed using an insulating film containing one or more of aluminum oxide, magnesium oxide, silicon oxide, silicon oxynitride, silicon nitride oxide, silicon nitride, gallium oxide, germanium oxide, yttrium oxide, zirconium oxide, lanthanum oxide, neodymium oxide, hafnium oxide, and tantalum oxide. The insulating layer 160 may be a stack including any of the above materials. The insulating layer 160 may contain La, N, Zr, or the like as an impurity

An example of a layered structure of the insulating layer 160 is described. The insulating layer 160 includes, for example, oxygen, nitrogen, silicon, or hafnium. Specifically, the insulating layer 160 preferably includes hafnium oxide and silicon oxide or silicon oxynitride.

Hafnium oxide and aluminum oxide have higher dielectric constants than silicon oxide and silicon oxynitride. Therefore, the insulating layer 160 using hafnium oxide or aluminum oxide can have larger thickness than the insulating layer 160 using silicon oxide, so that leakage current due to tunnel current can be reduced. That is, a transistor with a low off-state current can be provided. Moreover, hafnium oxide with a crystalline structure has a higher dielectric constant than hafnium oxide with an amorphous structure. Therefore, it is preferable to use hafnium oxide with a crystalline structure in order to provide a transistor with a low off-state current. Examples of the crystal structure include a monoclinic crystal structure and a cubic crystal structure. Note that one embodiment of the present invention is not limited to the these examples.

For the insulating layers 120 and 160 in contact with the oxide semiconductor layer 130, a film that releases less nitrogen oxide is preferably used. In the case where the oxide semiconductor is in contact with an insulating layer that releases a large amount of nitrogen oxide, the density of states due to nitrogen oxide increases in some cases. For the insulating layers 120 and 160, for example, an oxide insulating layer such as a silicon oxynitride film or an aluminum oxynitride film that releases less nitrogen oxide can be used.

A silicon oxynitride film that releases less nitrogen oxide is a film of which the amount of released ammonia is larger than the amount of released nitrogen oxide in TDS; the amount of released ammonia is typically greater than or equal to 1×10¹⁸ molecules/cm³ and less than or equal to 5×10¹⁹ molecules/cm³. Note that the amount of released ammonia is the amount of ammonia released by heat treatment with which the surface temperature of the film becomes higher than or equal to 50° C. and lower than or equal to 650° C., preferably higher than or equal to 50° C. and lower than or equal to 550° C.

By using the above oxide insulating layer for the insulating layers 120 and 160, a shift in the threshold voltage of the transistor can be reduced, which leads to reduced fluctuations in the electrical characteristics of the transistor.

For the conductive layer 170 functioning as a gate electrode, for example, a conductive film formed using Al, Ti, Cr, Co, Ni, Cu, Y, Zr, Mo, Ru, Ag, Mn, Nd, Sc, Ta, or W can be used. Alternatively, an alloy or a conductive nitride of any of these materials may be used. Alternatively, a stack of a plurality of materials selected from these materials, alloys of these materials, and conductive nitrides of these materials may be used. Typically, tungsten, a stack of tungsten and titanium nitride, a stack of tungsten and tantalum nitride, or the like can be used. Alternatively, Cu or an alloy such as Cu—Mn, which has low resistance, or a stack of any of the above materials and Cu or an alloy such as Cu—Mn may be used. In this embodiment, tantalum nitride is used for the conductive layer 171 and tungsten is used for the conductive layer 172 to form the conductive layer 170.

As the insulating layer 175, a silicon nitride film, an aluminum nitride film, or the like containing hydrogen can be used. In the transistors 103, 104, 106, 109, 110, and 112 described in Embodiment 2, when an insulating film containing hydrogen is used as the insulating layer 175, part of the oxide semiconductor layer can have n-type conductivity. In addition, a nitride insulating film functions as a blocking film against moisture and the like and can improve the reliability of the transistor.

An aluminum oxide film can also be used as the insulating layer 175. It is particularly preferable to use an aluminum oxide film as the insulating layer 175 in the transistors 101, 102, 105, 107, 108, and 111 described in Embodiment 2. The aluminum oxide film has a significant effect of blocking both oxygen and impurities such as hydrogen and moisture. Accordingly, during and after the manufacturing process of the transistor, the aluminum oxide film can suitably function as a protective film that has effects of preventing entry of impurities such as hydrogen and moisture into the oxide semiconductor layer 130, preventing release of oxygen from the oxide semiconductor layer, and preventing unnecessary release of oxygen from the insulating layer 120. Furthermore, oxygen contained in the aluminum oxide film can be diffused into the oxide semiconductor layer.

Furthermore, the insulating layer 180 is preferably formed over the insulating layer 175. The insulating layer 180 can be formed using an insulating film containing one or more of magnesium oxide, silicon oxide, silicon oxynitride, silicon nitride oxide, silicon nitride, gallium oxide, germanium oxide, yttrium oxide, zirconium oxide, lanthanum oxide, neodymium oxide, hafnium oxide, and tantalum oxide. The insulating layer 180 may be a stack of any of the above materials.

Here, like the insulating layer 120, the insulating layer 180 preferably contains oxygen more than that in the stoichiometric composition. Oxygen released from the insulating layer 180 can be diffused into the channel formation region in the oxide semiconductor layer 130 through the insulating layer 160, so that oxygen vacancies formed in the channel formation region can be filled with oxygen. In this manner, stable electrical characteristics of the transistor can be achieved.

High integration of a semiconductor device requires miniaturization of a transistor. However, it is known that miniaturization of a transistor causes deterioration of electrical characteristics of the transistor. In particular, a decrease in channel width causes a reduction in on-state current.

In the transistors 107 to 112 in one embodiment of the present invention, the oxide semiconductor layer 130c is formed to cover the oxide semiconductor layer 130b where a channel is formed; thus, a channel formation layer is not in contact with the gate insulating film. Accordingly, scattering of carriers at the interface between the channel formation layer and the gate insulating film can be reduced and the on-state current of the transistor can be increased.

In the transistor in one embodiment of the present invention, as described above, the gate electrode (the conductive layer 170) is formed to electrically surround the oxide semiconductor layer 130 in the channel width direction; accordingly, a gate electric field is applied to the oxide semiconductor layer 130 in a direction perpendicular to its side surface in addition to a direction perpendicular to its top surface. In other words, a gate electric field is applied to the entire channel formation layer and an effective channel width is increased, leading to a further increase in on-state current.

Furthermore, in the transistor in one embodiment of the present invention in which the oxide semiconductor layer 130 has a two-layer structure or a three-layer structure, since the oxide semiconductor layer 130b where a channel is formed is provided over the oxide semiconductor layer 130a, an interface state is less likely to be formed. In the transistor in one embodiment of the present invention in which the oxide semiconductor layer 130 has a three-layer structure, since the oxide semiconductor layer 130b is positioned at the middle of the three-layer structure, the influence of an impurity that enters from upper and lower layers on the oxide semiconductor layer 130b can also be eliminated. Therefore, the transistor can achieve not only the increase in on-state current but also stabilization of the threshold voltage and a reduction in S value (subthreshold value). Thus, current at a gate voltage VG of 0 V can be reduced and power consumption can be reduced. In addition, since the threshold voltage of the transistor becomes stable, long-term reliability of the semiconductor device can be improved. Furthermore, the transistor in one embodiment of the present invention is suitable for a highly integrated semiconductor device because deterioration of electrical characteristics due to miniaturization is reduced.

Although the variety of films such as the metal films, the semiconductor films, and the inorganic insulating films that are described in this embodiment typically can be formed by sputtering or plasma-enhanced CVD, such films may be formed by another method such as thermal CVD. Examples of the thermal CVD include metal organic chemical vapor deposition (MOCVD) and atomic layer deposition (ALD).

Since plasma is not used for deposition, thermal CVD has an advantage that no defect due to plasma damage is generated.

Deposition by thermal CVD may be performed in such a manner that a source gas and an oxidizer are supplied to the chamber at the same time, the pressure in the chamber is set to an atmospheric pressure or a reduced pressure, and reaction is caused in the vicinity of the substrate or over the substrate.

Deposition by ALD is performed in such a manner that the pressure in a chamber is set to an atmospheric pressure or a reduced pressure, source gases for reaction are introduced into the chamber and reacted, and then the sequence of gas introduction is repeated. An inert gas (e.g., argon or nitrogen) may be introduced as a carrier gas with the source gases. For example, two or more kinds of source gases may be sequentially supplied to the chamber. In that case, after reaction of a first source gas, an inert gas is introduced, and then a second source gas is introduced so that the source gases are not mixed. Alternatively, the first source gas may be exhausted by vacuum evacuation instead of introduction of the inert gas, and then the second source gas may be introduced. The first source gas is adsorbed on the surface of the substrate and reacted to form a first layer, and then, the second source gas introduced is absorbed and reacted. As a result, a second layer is stacked over the first layer, so that a thin film is formed. The sequence of gas introduction is controlled and repeated more than once until desired thickness is obtained, so that a thin film with excellent step coverage can be formed. The thickness of the thin film can be adjusted by the number of repetition times of the sequence of gas introduction; therefore, ALD makes it possible to accurately adjust thickness and thus is suitable for manufacturing a minute FET.

The variety of films such as the metal film, the semiconductor film, and the inorganic insulating film that have been disclosed in the above embodiments can be formed by thermal CVD such as MOCVD or ALD. For example, in the case where an In—Ga—Zn—O film is formed, trimethylindium (In(CH₃)₃), trimethylgallium (Ga(CH₃)₃), and dimethylzinc (Zn(CH₃)₂) can be used. Without limitation to the above combination, triethylgallium (Ga(C₂H₅)₃) can be used instead of trimethylgallium and diethylzinc (Zn(C₂H₅)₂) can be used instead of dimethylzinc.

For example, in the case where a hafnium oxide film is formed by a deposition apparatus using ALD, two kinds of gases, i.e., ozone (O₃) as an oxidizer and a source material gas which is obtained by vaporizing liquid containing a solvent and a hafnium precursor (hafnium alkoxide and a hafnium amide such as tetrakis(dimethylamide)hafnium (TDMAH, Hf[N(CH₃)₂]₄) and tetrakis(ethylmethylamide)hafnium) are used.

For example, in the case where an aluminum oxide film is formed by a deposition apparatus using ALD, two kinds of gases, i.e., H₂O as an oxidizer and a source gas which is obtained by vaporizing liquid containing a solvent and an aluminum precursor (e.g., trimethylaluminum (TMA, Al(CH₃)₃)) are used. Examples of another material include tris(dimethylamide)aluminum, triisobutylaluminum, and aluminum tris(2,2,6,6-tetramethyl-3,5-heptanedionate).

For example, in the case where a silicon oxide film is formed by a deposition apparatus using ALD, hexachlorodisilane is adsorbed on a surface where a film is to be formed, and radicals of an oxidizing gas (e.g., O₂ or dinitrogen monoxide) are supplied to react with an adsorbate.

For example, in the case where a tungsten film is formed by a deposition apparatus using ALD, a WF₆ gas and a B₂H₆ gas are sequentially introduced to form an initial tungsten film, and then a WF₆ gas and an H₂ gas are sequentially introduced to form a tungsten film. Note that an SiH₄ gas may be used instead of a B₂H₆ gas.

For example, in the case where an oxide semiconductor film, e.g., an In—Ga—Zn—O film is formed by a deposition apparatus using ALD, an In(CH₃)₃ gas and an O₃ gas are sequentially introduced to form an In—O layer, a Ga(CH₃)₃ gas and an O₃ gas are sequentially introduced to form a Ga—O layer, and then a Zn(CH₃)₂ gas and an O₃ gas are sequentially introduced to form a Zn—O layer. Note that the order of these layers is not limited to this example. A mixed compound layer such as an In—Ga—O layer, an In—Zn—O layer, or a Ga—Zn—O layer may be formed by using these gases. Although an H₂O gas which is obtained by bubbling with an inert gas such as Ar may be used instead of an O₃ gas, it is preferable to use an O₃ gas, which does not contain H.

The structures described in this embodiment can be combined with any of the structures described in the other embodiments and example as appropriate.

### Embodiment 6

The structure of an oxide semiconductor film that can be used for one embodiment of the present invention will be described below.

In this specification, the term “parallel” indicates that the angle formed between two straight lines is greater than or equal to −10° and less than or equal to 10°, and accordingly includes the case where the angle is greater than or equal to −5° and less than or equal to 5°. The term “perpendicular” indicates that an angle formed between two straight lines is greater than or equal to 80° and less than or equal to 100°, and accordingly includes the case where the angle is greater than or equal to 85° and less than or equal to 95°.

In this specification, the trigonal and rhombohedral crystal systems are included in the hexagonal crystal system.

An oxide semiconductor film is roughly classified into a non-single-crystal oxide semiconductor film and a single-crystal oxide semiconductor film. The non-single-crystal oxide semiconductor film means any of a c-axis aligned crystalline oxide semiconductor (CAAC-OS) film, a polycrystalline oxide semiconductor film, a microcrystalline oxide semiconductor film, an amorphous oxide semiconductor film, and the like.

First, a CAAC-OS film is described.

The CAAC-OS film is one of oxide semiconductor films having a plurality of c-axis aligned crystal parts.

With a transmission electron microscope (TEM), a combined analysis image (also referred to as a high-resolution TEM image) of a bright-field image and a diffraction pattern of the CAAC-OS film is observed. Consequently, a plurality of crystal parts are observed clearly. However, in the high-resolution TEM image, a boundary between crystal parts, i.e., a grain boundary is not observed clearly. Thus, in the CAAC-OS film, a reduction in electron mobility due to the grain boundary is less likely to occur.

According to the high-resolution cross-sectional TEM image of the CAAC-OS film observed in a direction substantially parallel to a sample surface (cross-sectional TEM image), metal atoms are arranged in a layered manner in the crystal parts. Each metal atom layer has a morphology that reflects a surface over which the CAAC-OS film is formed (also referred to as a formation surface) or a top surface of the CAAC-OS film, and is provided parallel to the formation surface or the top surface of the CAAC-OS film.

On the other hand, according to the high-resolution planar TEM image of the CAAC-OS film observed in a direction substantially perpendicular to the sample surface, metal atoms are arranged in a triangular or hexagonal configuration in the crystal parts. However, there is no regularity of arrangement of metal atoms between different crystal parts.

The CAAC-OS film is subjected to structural analysis with an X-ray diffraction (XRD) apparatus. For example, when the CAAC-OS film including an InGaZnO₄ crystal is analyzed by an out-of-plane method, a peak appears frequently when the diffraction angle (2θ) is around 31°. This peak is derived from the (009) plane of the InGaZnO₄ crystal, which indicates that crystals in the CAAC-OS film have c-axis alignment, and that the c-axes are aligned in a direction substantially perpendicular to the formation surface or the top surface of the CAAC-OS film.

Note that when the CAAC-OS film with an InGaZnO₄ crystal is analyzed by an out-of-plane method, a peak of 2θ may also be observed at around 36°, in addition to the peak of 2θ at around 31°. The peak of 2μ at around 36° indicates that a crystal having no c-axis alignment is included in part of the CAAC-OS film. It is preferable that in the CAAC-OS film, a peak of 2θ appear at around 31° and a peak of 2θ not appear at around 36°.

The CAAC-OS film is an oxide semiconductor film having low impurity concentration. The impurity is an element other than the main components of the oxide semiconductor film, such as hydrogen, carbon, silicon, or a transition metal element. In particular, an element that has higher bonding strength to oxygen than a metal element included in the oxide semiconductor film, such as silicon, disturbs the atomic order of the oxide semiconductor film by depriving the oxide semiconductor film of oxygen and causes a decrease in crystallinity. Furthermore, a heavy metal such as iron or nickel, argon, carbon dioxide, or the like has a large atomic radius (molecular radius), and thus disturbs the atomic order of the oxide semiconductor film and causes a decrease in crystallinity when it is contained in the oxide semiconductor film. Note that the impurity contained in the oxide semiconductor film might serve as a carrier trap or a carrier generation source.

The CAAC-OS film is an oxide semiconductor film having low density of defect states. In some cases, oxygen vacancies in the oxide semiconductor film serve as carrier traps or serve as carrier generation sources when hydrogen is captured therein.

The state in which impurity concentration is low and density of defect states is low (the number of oxygen vacancies is small) is referred to as “highly purified intrinsic” or “substantially highly purified intrinsic”. A highly purified intrinsic or substantially highly purified intrinsic oxide semiconductor film has few carrier generation sources, and thus can have low carrier density. Thus, a transistor including the oxide semiconductor film rarely has negative threshold voltage (is rarely normally on). The highly purified intrinsic or substantially highly purified intrinsic oxide semiconductor film has few carrier traps. Accordingly, the transistor including the oxide semiconductor film has few variations in electrical characteristics and high reliability. Charge trapped by the carrier traps in the oxide semiconductor film takes a long time to be released and may behave like fixed charge. Thus, the transistor that includes the oxide semiconductor film having high impurity concentration and high density of defect states has unstable electrical characteristics in some cases.

In a transistor including the CAAC-OS film, changes in electrical characteristics of the transistor due to irradiation with visible light or ultraviolet light are small.

Next, a microcrystalline oxide semiconductor film is described.

A microcrystalline oxide semiconductor film has a region where a crystal part is observed in a high-resolution TEM image and a region where a crystal part is not clearly observed in a high-resolution TEM image. In most cases, a crystal part in the microcrystalline oxide semiconductor film is greater than or equal to 1 nm and less than or equal to 100 nm, or greater than or equal to 1 nm and less than or equal to 10 nm. A microcrystal with a size greater than or equal to 1 nm and less than or equal to 10 nm, or a size greater than or equal to 1 nm and less than or equal to 3 nm is specifically referred to as nanocrystal (nc). An oxide semiconductor film including nanocrystal is referred to as a nanocrystalline oxide semiconductor (nc-OS) film. In a high-resolution TEM image, a crystal grain boundary cannot be found clearly in the nc-OS film in some cases.

In the nc-OS film, a microscopic region (e.g., a region with a size greater than or equal to 1 nm and less than or equal to 10 nm, in particular, a region with a size greater than or equal to 1 nm and less than or equal to 3 nm) has periodic atomic order. There is no regularity of crystal orientation between different crystal parts in the nc-OS film. Thus, the orientation of the whole film is not observed. Accordingly, in some cases, the nc-OS film cannot be distinguished from an amorphous oxide semiconductor film depending on an analysis method. For example, when the nc-OS film is subjected to structural analysis by an out-of-plane method with an XRD apparatus using an X-ray having a diameter larger than that of a crystal part, a peak that shows a crystal plane does not appear. Furthermore, a halo pattern is shown in a selected-area electron diffraction pattern of the nc-OS film obtained by using an electron beam having a probe diameter larger than the diameter of a crystal part (e.g., larger than or equal to 50 nm). Meanwhile, spots are shown in a nanobeam electron diffraction pattern of the nc-OS film obtained by using an electron beam having a probe diameter close to or smaller than the diameter of a crystal part. Furthermore, in a nanobeam electron diffraction pattern of the nc-OS film, regions with high luminance in a circular (ring) pattern are shown in some cases. Also in a nanobeam electron diffraction pattern of the nc-OS film, a plurality of spots are shown in a ring-like region in some cases.

The nc-OS film is an oxide semiconductor film that has high regularity than an amorphous oxide semiconductor film. Thus, the nc-OS film has a lower density of defect states than the amorphous oxide semiconductor film. Note that there is no regularity of crystal orientation between different crystal parts in the nc-OS film; thus, the nc-OS film has a higher density of defect states than the CAAC-OS film.

Next, an amorphous oxide semiconductor film is described.

The amorphous oxide semiconductor film has disordered atomic arrangement and no crystal part. For example, the amorphous oxide semiconductor film does not have a specific state as in quartz.

In a high-resolution TEM image of the amorphous oxide semiconductor film, crystal parts cannot be found.

When the amorphous oxide semiconductor film is subjected to structural analysis by an out-of-plane method with an XRD apparatus, a peak which shows a crystal plane does not appear. A halo pattern is shown in an electron diffraction pattern of the amorphous oxide semiconductor film. Furthermore, a halo pattern is shown but a spot is not shown in a nanobeam electron diffraction pattern of the amorphous oxide semiconductor film.

Note that an oxide semiconductor film may have a structure having physical properties between the nc-OS film and the amorphous oxide semiconductor film. The oxide semiconductor film having such a structure is specifically referred to as an amorphous-like oxide semiconductor (amorphous-like OS) film.

In a high-resolution TEM image of the amorphous-like OS film, a void may be seen. Furthermore, in the high-resolution TEM image, there are a region where a crystal part is clearly observed and a region where a crystal part is not observed. In the amorphous-like OS film, crystallization by a slight amount of electron beam used for TEM observation occurs and growth of the crystal part is found sometimes. In contrast, crystallization by a slight amount of electron beam used for TEM observation is less observed in the nc-OS film having good quality.

Note that the crystal part size in the amorphous-like OS film and the nc-OS film can be measured using high-resolution TEM images. For example, an InGaZnO₄ crystal has a layered structure in which two Ga—Zn—O layers are included between In—O layers. A unit cell of the InGaZnO₄ crystal has a structure in which nine layers of three In—O layers and six Ga—Zn—O layers are layered in the c-axis direction. Accordingly, the spacing between these adjacent layers is equivalent to the lattice spacing on the (009) plane (also referred to as a d value). The value is calculated to be 0.29 nm from crystal structure analysis. Thus, each of the lattice fringes in which the spacing therebetween is from 0.28 nm to 0.30 nm corresponds to the a-b plane of the InGaZnO₄ crystal, focusing on the lattice fringes in the high-resolution TEM image.

Note that an oxide semiconductor film may be a stacked film including two or more films of an amorphous oxide semiconductor film, an amorphous-like OS film, a microcrystalline oxide semiconductor film, and a CAAC-OS film, for example.

The structures described in this embodiment can be combined with any of the structures described in the other embodiments and example as appropriate.

### Embodiment 7

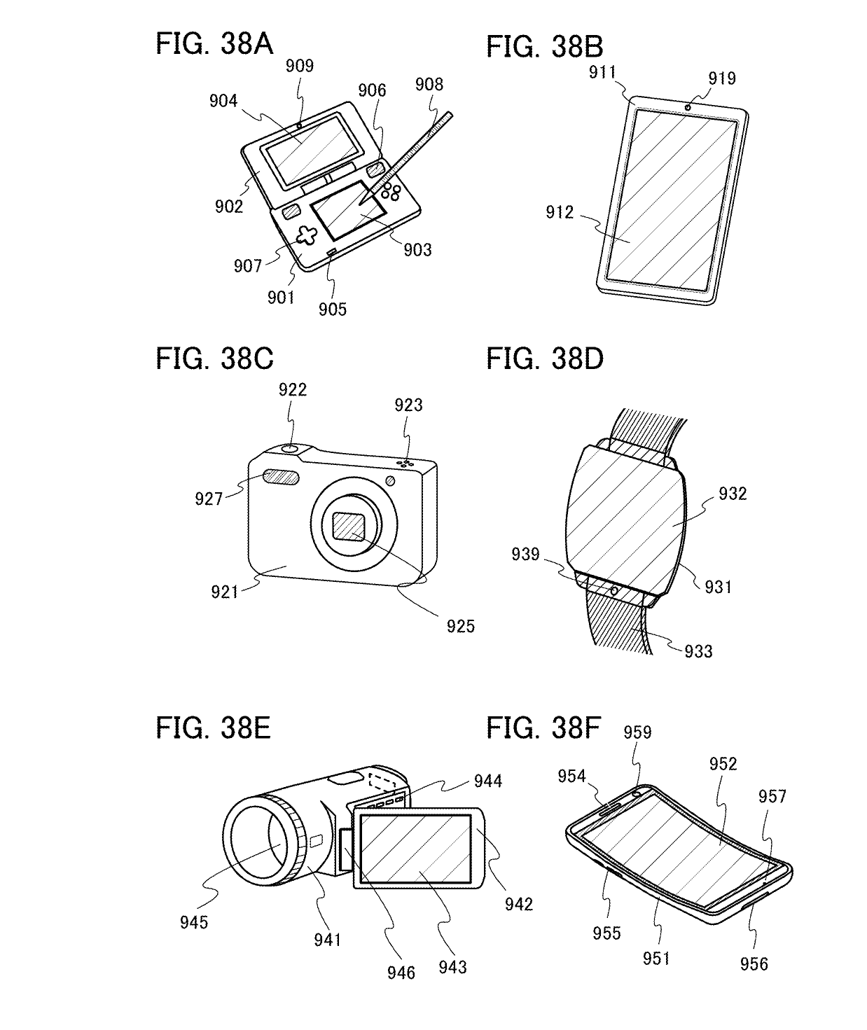

An imaging device in one embodiment of the present invention and a semiconductor device including the imaging device can be used for display devices, personal computers, or image reproducing devices provided with recording media (typically, devices that reproduce the content of recording media such as digital versatile discs (DVDs) and have displays for displaying the reproduced images). Furthermore, as electronic devices that can include the imaging device in one embodiment of the present invention and the semiconductor device including the imaging device, cellular phones, game machines (including portable game machines), portable information terminals, e-book readers, cameras such as video cameras and digital still cameras, goggle-type displays (head mounted displays), navigation systems, audio reproducing devices (e.g., car audio systems and digital audio players), copiers, facsimiles, printers, multifunction printers, automated teller machines (ATM), vending machines, and the like can be given. FIGS. 38A to 38F illustrate specific examples of these electronic devices.

FIG. 38A illustrates a portable game machine, which includes housings 901 and 902, display portions 903 and 904, a microphone 905, speakers 906, an operation key 907, a stylus 908, a camera 909, and the like. Although the portable game machine in FIG. 38A has the two display portions 903 and 904, the number of display portions included in the portable game machine is not limited to this. The imaging device in one embodiment of the present invention can be used for the camera 909.

FIG. 38B illustrates a portable information terminal, which includes a first housing 911, a display portion 912, a camera 919, and the like. The touch panel function of the display portion 912 enables input and output of information. The imaging device in one embodiment of the present invention can be used for the camera 919.

FIG. 38C illustrates a digital camera, which includes a housing 921, a shutter button 922, a microphone 923, a light-emitting portion 927, a lens 925, and the like. The imaging device in one embodiment of the present invention can be provided in a focus position of the lens 925.

FIG. 38D illustrates a wrist-watch-type information terminal, which includes a housing 931, a display portion 932, a wristband 933, a camera 939, and the like. The display portion 932 may be a touch panel. The imaging device in one embodiment of the present invention can be used for the camera 939.

FIG. 38E illustrates a video camera, which includes a first housing 941, a second housing 942, a display portion 943, operation keys 944, a lens 945, a joint 946, and the like. The operation keys 944 and the lens 945 are provided for the first housing 941, and the display portion 943 is provided for the second housing 942. The first housing 941 and the second housing 942 are connected to each other with the joint 946, and an angle between the first housing 941 and the second housing 942 can be changed with the joint 946. An image displayed on the display portion 943 may be switched in accordance with the angle between the first housing 941 and the second housing 942 at the joint 946. The imaging device in one embodiment of the present invention can be provided in a focus position of the lens 945.

FIG. 38F illustrates a cellular phone, which includes a display portion 952, a microphone 957, a speaker 954, a camera 959, an input/output terminal 956, an operation button 955, and the like in a housing 951. The imaging device in one embodiment of the present invention can be used for the camera 959.

The structures described in this embodiment can be combined with any of the structures described in the other embodiments and example as appropriate.

### EXAMPLE

This example will describe in detail the measurement results of 1/f noise of submicron top-gate OS transistors.

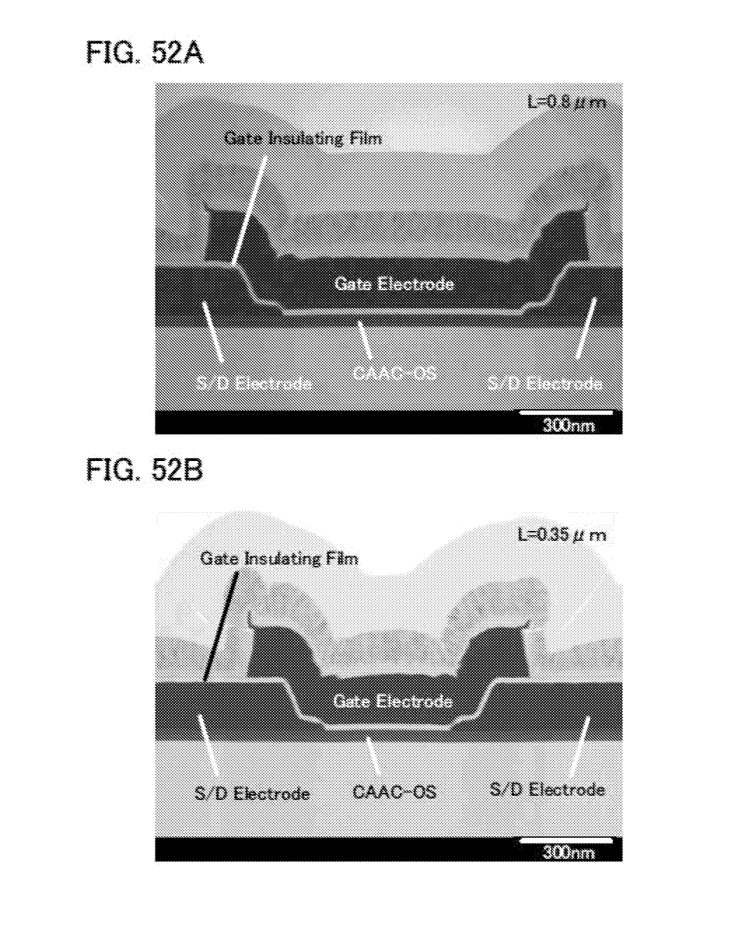

FIGS. 52A and 52B show cross-sectional STEM images of CAAC-OS transistors fabricated in a top-gate process. CAAC-OS was deposited on an insulating film by a sputtering method using an IGZO target with an atomic ratio of In to Ga and Zn=1:1:1. The thickness of the CAAC-OS film was 45 nm and the thickness of the gate insulating film (silicon oxide film) was 18.5 nm. The channel lengths L of the fabricated transistors were 0.8 μm and 0.35 μm.

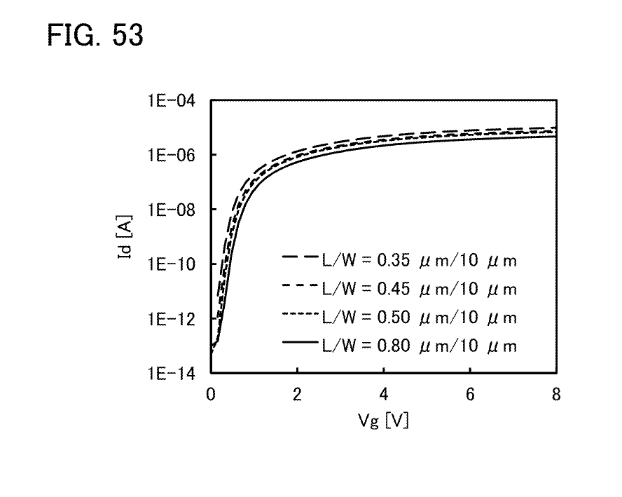

The 1/f noise was measured in a dark environment using Agilent E4725A and Cascade Microtech SUMMIT 11000B-M prober with temperature regulation (213 K to 473 K). The measurement was performed on submicron CAAC-OS transistors with channel lengths L=0.35 μm, 0.45 μm, 0.5 μm, and 0.8 μm and a channel width W=10 μm. For comparison, Si transistors (NMOS, PMOS) with channel lengths of 0.8 μm and 0.35 μm were also measured. For all measurements, the drain voltage Vd was 50 mV. FIG. 53 shows the static characteristics (Vd=50 mV) of the CAAC-OS transistors with channel lengths L=0.35 μm, 0.45 μm, 0.5 μm, and 0.8 μm and a channel width W=10 μm.

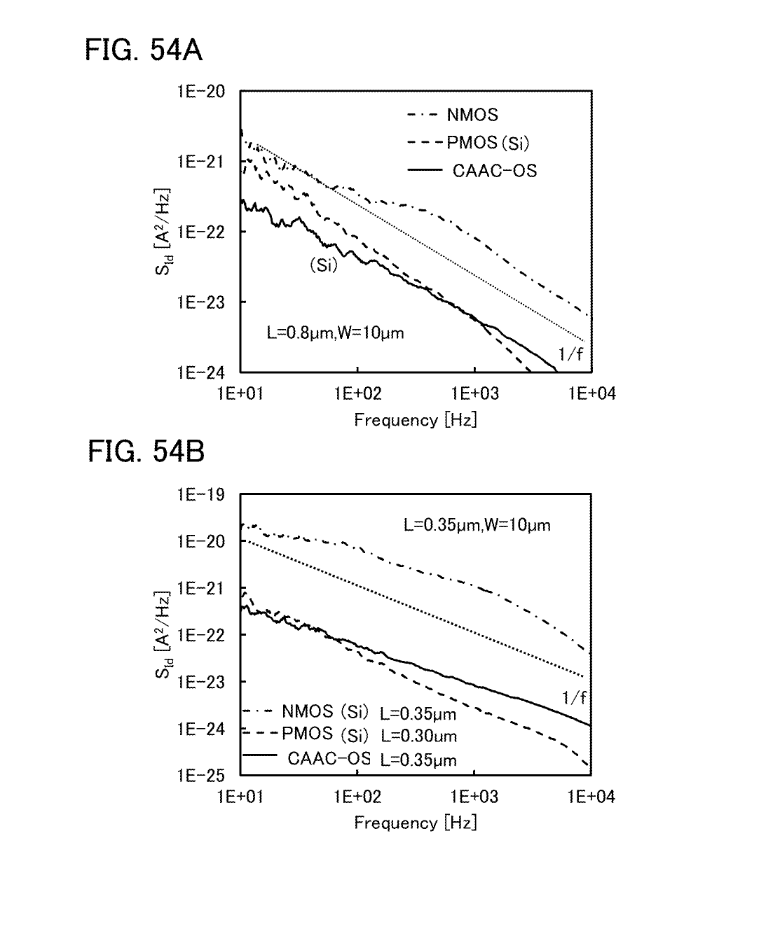

FIGS. 54A and 54B show measurement data of drain-current spectral density (S_{Id}) of the CAAC-OS transistor, the NMOS transistor, and the PMOS transistor as a function of frequency (drain current Id=1 μA). FIG. 54A shows the data for the transistors with a channel length L=0.8 μm and a channel width W=10 μm, and FIG. 54B shows the data for the transistors with a channel length L=0.35 μm and a channel width W=10 μm. Although we cannot quantitatively evaluate noise because of the different gate bias conditions for each transistor, the noise of the CAAC-OS transistor tends to be lower than that of the NMOS transistor.

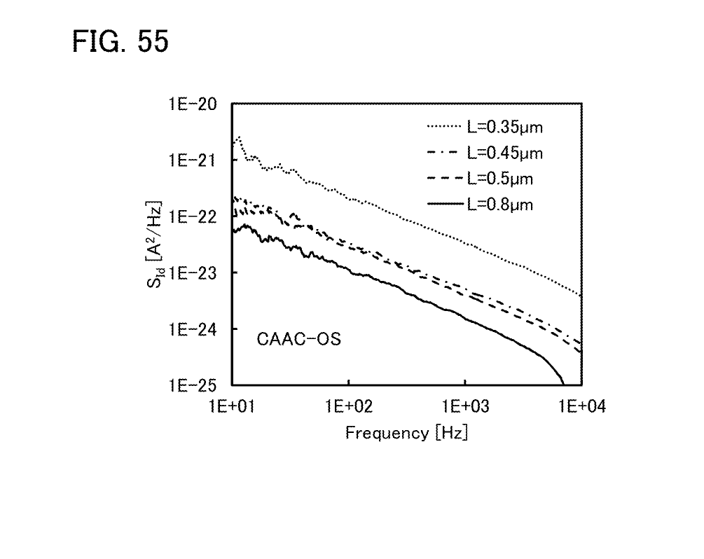

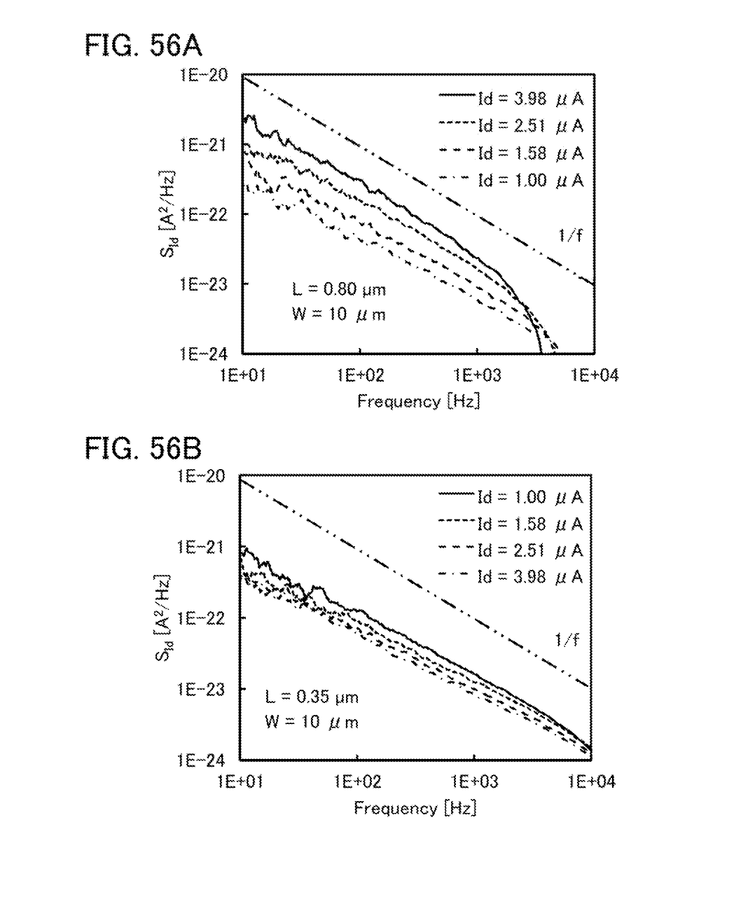

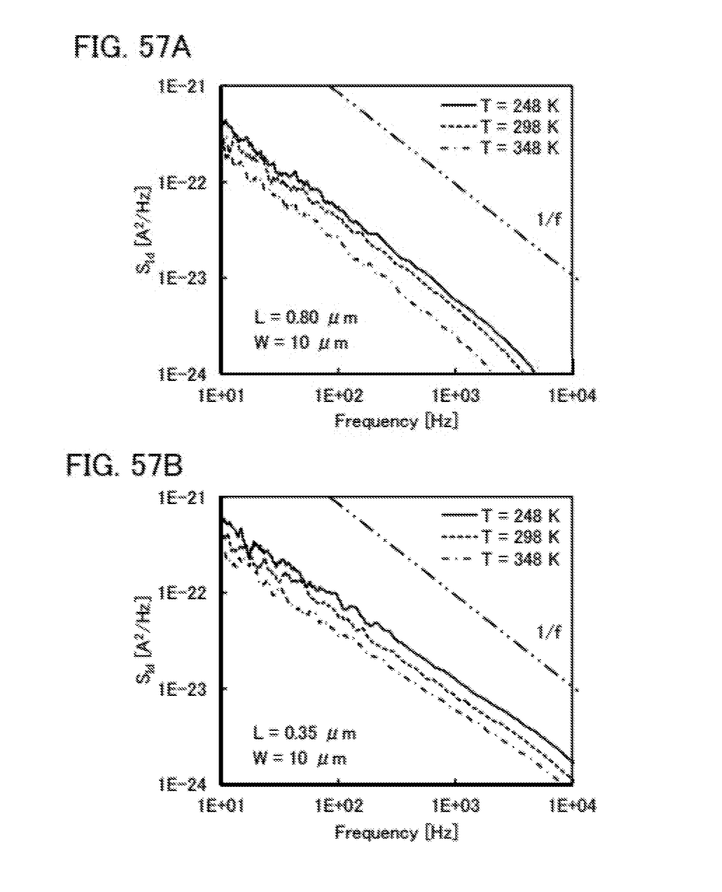

FIG. 55 shows S_{Id} as a function of frequency for the CAAC-OS transistors with plural channel lengths (L=0.35 μm, 0.45 μm, 0.5 μm, 0.8 μm) and a channel width W=10 μm. FIGS. 56A and 56B show S_{Id} as a function of frequency for a plurality of Id (Id=1.00 μA, 1.58 μA, 2.51 μA, 3.98 μA). FIGS. 57A and 57B show S_{Id} as a function of frequency for a plurality of temperatures (248 K, 298 K, 348 K). The CAAC-OS transistors do not deviate (hump) from the 1/f noise straight line for any current condition. Such a hump could be caused primarily by random telegraph signal (RTS) noise resulting from carrier generation and recombination (GR).

CAAC-OS is a wide bandgap material whose valence band maximum is flat and holes are heavy. In other words, carrier GR is unlikely to occur in CAAC-OS transistors. This is a great advantage in applying CAAC-OS transistors to image sensors.

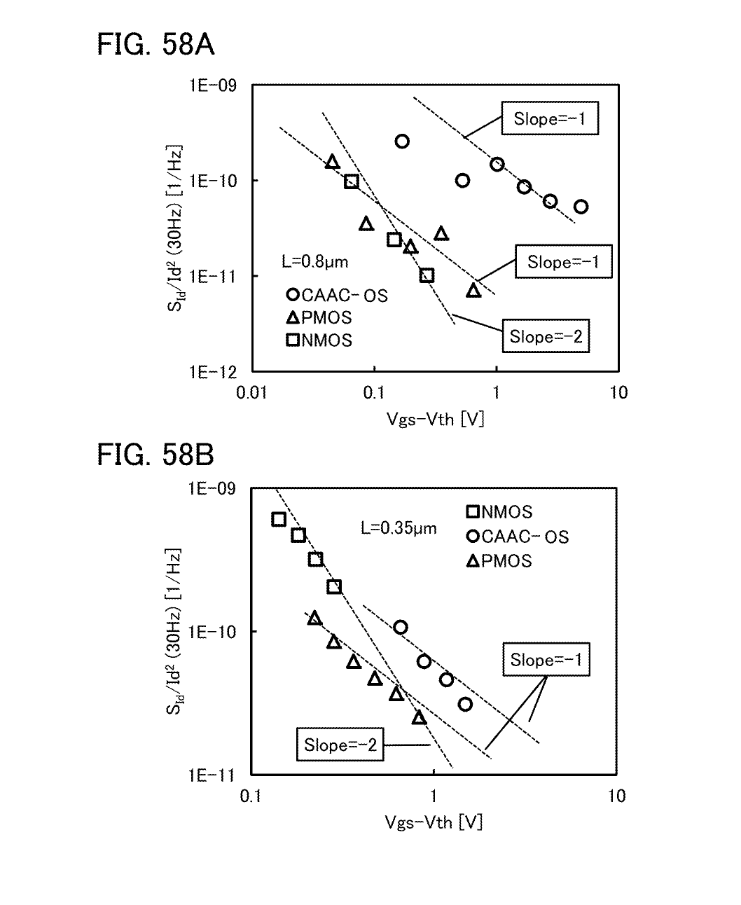

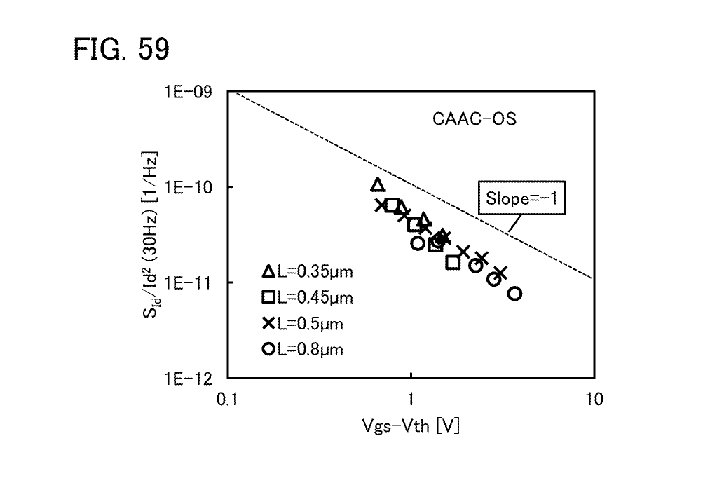

FIGS. 58A and 58B and FIG. 59 show normalized drain-current spectral density (S_{Id}/Id²) as a function of gate overdrive voltage (Vgs−Vth) at 30 Hz. FIG. 58A shows a comparison between an NMOS transistor, a PMOS transistor, and a CAAC-OS transistor (L=0.8 μm), FIG. 58B shows a comparison between an NMOS transistor a PMOS transistor, and a CAAC-OS transistor (L=0.35 μm), and FIG. 59 shows a comparison between CAAC-OS transistors with different L lengths (L=0.35 μm, 0.45 μm, 0.5 μm, 0.8 μm).

A carrier number fluctuation model is appropriate when S_{Id}/Id² is proportional to (Vgs−Vth)⁻², and a mobility fluctuation (4) model is appropriate when S_{Id}/Id² is proportional to (Vgs−Vth)⁻¹.

It has been reported that the Δμ model can also be applied to an OS transistor with a channel length L=20 μm. In other words, the 1/f noise of the CAAC-OS transistor comes from carrier scattering, with very little fluctuations in carrier number, i.e., GR is unlikely to occur.

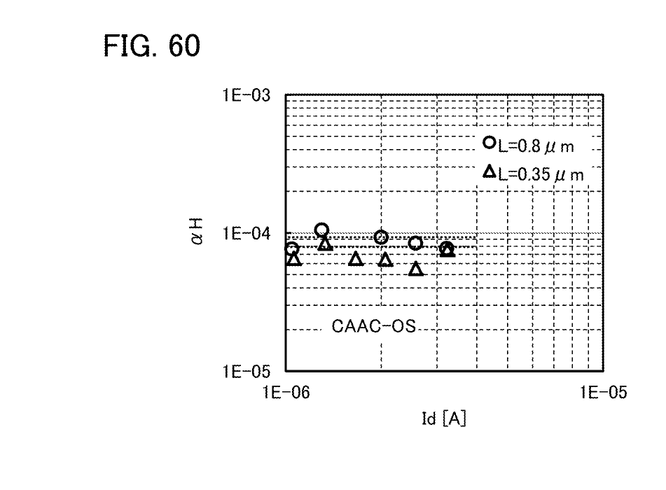

FIG. 60 represents the relationship between Id and Hooge's parameter α_{H}, which is calculated from S_{Id}/Id², at 30 Hz. The Δμ model is used in the Id range where α_{H} is flat, and α_{H} of CAAC-OS transistors with L=0.35 μm and 0.8 μm are approximately 7×10⁻⁵ and 9×10⁻⁵, respectively.

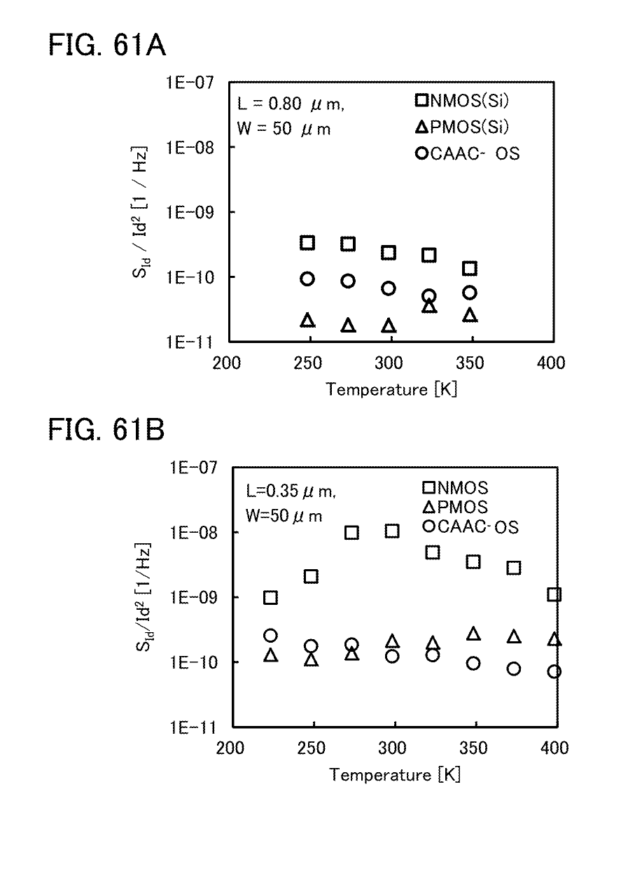

FIGS. 61A and 61B show S_{Id}/Id² as a function of temperature at 30 Hz and Id=1 μA for CAAC-OS transistors with L=0.8 μm and 0.35 μm, respectively. For the CAAC-OS transistors, S_{Id}/Id² tends to decrease as temperature increases. However, the temperature dependence of S_{Id}/Id² is weaker than that for the NMOS transistor.

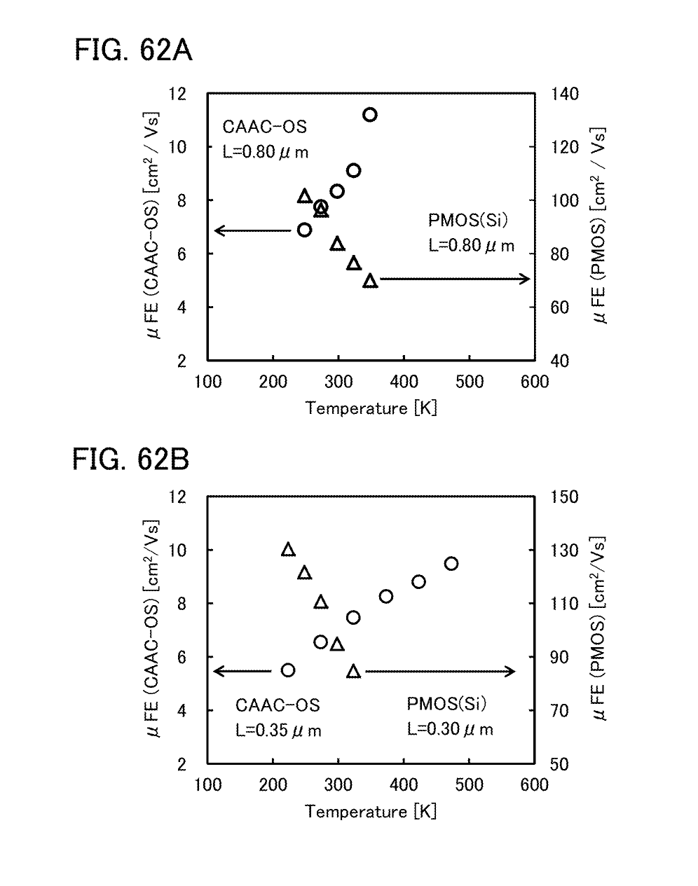

FIG. 62A shows the μ_{FE} of a PMOS transistor and a CAAC-OS transistor with L=0.8 μm measured at different temperatures and FIG. 62B shows the μ_{FE} of a PMOS transistor and a CAAC-OS transistor with L=0.35 μm measured at different temperatures. FIGS. 62A and 62B show a negative correlation between S_{Id}/Id² and μ_{TE}.

For the PMOS transistor, μ_{FE} decreases at high temperatures, whereas μ_{FE} increases at high temperatures for the CAAC-OS transistor. This difference indicates that μ_{FE} of the CAAC-OS transistor is determined by scattering that is different from lattice scattering, which determines the PMOS transistor μFE. On the basis of the Arrhenius equation, the activation energy Ea of μ_{FE} of the CAAC-OS transistor was approximately 30 meV for L/W=0.8 μm/50 μm, and approximately 20 meV for L/W=0.35 μm/50 μm.

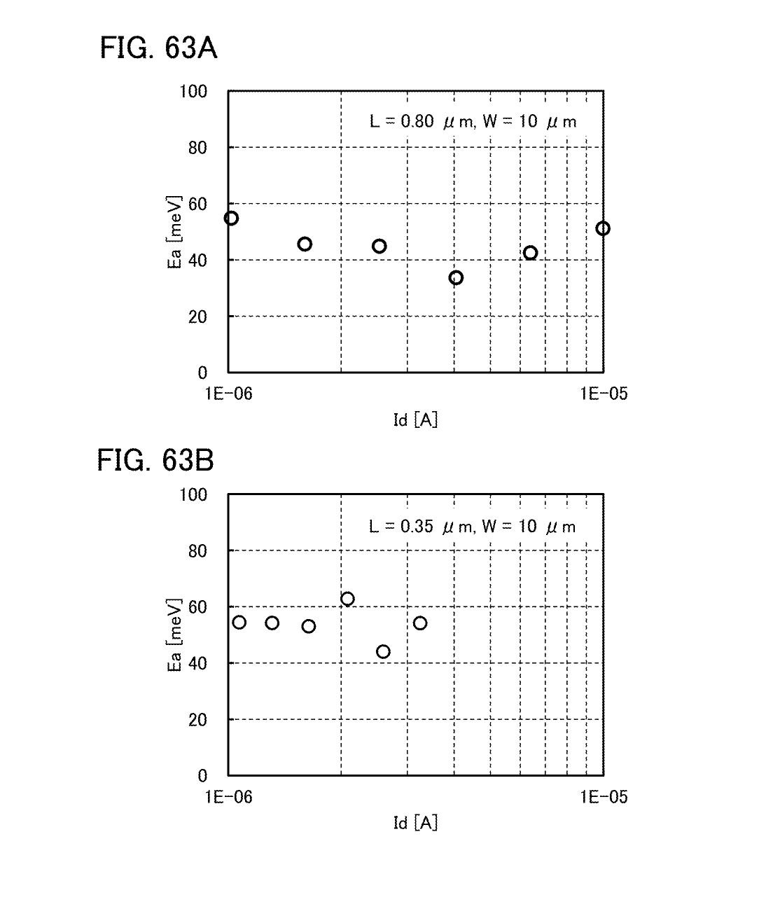

FIGS. 63A and 63B show the relationship between drain current and the S_{Id}/Id² activation energy calculated by applying the Arrhenius equation to the temperature dependence of S_{Id}/Id² in FIGS. 61A and 61B. The activation energy falls within the range of approximately 40 meV to 70 meV for L/W=0.35 μm/50 μm as shown in FIG. 63B, and within the range of approximately 30 meV to 60 meV for L/W=0.8 μm/50 μm as shown in FIG. 63A. This result indicates that conduction electrons scatter in the CAAC-OS transistor from an energy barrier of approximately 30 meV to 70 meV.

As described above, the 1/f noise of CAAC-OS transistors was analyzed. The characteristics of CAAC-OS transistor 1/f noise are superior to those of the NMOS and PMOS transistor 1/f noise. Moreover, a submicron CAAC-OS transistor does not result in fluctuations in carrier number and has a weak temperature dependence. These device characteristics are effective in using CAAC-OS transistors in analog LSI such as image sensors.

The structure shown in this example can be used as appropriate in combination with any of the structures shown in the other embodiments.

This application is based on Japanese Patent Application serial No. 2014-209236 filed with Japan Patent Office on Oct. 10, 2014, Japanese Patent Application serial No. 2014-227919 filed with Japan Patent Office on Nov. 10, 2014, Japanese Patent Application serial No. 2015-012296 filed with Japan Patent Office on Jan. 26, 2015, and Japanese Patent Application serial No. 2015-099700 filed with Japan Patent Office on May 15, 2015, the entire contents of which are hereby incorporated by reference.

### EXPLANATION OF REFERENCE

31: opening, 32: opening, 40: silicon substrate, 41: insulating layer, 41a: insulating layer, 41b: insulating layer, 42: insulating layer, 42a: insulating layer, 42b: insulating layer, 51: transistor, 52: transistor, 53: transistor, 54: transistor, 55: transistor, 56: transistor, 58: capacitor, 59: active layer, 60: photoelectric conversion element, 61: photoelectric conversion layer, 62: light-transmitting conductive layer, 63: semiconductor layer, 64: semiconductor layer, 65: semiconductor layer, 66: electrode, 66a: conductive layer, 66b: conductive layer, 67: partition wall, 70: conductor, 71: wiring, 72: wiring, 74: wiring, 75: wiring, 76: wiring, 77: wiring, 77a: conductive layer, 77b: conductive layer, 78: wiring, 79: wiring, 80: insulating layer, 81: conductor, 101: transistor, 102: transistor, 103: transistor, 104: transistor, 105: transistor, 106: transistor, 107: transistor, 108: transistor, 109: transistor, 110: transistor, 111: transistor, 112: transistor, 115: substrate, 120: insulating layer, 130: oxide semiconductor layer, 130a: oxide semiconductor layer, 130b: oxide semiconductor layer, 130c: oxide semiconductor layer, 140: conductive layer, 141: conductive layer, 142: conductive layer, 150: conductive layer, 151: conductive layer, 152: conductive layer, 160: insulating layer, 170: conductive layer, 171: conductive layer, 172: conductive layer, 173: conductive layer, 175: insulating layer, 180: insulating layer, 231: region, 232: region, 233: region, 311: wiring, 312: wiring, 313: wiring, 314: wiring, 315: wiring, 316: wiring, 317: wiring, 331: region, 332: region, 333: region, 334: region, 335: region, 501: signal, 502: signal, 503: signal, 504: signal, 505: signal, 506: signal, 507: signal, 508: signal, 509: signal, 510: period, 511: period, 520: period, 531: period, 610: period, 611: period, 612: period, 621: period, 622: period, 623: period, 631: period, 701: signal, 702: signal, 703: signal, 704: signal, 705: signal, 901: housing, 902: housing, 903: display portion, 904: display portion, 905: microphone, 906: speaker, 907: operation key, 908: stylus, 909: camera, 911: housing, 912: display portion, 919; camera, 921: housing, 922: shutter button, 923: microphone, 925: lens, 927: light-emitting portion, 931: housing, 932: display portion, 933: wristband, 939: camera, 941: housing, 942: housing, 943: display portion, 944: operation kay, 945: lens, 946: joint, 951: housing, 952: display portion, 954: speaker, 955: button, 956: input/output terminal, 957: microphone, 959: camera, 1200: region, 1300: region, 1400: region, 1500: insulating layer, 1510: light-blocking layer, 1520: organic resin layer, 1530a: color filter, 1530b: color filter, 1530c: color filter, 1540: microlens array, 1550: photoelectric conversion layer.

1. An imaging device comprising a photoelectric conversion element, a first transistor, a second transistor, and a first insulating layer provided between the first transistor and the photoelectric conversion element,
wherein one of a source electrode and a drain electrode of the first transistor is electrically connected to an electrode of the photoelectric conversion element,
wherein the other of the source electrode and the drain electrode of the first transistor is electrically connected to a gate electrode of the second transistor,
wherein a single electrical connection portion between the one of the source electrode and the drain electrode of the first transistor and the electrode of the photoelectric conversion element is provided in the first insulating layer,
wherein the first transistor includes an oxide semiconductor in an active layer, and
wherein drain current spectral density of the first transistor is inversely proportional to frequency.

2. The imaging device according to claim 1, further comprising an opening,
wherein the single electrical connection portion is provided in the opening where the one of the source electrode and the drain electrode of the first transistor overlaps with the electrode of the photoelectric conversion element.

3. The imaging device according to claim 1, further comprising a second insulating layer provided between the other of the source electrode and the drain electrode of the first transistor and the gate electrode of the second transistor,
wherein a single electrical connection portion between the other of the source electrode and the drain electrode of the first transistor and the gate electrode of the second transistor is provided in the second insulating layer, and
wherein the single electrical connection portion is provided in a portion of the second insulating layer where the other of the source electrode and the drain electrode of the first transistor overlaps with the gate electrode of the second transistor.

4. The imaging device according to claim 1, further comprising a capacitor,
wherein the other of the source electrode and the drain electrode of the first transistor is electrically connected to an electrode of the capacitor.

5. The imaging device according to claim 1, further comprising a third transistor and a fourth transistor,
wherein the other of the source electrode and the drain electrode of the first transistor is electrically connected to one of a source electrode and a drain electrode of the third transistor,
wherein one of a source electrode and a drain electrode of the second transistor is electrically connected to one of a source electrode and a drain electrode of the fourth transistor, and
wherein each of the third transistor and the fourth transistor includes an oxide semiconductor in an active layer.

6. The imaging device according to claim 1,
wherein the oxide semiconductor includes In, Zn, and M (M is Al, Ti, Ga, Sn, Y, Zr, La, Ce, Nd, or Hf), and
wherein c-axes of the oxide semiconductor are aligned in a direction perpendicular to a top surface of the oxide semiconductor.

7. The imaging device according to claim 1,
wherein the photoelectric conversion element comprises a photoelectric conversion layer including selenium.

8. The imaging device according to claim 1,
wherein the imaging device is bent.

9. An electronic device comprising:
the imaging device according to claim 1; and
a display device.

10. An imaging device comprising a photoelectric conversion element, a first transistor, a second transistor, and a first insulating layer,
wherein the first insulating layer is over the first transistor and the second transistor,
wherein the photoelectric conversion element is over the first insulating layer,
wherein one of a source electrode and a drain electrode of the first transistor is electrically connected to an electrode of the photoelectric conversion element,
wherein the other of the source electrode and the drain electrode of the first transistor is electrically connected to a gate electrode of the second transistor,
wherein a single electrical connection portion between the one of the source electrode and the drain electrode of the first transistor and the electrode of the photoelectric conversion element is provided in the first insulating layer,
wherein the first transistor includes an oxide semiconductor in an active layer, and
wherein drain current spectral density of the first transistor is inversely proportional to frequency.

11. The imaging device according to claim 10, further comprising a second insulating layer provided between the other of the source electrode and the drain electrode of the first transistor and the gate electrode of the second transistor,
wherein a single electrical connection portion between the other of the source electrode and the drain electrode of the first transistor and the gate electrode of the second transistor is provided in the second insulating layer, and
wherein the single electrical connection portion is provided in a portion of the second insulating layer where the other of the source electrode and the drain electrode of the first transistor overlaps with the gate electrode of the second transistor.

12. The imaging device according to claim 10, further comprising a second insulating layer provided between the other of the source electrode and the drain electrode of the first transistor and the gate electrode of the second transistor, and
wherein a single electrical connection portion between the other of the source electrode and the drain electrode of the first transistor and the gate electrode of the second transistor is provided in the second insulating layer.

13. The imaging device according to claim 10, further comprising a capacitor,
wherein the other of the source electrode and the drain electrode of the first transistor is electrically connected to an electrode of the capacitor.

14. The imaging device according to claim 10, further comprising a third transistor and a fourth transistor,
wherein the other of the source electrode and the drain electrode of the first transistor is electrically connected to one of a source electrode and a drain electrode of the third transistor,
wherein one of a source electrode and a drain electrode of the second transistor is electrically connected to one of a source electrode and a drain electrode of the fourth transistor, and
wherein each of the third transistor and the fourth transistor includes an oxide semiconductor in an active layer.

15. The imaging device according to claim 10,
wherein the oxide semiconductor includes In, Zn, and M (M is Al, Ti, Ga, Sn, Y, Zr, La, Ce, Nd, or Hf), and
wherein c-axes of the oxide semiconductor are aligned in a direction perpendicular to a top surface of the oxide semiconductor.

16. The imaging device according to claim 10,
wherein the photoelectric conversion element comprises a photoelectric conversion layer including selenium.

17. The imaging device according to claim 10,
wherein the imaging device is bent.

18. An electronic device comprising:
the imaging device according to claim 10; and
a display device.
